(19) United States
(12) Patent Application Publication
(10) Pub. No.: US 2026/0351526 A1
(43) Pub. Date: Nov. 5, 2026

(54) FILM, LAMINATE, PLASMA PROCESSING APPARATUS, AND MANUFACTURING METHOD OF LAMINATE

(71) Applicant: TORAY Industries, Inc., Tokyo (JP)

(72) Inventors: Yugo TANIGAKI, Otsu-shi, Shiga (JP); Akira SHIMADA, Otsu-shi, Shiga (JP); Daisaku TANAKA, Otsu-shi, Shiga (JP); Yohei SAKABE, Otsu-shi, Shiga (JP)

(73) Assignee: TORAY Industries, Inc., Tokyo (JP)

(21) Appl. No.: 19/111,747

(22) PCT Filed: Sep. 6, 2023
(86) PCT No.: PCT/JP2023/032488

§ 371 Date: Mar. 13, 2025

(30) Foreign Application Priority Data
Sep. 21, 2022 (JP) 2022-149958
Sep. 21, 2022 (JP) 2022-149959

(51) Int. Cl. H01J 37/32; C09J 11/04; H01J 9/30; H10P 72/00; H10P 72/72

(52) U.S. Cl. CPC H01J 37/32467; C09J 11/04; H01J 9/30; H01J 37/32715; H01J 37/32807; H10P 72/722; H10P 72/0421

(57) ABSTRACT

The present disclosure provides a film including: an (SA) binder resin; and an (SD) thermally conductive filler, wherein the (SD) thermally conductive filler includes an (SD1) first thermally conductive filler and an (SD2) second thermally conductive filler.

### TECHNICAL FIELD

The present invention relates to a film, a laminate, a plasma processing apparatus, and a method for manufacturing a laminate.

### BACKGROUND ART

In recent years, electronic terminal devices have become more sophisticated, smaller, thinner, and lighter. These electronic terminal devices include a semiconductor device, and examples thereof include a processor and a memory. In the process of manufacturing these semiconductors, a coating liquid such as an adhesive or a sheet having adhesiveness is used for the purpose of joining members to each other or temporarily holding members in the manufacturing process.

In addition, in a substrate processing apparatus that performs sputtering, vapor deposition, chemical vapor deposition, ion implantation, etching, ashing, exposure, inspection, or the like in the process of manufacturing semiconductors, an electrostatic chuck is used as a means for attracting and holding a semiconductor wafer, a glass substrate, or the like. For example, the plasma processing apparatus is provided inside a vacuum chamber with a stage on which a semiconductor wafer is to be placed, and the stage mainly includes an electrostatic chuck and a cooler for controlling the temperature of the electrostatic chuck. The electrostatic chuck is made by sandwiching an electrode between ceramic dielectric plates, followed by baking, and includes a base plate, a ceramic dielectric plate formed of ceramics, and an adhesive member that adheres the base plate and the ceramic dielectric plate. The electrostatic chuck is a holding device that attracts and holds a semiconductor wafer or the like on the surface of a ceramic dielectric plate by utilizing an electrostatic attractive force generated by applying a voltage to a built-in electrode.

Meanwhile, in the manufacture of a semiconductor device, an etching process with a high aspect ratio for increasing the etching depth is required to achieve high density and high integration of a 3D-NAND memory or the like. To improve the aspect ratio and reduce the process time in the etching step, a method of etching at a cryogenic temperature of −30 °C or less is proposed (see, for example, Patent Document 1). Therefore, an adhesive member that can be used even at a cryogenic temperature of −30 °C or less is required. An adhesive member that can be used even at such a cryogenic temperature is required not only for an electrostatic chuck but also for other holding devices such as a vacuum chuck.

Examples of an adhesive member in an electrostatic chuck or the like include a silicone resin-based adhesive member and an acrylic resin-based adhesive member (see, for example, Patent Document 2 or Patent Document 3).

### PRIOR ART DOCUMENT

### Patent Documents

Patent Document 1: Japanese Patent No. 6621882
Patent Document 2: Japanese Patent Laid-open Publication No. 2011-151280
Patent document 3: Japanese Patent Laid-open Publication No. 2014-207374

### SUMMARY OF THE INVENTION

### Problems to be Solved by the Invention

With the adhesive member described in Patent Document 2 or Patent Document 3, however, mechanical physical properties are deteriorated at a cryogenic temperature of −30 °C or less, so that there are problems such as the peeling of members due to deterioration of adhesion for joining the members, and occurrence of cracks in the adhesive member. An object of the present invention is to provide a film that is superior in adhesion for joining members to each other even at a cryogenic temperature of about −50 °C and having high thermal cycle reliability.

### Solutions to the Problems

To solve the problems described above, the film of the present invention has the following configurations [1] to [20].

[1] A film including: an (SA) binder resin; and an (SD) thermally conductive filler, wherein the (SD) thermally conductive filler includes an (SD1) first thermally conductive filler and an (SD2) second thermally conductive filler, the (SD1) first thermally conductive filler has an average primary particle size of 1.0 to 200 μm, the (SD2) second thermally conductive filler has an average primary particle size of 0.010 μm or more and less than 1.0 μm, the film has a shear strain of 0.70 to 20 at −50 °C, and the film has a thermal conductivity 0.10 to 5.0 W/(m·K) at 25 °C.

[2] The film according to the preceding [1], wherein the film has an elastic modulus of 0.10 to 200 MPa at −50 °C.

[3] The film according to the preceding [1] or [2], wherein the film satisfies at least one of the following conditions (S1a), (S2a), (S3a), (S1b), (S2b), and (S3b): (S1a) a content of boron element in the film is 5.0% by mass or less;
(S2a) a content of phosphorus element in the film is 1,000 ppm by mass or less;
(S3a) a total content of chlorine element and bromine element in the film is 1,000 ppm by mass or less;
(S1b) a total content of boron element-containing ions in the film is 5.0% by mass or less;
(S2b) a total content of phosphorus element-containing ions in the film is 5,000 ppm by mass or less; and
(S3b) a total content of chloride ion and bromide ion in the film is 1,000 ppm by mass or less.

[4] The film according to any one of the preceding [1] to [3], wherein the film satisfies at least one of the following conditions (S4a) and (S4b):
(S4a) a content of platinum element in the film is 1,000 ppm by mass or less; and
(S4b) a total content of platinum element-containing ions in the film is 5,000 ppm by mass or less.

[5] The film according to any one of the preceding [1] to [4], wherein the film satisfies at least one of the following conditions (S5a) and (S5b):
(S5a) a total content of an organosilane compound having 1 to 2 silicon atoms in the film is 1,000 ppm by mass or less; and
(S5b) a total content of a cyclic silicone compound in the film is 1,000 ppm by mass or less.

[6] A film including: an (SA) binder resin; and an (SD) thermally conductive filler, wherein the film has an elastic modulus of 0.10 to 200 MPa at −50 °C, and the film has a thermal conductivity of 0.10 to 5.0 W/(m·K) at 25 °C.

[7] The film according to the preceding [6], wherein the film has a shear strain of 0.70 to 20 at −50 °C.

[8] The film according to the preceding [6] or [7], wherein the film satisfies at least one of the following conditions (S1a), (S2a), (S3a), (S1b), (S2b), and (S3b):
(S1a) a content of boron element in the film is 5.0% by mass or less;
(S2a) a content of phosphorus element in the film is 1,000 ppm by mass or less;
(S3a) a total content of chlorine element and bromine element in the film is 1,000 ppm by mass or less;
(S1b) a total content of boron element-containing ions in the film is 5.0% by mass or less;
(S2b) a total content of phosphorus element-containing ions in the film is 5,000 ppm by mass or less; and
(S3b) a total content of chloride ion and bromide ion in the film is 1,000 ppm by mass or less.

[9] The film according to any one of the preceding [6] to [8], wherein the film satisfies at least one of the following conditions (S4a) and (S4b):
(S4a) a content of platinum element in the film is 1,000 ppm by mass or less; and
(S4b) a total content of platinum element-containing ions in the film is 5,000 ppm by mass or less.

[10] The film according to any one of the preceding [6] to [9], wherein the film satisfies at least one of the following conditions (S5a) and (S5b):
(S5a) a total content of an organosilane compound having 1 to 2 silicon atoms in the film is 1,000 ppm by mass or less; and
(S5b) a total content of a cyclic silicone compound in the film is 1,000 ppm by mass or less.

[11] The film according to any one of the preceding [1] to [10], wherein the (SA) binder resin includes an (SA1) resin having a silicone structure and/or a siloxane structure in a structural unit of the resin.

[12] The film according to the preceding [11], wherein a content ratio of aliphatic groups bonding to silicon atoms in the silicone structure and/or the siloxane structure accounting for in a total of the aliphatic groups and aromatic groups bonding to silicon atoms in the silicone structure and/or the siloxane structure is 80 to 100 mol %.

[13] The film according to the preceding [11] or [12], wherein the (SA1) resin containing a silicone structure and/or a siloxane structure in a structural unit of the resin includes an (SA1-1) resin containing one or more selected from the group consisting of an imide structure, an amide structure, and an oxazole structure in a structural unit of the resin.

[14] The film according to the preceding [13], wherein the (SA1-1) resin containing one or more selected from the group consisting of an imide structure, an amide structure, and an oxazole structure in a structural unit of the resin has one or more selected from the group consisting of the following residues (1) and (2):
(1) a diamine residue, diamine derivative residue, bisaminophenol compound residue, or bisaminophenol compound derivative residue containing a silicone structure and/or a siloxane structure; and
(2) a tetracarboxylic acid residue, tetracarboxylic acid derivative residue, tricarboxylic acid residue, tricarboxylic acid derivative residue, dicarboxylic acid residue, or dicarboxylic acid derivative residue containing a silicone structure and/or a siloxane structure.

[15] The film according to any one of the preceding [1] to [14], wherein the film contains (SB) an epoxy compound or a compound having a structure derived from an epoxy compound (hereinafter “(SB) compound”), and the (SB) compound contains one or more selected from the group consisting of an (SB1) compound having a structure containing an oxyalkylene group, an (SB2) compound having a structure containing at least two aromatic structures and having a structure containing an oxyalkylene group, and an (SB3) compound having a tertiary amine structure bonding to an arylene group and two divalent organic groups.

[16] The film according to any one of the preceding [1] to [15], wherein the film contains (SC) an amine compound or a compound having a structure derived from an amine compound (hereinafter “(SC) compound”), and the (SC) compound contains an (SC1) compound having a silicone structure and/or a siloxane structure and having at least two alkylene groups bonding to a silicon atom in the silicone structure and/or the siloxane structure.

[17] The film according to any one of the preceding [1] to [16], wherein the film has an elastic modulus of 0.010 to 1.0 MPa at 25 °C.

[18] The film according to any one of the preceding [1] to [16], wherein the film is a cured product of a composition.

[19] The film according to any one of the preceding [1] to [18], which is used for an electrostatic chuck.

[20] A laminate including: a base plate; the film according to any one of the preceding [1] to [19]; and a ceramic dielectric plate arranged in this order, wherein the base plate and the ceramic dielectric plate are different in coefficient of thermal expansion.

[21] The laminate according to the preceding [20], wherein a difference in coefficient of thermal expansion between the base plate and the ceramic dielectric plate is 1.0 to 30 ppm/K.

[22] A plasma processing apparatus including: a plasma source; and the laminate according to the preceding [20] or [21].

[23] A method for manufacturing a laminate, including: a step of disposing a base plate; a step of disposing the film according to any one of the preceding [1] to [19]; and a step of disposing a ceramic dielectric plate.

### Effects of the Invention

According to the present invention, it is possible to provide a film that is superior in adhesion for joining members to each other even at a cryogenic temperature of about −50 °C and having high thermal cycle reliability.

### BRIEF DESCRIPTION OF THE DRAWINGS

FIG. 1 is a schematic sectional view illustrating Embodiment 1 of a laminate that is a laminate, including a first support, a film, and a second support.

FIG. 2 is a schematic sectional view illustrating Embodiment 2 of a laminate that is a laminate, including a base plate, a film, and a ceramic dielectric plate.

### EMBODIMENTS OF THE INVENTION

Hereinafter, the film of the present invention will be described. In the case of making a description referring to “the film of the present invention,” this description is a common description of a first aspect and a second aspect of the film of the present invention. Meanwhile, when a film of a specific aspect is described, the description is made with an expression “the first aspect of the film of the present invention” or the like. It is noted that the present invention is not limited to only the following embodiments, and various modifications can naturally be made as long as the modifications can achieve the object of the invention and do not depart from the gist of the invention.

The main chain of a resin refers to the chain having the longest chain length among the chains constituting the resin containing structural units. A side chain of a resin refers to any chain branched from the main chain or bonded to the main chain and having a chain length shorter than that of the main chain among chains constituting the resin containing structural units. A terminal of a resin refers to a structure that caps the main chain, and is, for example, a structure derived from an end-capping agent or the like.

In the present description, to overlap means to overlap directly or indirectly with respect to the z-axis direction. That is, when one layer and another layer overlap, the layers may be in contact with each other, or still another layer may exist between those layers.

In the present description, a silicone structure refers to any structure having an Si—O—Si bond as a main skeleton and having two organic groups on a silicon atom. That is, silicon atoms in the silicone structure are each bonded to two organic groups and two oxygen atoms. A siloxane structure refers to any structure having an Si—O—Si bond as a main skeleton and having one organic group on a silicon atom. That is, silicon atoms in the siloxane structure are each bonded to one organic group and three oxygen atoms.

### <Film>

The first aspect of the film of the present invention is a film including: an (SA) binder resin; and an (SD) thermally conductive filler, wherein the (SD) thermally conductive filler includes an (SD1) first thermally conductive filler and an (SD2) second thermally conductive filler, the (SD1) first thermally conductive filler has an average primary particle size of 1.0 to 200 μm, the (SD2) second thermally conductive filler has an average primary particle size of 0.010 μm or more and less than 1.0 μm, the film has a shear strain of 0.70 to 20 at −50 °C, and the film has a thermal conductivity 0.10 to 5.0 W/(m·K) at 25 °C. With the configuration as described above, the present invention can provide a film that is superior in adhesion for joining members to each other even at a cryogenic temperature of about −50 °C and having high thermal cycle reliability. This is considered to be because the shear strain at −50 °C. can be adjusted within a specific range because the slope in a stress-strain curve with the vertical axis as the stress and the horizontal axis as the strain decreases (the strain per unit stress increases) due to the anchor effect produced by the combined use of fillers having a specific average primary particle size. Therefore, it is presumed that the film has flexibility high enough for alleviating a difference in coefficient of thermal expansion between members to be joined by the film through increase in the shear strain at a cryogenic temperature of about −50 °C, and followability to each member is improved, so that adhesion and thermal cycle reliability are improved.

It is also considered to be because when the film contains two types of thermally conductive fillers, each having a specific average primary particle size, the heat generated in a member to be joined can be efficiently radiated, and the internal stress caused by the temperature rise of the member can be reduced. In addition, it is also presumed to be because the heat stored in the film can be reduced, and the change in mechanical properties due to the temperature rise of the film can be suppressed.

It is also considered to be because by increasing the thermal conductivity of the film, the heat generated in a member to be joined can be efficiently radiated, and the internal stress caused by the temperature rise of the member can be reduced. In addition, it is also presumed to be because the heat stored in the film can be reduced, and the change in mechanical properties due to the temperature rise of the film can be suppressed.

The film refers to any film capable of forming a self-supporting film as a single film. It is preferable that the film has adhesiveness, and it is also preferable that a plurality of members is joined. The phrase “capable of forming a self-supporting film as a single film” means that a film having a width of 5.0 cm or more, a length of 5.0 cm or more, and a thickness of 5.0 μm or more can be formed without a support.

The second aspect of the film of the present invention is a film including: an (SA) binder resin; and an (SD) thermally conductive filler, wherein the film has an elastic modulus of 0.10 to 200 MPa at −50 °C, and the film has a thermal conductivity of 0.10 to 5.0 W/(m·K) at 25 °C.

With the configuration as described above, the present invention can provide a film that is superior in adhesion for joining members to each other even at a cryogenic temperature of about −50 °C and having high thermal cycle reliability. This is presumed to be because the internal stress caused by the difference in coefficient of thermal expansion between the members to be joined by the film can be reduced by reducing the elastic modulus at a cryogenic temperature of about −50 °C, and the followability to each member is improved, so that the adhesion and the thermal cycle reliability are improved.

It is also considered to be because by increasing the thermal conductivity of the film, the heat generated in a member to be joined can be efficiently radiated, and the internal stress caused by the temperature rise of the member can be reduced. In addition, it is also presumed to be because the heat stored in the film can be reduced, and the change in mechanical properties due to the temperature rise of the film can be suppressed.

### <(SA) Binder Resin>

The film of the present invention contains an (SA) binder resin. The (SA) binder resin is a resin having heat resistance with which at least a part of the resin remains in a cured product obtained by curing a composition for forming the film of the present invention. The (SA) binder resin is preferably a resin that will form or has formed a cross-linked structure with the (SB) compound described later. The cross-linked structure is preferably one formed via a reaction, and is not particularly limited, for example, one formed by heating or by irradiation with an energy ray.

The (SA) binder resin preferably has an acidic group or a structure derived from an acidic group, and more preferably has an acidic group or a structure derived from an acidic group in a repeating unit of the resin. The acidic group is preferably a phenolic hydroxy group, a hydroxyimide group, a hydroxyamide group, a silanol group, a 1, 1-bis(trifluoromethyl)methylol group, a mercapto group, a carboxy group, a carboxylic anhydride group, or a sulfonic acid group, and more preferably a phenolic hydroxy group, a carboxy group, or a carboxylic anhydride group. When the (SA) binder resin satisfies the following conditions (P1a) and/or (P2a) described later, or when the film of the present invention satisfies at least one of the following conditions (S3α) and (S3β) described later, the acidic group is preferably a phenolic hydroxy group, a hydroxyimide group, a hydroxyamide group, a silanol group, a mercapto group, a carboxy group, a carboxylic anhydride group, or a sulfonic acid group.

The acid equivalent of the (SA) binder resin is preferably 200 g/mol or more, more preferably 250 g/mol or more, and still more preferably 300 g/mol or more from the viewpoint of improving the adhesion and the thermal cycle reliability. Meanwhile, the acid equivalent of the (SA) binder resin is preferably 600 g/mol or less, more preferably 500 g/mol or less, and still more preferably 450 g/mol or less from the viewpoint of improving the thermal cycle reliability.

The (SA) binder resin having an acidic group or a structure derived from an acidic group is suitable for adjusting the shear strain at −50 °C to be within a range of 0.70 to 20 and/or adjusting the elastic modulus at −50 °C to be within a range of 0.10 to 200 MPa through the formation of a cross-linked structure with an (SB) compound described later. The acidic group or the structure derived from an acidic group can improve the dispersibility of an (SD) thermally conductive filler described later by interaction with the filler, so that the effect of improving the thermal conductivity of the film becomes remarkable. As a result, followability to each member is improved, and thus it is presumed that adhesion and thermal cycle reliability are improved.

### <(SA1) Resin>

The (SA) binder resin preferably includes an (SA1) resin having a silicone structure and/or a siloxane structure in a structural unit of the resin (hereinafter, “(SA1) resin”) from the viewpoint of improving the adhesion at a cryogenic temperature of about −50 °C and improving the thermal cycle reliability.

The silicone structure and the siloxane structure of the (SA1) resin are each preferably a divalent or more structure which is bonded to at least two alkylene groups and in which these alkylene groups are interposed. The divalent or more structure is more preferably trivalent or more, and still more preferably tetravalent or more. Meanwhile, the divalent or more structure is preferably hexavalent or less.

The number of the silicon atoms of the silicone structure and/or the siloxane structure in the (SA1) resin is preferably 5 or more, more preferably 10 or more, still more preferably 15 or more, and particularly preferably 20 or more. Meanwhile, the number of the silicon atoms is preferably 30 or less, more preferably 27 or less, and still more preferably 25 or less.

In the (SA1) resin, the silicone structure is preferably a dialkylsilicone structure and/or a monoalkylsilicone structure, and the siloxane structure is preferably a monoalkylsiloxane structure.

The number of the carbon atoms of an alkyl group of the dialkylsilicone structure and the monoalkylsilicone structure is preferably 1 or more, more preferably 2 or more, and still more preferably 3 or more. Meanwhile, the number of the carbon atoms in the alkyl group is preferably 10 or less, more preferably 8 or less, and still more preferably 6 or less.

The number of the carbon atoms of the alkyl group of the monoalkylsiloxane structure is preferably 1 or more, more preferably 2 or more, and still more preferably 3 or more. Meanwhile, the number of the carbon atoms in the alkyl group is preferably 10 or less, more preferably 8 or less, and still more preferably 6 or less.

In the (SA1) resin, a content ratio of aliphatic groups bonding to silicon atoms in the silicone structure and/or the siloxane structure accounting for in a total of the aliphatic groups and aromatic groups bonding to silicon atoms in the silicone structure and/or the siloxane structure is preferably 80 mol % or more, more preferably 85 mol % or more, and still more preferably 90 mol % or more, from the viewpoint of improving the adhesion and improving the thermal cycle reliability. Meanwhile, the content ratio of the aliphatic groups to the total of the aliphatic groups and the aromatic groups is preferably 100 mol % or less, more preferably 99 mol % or less, and still more preferably 97 mol % or less, from the viewpoint of improving the thermal cycle reliability.

The aliphatic group of the (SA1) resin is preferably an alkyl group. The preferred number of carbon atoms of the alkyl group is also the same as described above. The alkyl group is preferably a methyl group, an ethyl group, a propyl group, a butyl group, or a hexyl group. The number of the carbon atoms of the aromatic group of the (SA1) resin is preferably 6 or more, more preferably 7 or more, and still more preferably 8 or more. Meanwhile, the number of the carbon atoms of the aromatic group is preferably 15 or less, more preferably 12 or less, and still more preferably 10 or less. The aromatic group is preferably a phenyl group, a tolyl group, a xylyl group, a phenoxy group, a tolyloxy group, or a xylyloxy group.

The (SA1) resin as described above is suitable for adjusting the shear strain at −50 °C to be within a range of 0.70 to 20 and/or adjusting the elastic modulus at −50 °C to be within a range of 0.10 to 200 MPa by a flexible skeleton derived from the silicone structure or the siloxane structure.

### <(SA1-1) Resin>

The (SA1) resin preferably includes an (SA1-1) resin containing one or more selected from the group consisting of an imide structure, an amide structure, and an oxazole structure in a structural unit of the resin “hereinafter, (SA1-1) resin” from the viewpoint of improving the adhesion at a cryogenic temperature of about −50 °C and improving the thermal cycle reliability.

The (SA1-1) resin is a resin containing one or more selected from the group consisting of an imide structure, an amide structure, and an oxazole structure in a structural unit of the resin, such as a polyimide, a polybenzoxazole, precursors thereof, and a copolymer composed of two or more among them.

The (SA1-1) resin preferably includes one or more selected from the group consisting of a polyimide, a polyimide precursor, a polybenzoxazole, a polybenzoxazole precursor, a polyamideimide, a polyamideimide precursor, a polyamide, and a copolymer composed of two or more among them (hereinafter, “polyimide-based resin”) from the viewpoint of improving the adhesion and improving the thermal cycle reliability. The (SA1-1) resin may be a single resin or a copolymer thereof.

The (SA1-1) resin preferably has one or more selected from the group consisting of the following residues (1) and (2).
(1) A diamine residue, diamine derivative residue, bisaminophenol compound residue, or bisaminophenol compound derivative residue containing a silicone structure and/or a siloxane structure.
(2) A tetracarboxylic acid residue, tetracarboxylic acid derivative residue, tricarboxylic acid residue, tricarboxylic acid derivative residue, dicarboxylic acid residue, or dicarboxylic acid derivative residue containing a silicone structure and/or a siloxane structure.

The residue (1) of the (SA1-1) resin is a diamine residue containing a silicone structure and/or a siloxane structure, a diamine derivative residue containing a silicone structure and/or a siloxane structure, a bisaminophenol compound residue containing a silicone structure and/or a siloxane structure, or a bisaminophenol compound derivative residue containing a silicone structure and/or a siloxane structure.

The residue (2) of the (SA1-1) resin is a tetracarboxylic acid residue containing a silicone structure and/or a siloxane structure, a tetracarboxylic acid derivative residue containing a silicone structure and/or a siloxane structure, a tricarboxylic acid residue containing a silicone structure and/or a siloxane structure, a tricarboxylic acid derivative residue containing a silicone structure and/or a siloxane structure, a dicarboxylic acid residue containing a silicone structure and/or a siloxane structure, or a dicarboxylic acid derivative residue containing a silicone structure and/or a siloxane structure.

The residue (1) of the (SA1-1) resin is divalent or more, and preferably trivalent or more. Meanwhile, the residue (1) is preferably hexavalent or less, and more preferably tetravalent or less. The residue (2) of the (SA1-1) resin is divalent or more, preferably trivalent or more, and more preferably tetravalent or more. Meanwhile, the residue (2) is preferably hexavalent or less.

The residue (2) of the (SA1-1) resin is preferably a tetracarboxylic dianhydride residue, tricarboxylic anhydride residue, or dicarboxylic anhydride residue containing a silicone structure and/or a siloxane structure. The residue (2) preferably has an acid anhydride residue containing a phthalic acid structure, an acid anhydride residue containing a succinic acid structure, or an acid anhydride residue containing a maleic acid structure.

In the (SA1-1) resin, the total content ratio of the residue (1) and the residue (2) accounting for in the total of all amine residues and all carboxylic acid residues is preferably 10 mol % or more, more preferably 30 mol % or more, still more preferably 40 mol % or more, further preferably 60 mol % or more, and particularly preferably 80 mol % or more, from the viewpoint of improving the adhesion at a cryogenic temperature of about −50 °C and improving the thermal cycle reliability. Meanwhile, the total content ratio of the residue (1) and the residue (2) accounting for in the total of all the amine residues and all the carboxylic acid residues is preferably 100 mol % or less, more preferably 99 mol % or less, and still more preferably 97 mol % or less from the viewpoint of improving the thermal cycle reliability.

In the (SA1-1) resin, the total content ratio of the residue (1) accounting for in all the amine residues is preferably 10 mol % or more, more preferably 30 mol % or more, still more preferably 40 mol % or more, further preferably 60 mol % or more, and particularly preferably 80 mol % or more, from the viewpoint of improving the adhesion at a cryogenic temperature of about −50 °C and improving the thermal cycle reliability. Meanwhile, the total content ratio of the residue (1) accounting for in all the amine residues is preferably 100 mol % or less, more preferably 99 mol % or less, and still more preferably 97 mol % or less, from the viewpoint of improving the thermal cycle reliability.

In the (SA1-1) resin, the total content ratio of the residue (2) accounting for in all carboxylic acid residues is preferably 10 mol % or more, more preferably 30 mol % or more, still more preferably 40 mol % or more, further preferably 60 mol % or more, and particularly preferably 80 mol % or more, from the viewpoint of improving the adhesion at a cryogenic temperature of about −50 °C and improving the thermal cycle reliability. Meanwhile, the total content ratio of the residue (2) accounting for in all the carboxylic acid residues is preferably 100 mol % or less, more preferably 99 mol % or less, and still more preferably 97 mol % or less, from the viewpoint of improving the thermal cycle reliability.

The residue (1) in the (SA1-1) resin preferably has a structure represented by the general formula (11). The residue (2) in the (SA1-1) resin preferably has a structure represented by the general formula (12).

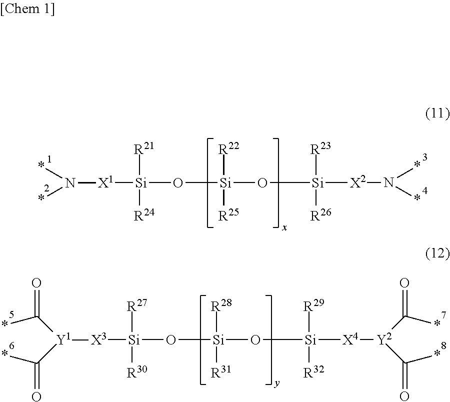

In the general formulas (11) and (12), X¹ to X⁴ each independently represent a direct bond, an oxygen atom, an alkylene group having 1 to 30 carbon atoms, an alkyleneoxy group having 1 to 30 carbon atoms, or an arylene group having 6 to 30 carbon atoms. Y¹ and Y² each independently represent a trivalent organic group having 1 to 20 carbon atoms. R²¹ to R³² each independently represent an alkyl group having 1 to 30 carbon atoms, an aryl group having 6 to 30 carbon atoms, or an aryloxy group having 6 to 30 carbon atoms. x and y each independently represent an integer of 1 to 100. *¹ to *⁸ each independently represent a bonding point to another structure.

In the general formulas (11) and (12), the trivalent organic group having 1 to 20 carbon atoms is preferably a trivalent hydrocarbon group having 1 to 20 carbon atoms. The alkyl group having 1 to 30 carbon atoms is preferably a methyl group, an ethyl group, a propyl group, a butyl group, or a hexyl group. The aryl group having 6 to 30 carbon atoms is preferably a phenyl group, a tolyl group, or a xylyl group. The aryloxy group having 6 to 30 carbon atoms is preferably a phenoxy group, a tolyloxy group, or a xylyloxy group. The alkylene group having 1 to 30 carbon atoms is preferably a methylene group, an ethylene group, a propylene group, a butylene group, or a hexylene group. The arylene group having 6 to 30 carbon atoms is preferably a phenylene group, a tolylene group, or a xylylene group. The alkyl group and the alkylene group each has a linear structure or a branched structure. The alkyl group, the aryl group, the aryloxy group, the alkylene group, and the arylene group each may have a hetero atom, and each may be either unsubstituted or substituted.

x is preferably 6 or more, more preferably 15 or more, still more preferably 24 or more, further preferably 28 or more, and particularly preferably 32 or more, from the viewpoint of improving the adhesion at a cryogenic temperature of about −50 °C and improving the thermal cycle reliability. Meanwhile, x is preferably 100 or less, more preferably 70 or less, still more preferably 50 or less, and particularly preferably 44 or less, from the viewpoint of improving the adhesion at a cryogenic temperature of about −50 °C and improving the thermal cycle reliability.

y is preferably 6 or more, more preferably 11 or more, still more preferably 15 or more, and particularly preferably 18 or more, from the viewpoint of improving the adhesion at a cryogenic temperature of about −50 °C and improving the thermal cycle reliability. Meanwhile, y is preferably 100 or less, more preferably 50 or less, still more preferably 30 or less, and particularly preferably 26 or less, from the viewpoint of improving the adhesion at a cryogenic temperature of about −50 °C and improving the thermal cycle reliability.

In the (SA1-1) resin, the total content ratio of the structures having x of 6 or more and 100 or less among the structures represented by the general formula (11) accounting for in the residue (1) is preferably 50 mol % or more, more preferably 70 mol % or more, and still more preferably 90 mol % or more, from the viewpoint of the effect of the above invention. Meanwhile, the total content ratio of the structures having x of 6 or more and 100 or less among the structures represented by the general formula (11) is preferably 100 mol % or less, more preferably 99 mol % or less, and still more preferably 97 mol % or less, from the viewpoint of the effect of the present invention.

In the (SA1-1) resin, the total content ratio of the structures having y of 6 or more and 100 or less among the structures represented by the general formula (12) accounting for in the residue (2) is preferably 50 mol % or more, more preferably 70 mol % or more, and still more preferably 90 mol % or more, from the viewpoint of the effect of the above invention. Meanwhile, the total content ratio of the structures having y of 6 or more and 100 or less among the structures represented by the general formula (12) is preferably 100 mol % or less, more preferably 99 mol % or less, and still more preferably 97 mol % or less, from the viewpoint of the effect of the present invention.

The (SA1-1) resin as described above is suitable for adjusting the shear strain at −50 °C to be within a range of 0.70 to 20 and/or adjusting the elastic modulus at −50 °C to be within a range of 0.10 to 200 MPa by improving mechanical properties by an imide structure, an amide structure, or an oxazole structure in addition to a flexible skeleton derived from a silicone structure or a siloxane structure. In addition, the (SA1-1) resin is considered to function as an anchor at an interface with a member at a cryogenic temperature due to coordination ability to each member derived from an imide structure, an amide structure, or an oxazole structure. Therefore, it is presumed that followability to each member is improved, and the adhesion and the thermal cycle reliability are improved.

Examples of an amine monomer for introducing the residue (1) into the (SA1-1) resin include X-22-161A (amino group equivalent: 800 g/mol), X-22-161B (amino group equivalent: 1,500 g/mol), KF-8012 (amino group equivalent: 2,200 g/mol), KF-8010 (amino group equivalent: 430 g/mol), or KF-8008 (amino group equivalent: 5,700 g/mol) (all manufactured by Shin-Etsu Chemical Co., Ltd.), which are dual-end amino group-modified dimethyl silicones, or X-22-1660B-3 (amino group equivalent: 2,200 g/mol) or X-22-9409 (amino group equivalent: 650 g/mol) (both manufactured by Shin-Etsu Chemical Co., Ltd.), which are dual-end amino group-modified methyl phenyl silicones.

Examples of the acid monomer for introducing the residue (2) into the (SA1-1) resin include X-22-168AS (acid anhydride equivalent: 500 g/mol), X-22-168A (acid anhydride equivalent: 1,000 g/mol), X-22-168B (acid anhydride equivalent: 1,600 g/mol), and X-22-168-P5-B (acid anhydride equivalent: 2,100 g/mol) (all manufactured by Shin-Etsu Chemical Co., Ltd.).

The (SA1-1) resin preferably has a residue having an acidic group or a residue having a structure derived from an acidic group, and more preferably has a residue having an acidic group or a residue having a structure derived from an acidic group in a repeating unit of the resin. Examples of the amine monomer or acid monomer for introducing such a residue into the (SA1-1) resin include bis(3-amino-4-hydroxyphenyl)methane, 1,1-bis(3-amino-4-hydroxyphenyl)ethane, 2,2-bis(3-amino-4-hydroxyphenyl)propane, 2,2-bis(3-amino-4-hydroxyphenyl)hexafluoropropane, bis(3-amino-4-hydroxyphenyl)sulfone, bis[4-(4-aminophenoxy)phenyl]ether, bis(3-amino-4-hydroxyphenyl)ether, 9,9-bis(3-amino-4-hydroxyphenyl)fluorene, N,N′-bis [5,5′-hexafluoropropane-2, 2-diyl-bis(2-hydroxyphenyl)]bis(3-aminobenzoic acid amide), or N,N′-bis [5,5′-hexafluoropropane-2,2-diyl-bis(2-hydroxyphenyl)]bis(3,4-dicarboxybenzoic acid amide).

### <Polyimide-Based Resin>

Examples of the polyimide precursor include a polyamide acid, a polyamide acid ester, a polyamide acid amide, and a polyisoimide. Examples of the polyimide include a resin obtained by dehydrating and cyclizing a polyimide precursor by heating or a reaction using a catalyst.

Examples the polybenzoxazole precursor include a polyhydroxyamide. Examples of the polybenzoxazole include a resin obtained by dehydrating and cyclizing a polybenzoxazole precursor by heating or a reaction using a catalyst.

Examples of the polyamideimide precursor include a resin obtained by reacting a tricarboxylic anhydride or the like with a diamine or the like. Examples of the polyamideimide include a resin obtained by dehydrating and cyclizing a polyamideimide precursor by heating or a reaction using a catalyst.

Examples of the polyamide include a resin obtained by reacting a dicarboxylic acid, a corresponding dicarboxylic acid active diester, or the like with a diamine, a diisocyanate compound, or the like. The polyimide, the polyimide precursor, the polybenzoxazole, the polybenzoxazole precursor, the polyamideimide, and the polyamideimide precursor described above may be copolymers with a polyamide.

The polyimide-based resin may have a structure capped with a monoamine, a dicarboxylic anhydride, or a monocarboxylic acid derivative at an end of the resin. The polyimide-based resin preferably has, at an end of the resin, a cross-linkable group or a radically polymerizable group capable of reacting with the resin or the like, and more preferably has a maleimide group or a nadimide group, from the viewpoint of improving the adhesion and improving the thermal cycle reliability.

### <Content of Fluorine Element in Structure of (SA) Binder Resin>

It is also preferable that the (SA) binder resin satisfies the following condition (P1a) from the viewpoint of improving the adhesion at a cryogenic temperature of about −50 °C and improving the thermal cycle reliability. The (SA) binder resin more preferably further satisfies the following condition (P2a). When the (SA) binder resin is a polyimide-based resin, it is also preferable to satisfy the following condition (P1a) from the same viewpoint, and it is more preferable to further satisfy the following condition (P2a). When the (SA) binder resin satisfies the following condition (P2a), the following condition (P1a) is satisfied by fluoride ions in the structure of the (SA) binder resin.
(P1a) The content of fluorine element in the structure of the (SA) binder resin is 10,000 ppm by mass or less.
(P2a) The content of fluoride ion in the structure of the (SA) binder resin is 10,000 ppm by mass or less.

The content of fluorine element accounting for in the structure of the (SA) binder resin is preferably more than 0.000 ppm by mass, more preferably 0.010 ppm by mass or more, still more preferably 0.030 ppm by mass or more, further preferably 0.050 ppm by mass or more, particularly preferably 0.070 ppm by mass or more, and especially preferably 0.10 ppm by mass or more, from the viewpoint of the above-described effect of the invention. Meanwhile, the content of fluorine element is preferably 10,000 ppm by mass or less, more preferably 5,000 ppm by mass or less, further preferably 1,000 ppm by mass or less, further preferably 500 ppm by mass or less, further preferably 300 ppm by mass or less, further preferably 100 ppm by mass or less, further preferably 50 ppm by mass or less, further preferably 30 ppm by mass or less, further preferably 10 ppm by mass or less, further preferably 5 ppm by mass or less, particularly preferably 3 ppm by mass or less, and especially preferably 1 ppm by mass or less, from the viewpoint of the above-described effect of the invention.

Fluorine element has many lone pairs, and it is considered that when fluorine element is contained in the structure of the (SA) binder resin, a coordination bond to the surface of a member is easily formed by electron donation utilizing these electron pairs.

A preferred range of the content of fluoride ion in the structure of the (SA) binder resin is also the same as the preferred range of the content of fluorine element in the structure of the binder resin (SA) with respect to each of the upper limit value and the lower limit value.

The content of fluorine element in the structure of the (SA) binder resin may be 0.000 ppm by mass. The content of fluoride ion in the structure of the (SA) binder resin may also be 0.000 ppm by mass.

When the film is made containing the (SA) binder resin in which the content of fluorine element is equal to or less than the specific value, the content of fluorine element or the fluoride ion in these resins or the anion-containing fluorine element derived from these resins is equal to or less than the specific value, and thus it is presumed that the local interaction with the surface of a member to be joined is improved due to hydrogen bonding of each component in the film, the electronegativity of a fluorine atom, and the like. In addition, it is considered that by intentionally setting the content of the above components to a specific value or less, the polarization structure or the charge balance in the film is controlled, and the influence of an ionic component or the like that adversely affects the mechanical properties of the film in a cooling/heating cycle can be suppressed. It is presumed that owing to these actions, fluorine element functions as an anchor at an interface with a member at a cryogenic temperature, so that followability to each member is improved, and the adhesion and the thermal cycle reliability are improved.

### <(SA1-2) Resin>

The (SA1) resin preferably contains an (SA1-2) silicone resin and/or a polysiloxane (hereinafter, “(SA1-2) resin”) from the viewpoint of improving the adhesion at a cryogenic temperature of about −50 °C and improving the thermal cycle reliability.

Examples of the (SA1-2) resin include a resin obtained by hydrolysis and dehydration condensation of one or more selected from the group consisting of a bifunctional organosilane, a trifunctional organosilane, a tetrafunctional organosilane, and a monofunctional organosilane. In the (SA1-2) resin, a functional group may be introduced into an organic group on a silicon atom by hydrosilylation.

The silicone resin is a resin having, as a main skeleton, a structural unit containing a silicone structure. That is, a bifunctional organosilane unit having two organic groups on a silicon atom and having a silicon atom bonded to two oxygen atoms is contained as a main skeleton. In the silicone resin, the content ratio of the bifunctional organosilane unit accounting for in all the organosilane units is 50 mol % or more, preferably 60 mol % or more, and still more preferably 70 mol % or more. Meanwhile, the content ratio of the bifunctional organosilane unit preferably 100 mol % or less, more preferably 90 mol % or less, and still more preferably 80 mol %.

Polysiloxane is a resin having, as a main skeleton, a structural unit containing a siloxane structure. That is, a trifunctional organosilane unit that has one organic group having two organic groups on a silicon atom and has a silicon atom bonded to three oxygen atoms is contained as a main skeleton. In the silicone resin, the content ratio of the trifunctional organosilane unit accounting for in all the organosilane units is 50 mol % or more, preferably 60 mol % or more, and still more preferably 70 mol % or more. Meanwhile, the content ratio of the trifunctional organosilane unit preferably 100 mol % or less, more preferably 90 mol % or less, and still more preferably 80 mol %.

The (SA1-2) resin preferably has one or more selected from the group consisting of the following units (3) and (4).
(3) A bifunctional organosilane unit, trifunctional organosilane unit, tetrafunctional organosilane unit, or monofunctional organosilane unit having an aliphatic group.
(4) A bifunctional organosilane unit, trifunctional organosilane unit, tetrafunctional organosilane unit, or monofunctional organosilane unit having an aromatic group.

The silicone resin preferably has a bifunctional organosilane unit having an aliphatic group and/or a bifunctional organosilane unit having an aromatic group. The polysiloxane preferably has a trifunctional organosilane unit having an aliphatic group and/or a trifunctional organosilane unit having an aromatic group.

The aliphatic group of the (SA1-2) resin is preferably an alkyl group. The number of the carbon atoms of the alkyl group is preferably 1 or more, more preferably 2 or more, and still more preferably 3 or more. Meanwhile, the number of the carbon atoms of the alkyl group is preferably 10 or less, more preferably 8 or less, and still more preferably 6 or less. The alkyl group is preferably a methyl group, an ethyl group, a propyl group, a butyl group, or a hexyl group.

The number of the carbon atoms of the aromatic group of the (SA1-2) resin is preferably 6 or more, more preferably 7 or more, and still more preferably 8 or more. Meanwhile, the number of the carbon atoms of the aromatic group is preferably 15 or less, more preferably 12 or less, and still more preferably 10 or less. The aromatic group is preferably a phenyl group, a tolyl group, a xylyl group, a phenoxy group, a tolyloxy group, or a xylyloxy group.

In the (SA1-2) resin, the total content ratio of the unit (3) accounting for in all the organosilane units is preferably 70 mol % or more, more preferably 80 mol % or more, still more preferably 85 mol % or more, and particularly preferably 90 mol % or more, from the viewpoint of improving the adhesion at a cryogenic temperature of about −50 °C and improving the thermal cycle reliability. Meanwhile, the total content ratio of the unit (3) accounting for in all the organosilane units is preferably 100 mol % or less, more preferably 99 mol % or less, still more preferably 97 mol % or less, and particularly preferably 95 mol % or less from the viewpoint of improving the thermal cycle reliability.

In the (SA1-2) resin, the content ratio fraction of the unit (4) accounting for in all the organosilane units is preferably 1.0 mol % or more, more preferably 3.0 mol % or more, and still more preferably 5.0 mol % or more from the viewpoint of improving the thermal cycle reliability. Meanwhile, the total content ratio of the unit (4) accounting for in all the organosilane units is preferably 20 mol % or less, more preferably 15 mol % or less, and still more preferably 10 mol % or less, from the viewpoint of improving the adhesion at a cryogenic temperature of about −50 °C and improving the thermal cycle reliability.

The (SA1-2) resin preferably further has the following unit (5).
(5) A bifunctional organosilane unit, trifunctional organosilane unit, tetrafunctional organosilane unit, or monofunctional organosilane unit having an epoxy group.

The (SA1-2) resin preferably has a bifunctional organosilane unit having an epoxy group and/or a trifunctional organosilane unit having an epoxy group.

In the (SA1-2) resin, the total content ratio of the unit (5) accounting for in all the organosilane units is preferably 1.0 mol % or more, more preferably 3.0 mol % or more, and still more preferably 5.0 mol % or more, from the viewpoint of improving the adhesion at a cryogenic temperature of about −50 °C and improving the thermal cycle reliability. Meanwhile, the total content ratio of the unit (5) accounting for in all the organosilane units is preferably 20 mol % or less, more preferably 15 mol % or less, and still more preferably 10 mol % or less, from the viewpoint of improving the thermal cycle reliability.

The (SA1-2) resin as described above has a structural unit containing a silicone structure or a siloxane structure as a main skeleton and is superior in flexibility, and thus is suitable for adjusting the shear strain at −50 °C to be within a range of 0.70 to 20 and/or adjusting the elastic modulus at −50 °C to be within a range of 0.10 to 200 MPa.

### <Other (SA) Binder Resin>

The film of the present invention may contain another (SA) binder resin. The other (SA) binder resin is preferably a maleimide resin, a maleimide-styrene resin, a maleimide-triazine resin, a cardo-based resin, an epoxy (meth) acrylate resin, an acrylic resin, a phenol resin, a phenol aralkyl resin, polyhydroxystyrene, a tetrafluoroethylene-based polymer, a polyphenylene ether, a liquid crystal polymer, a cycloolefin polymer, or a benzocyclobutene resin. As these resins, known resins may be used. The other (SA) binder resin preferably has an acidic group or a structure derived from an acidic group, and more preferably has an acidic group or a structure derived from an acidic group in a repeating unit of the resin. Examples and preferred descriptions of the acidic group are the same as those of the acidic group of the (SA) binder described above.

The maleimide resin is a resin having at least two maleimide groups on at least one of a main chain of the resin, a side chain of the resin, and an end of the resin. The maleimide resin is a resin different from the polyimide-based resin.

Examples of the maleimide-styrene resin include a resin obtained by further radically copolymerizing a styrene derivative with the maleimide resin described above. Another example is a resin obtained by radically copolymerizing a maleimide compound and a styrene derivative with other copolymerization components such as a (meth)acrylic acid derivative.

Examples of the maleimide-triazine resin include a resin obtained by further reacting a compound having a triazine structure and/or an aromatic cyanic acid ester compound with the maleimide resin described above. Another example is a resin obtained by reacting a maleimide compound with a compound having a triazine structure and/or an aromatic cyanic acid ester compound.

Examples of the maleimide-oxazine resin include a resin obtained by further reacting a compound having a benzoxazine structure with the maleimide resin described above. Another example is a resin obtained by reacting a maleimide compound with a compound having a benzoxazine structure.

The total content ratio of the (SA1) resin accounting for in 100% by mass in total of the (SA) binder resin is preferably 50% by mass or more, more preferably 60% by mass or more, still more preferably 70% by mass or more, and particularly preferably 80% by mass or more, from the viewpoint of improving the adhesion at a cryogenic temperature of about −50 °C and improving the thermal cycle reliability. Meanwhile, the total content ratio of the (SA1) resin is preferably 100% by mass or less, more preferably 95% by mass or less, and still more preferably 90% by mass or less from the viewpoint of improving the adhesion.

The total content ratio of the (SA) binder resin in the film is preferably 10% by volume or more, more preferably 15% by volume or more, and still more preferably 20% by volume or more. Meanwhile, the total content ratio of the (SA) binder resin in the film is preferably 50% by volume or less, more preferably 40% by volume or less, and still more preferably 30% by volume or less.

<(SB) Epoxy Compound or Compound Having Structure Derived from Epoxy Compound>

The film of the present invention preferably contains (SB) an epoxy compound or a compound having a structure derived from an epoxy compound (hereinafter, “(SB) compound”). The (SB) compound may be an epoxy compound or a compound having a structure derived from an epoxy compound. The epoxy compound may be a compound in the composition for forming the film of the present invention. As described above, the (SB) compound is preferably a compound that is to form a cross-linked structure with the (SA) binder resin or a compound that has formed a cross-linked structure with the (SA) binder resin.

The number of the epoxy groups of the (SB) compound is preferably 2 or more, and more preferably 3 or more. Meanwhile, the number of the epoxy groups is preferably 6 or less, and more preferably 4.

It is preferable from the viewpoint of improving the adhesion at a cryogenic temperature of about −50 °C and improving the thermal cycle reliability that the film of the present invention contains an (SB) compound, wherein the (SB) compound includes one or more selected from the group consisting of an (SB1) compound having a structure containing an oxyalkylene group (hereinafter, “(SB1) compound”), an (SB2) compound having a structure containing at least two aromatic structures and having a structure containing an oxyalkylene group (hereinafter, “(SB2) compound”), and an (SB3) compound having a tertiary amine structure bonded to an arylene group and two divalent organic groups (hereinafter, “(SB3) compound”). The (SB1) compound, the (SB2) compound, and the (SB3) compound may be compounds having a structure derived from each of the above compounds. The (SB1) compound is a compound different from the (SB2) compound and does not have any structure containing an aromatic structure.

The oxyalkylene groups of the (SB1) compound are preferably divalent or more, and more preferably trivalent or more. Meanwhile, the oxyalkylene groups of the (SB1) compound are preferably hexavalent or less, and more preferably tetravalent or less.

The number of the oxyalkylene groups of the (SB1) compound is preferably 1 or more, more preferably 4 or more, still more preferably 6 or more, and particularly preferably 10 or more. Meanwhile, the number of the oxyalkylene groups is preferably 20 or less, more preferably 17 or less, and still more preferably 15 or less. The number of the carbon atoms of each oxyalkylene group of the (SB1) compound is preferably 1 or more, and more preferably 2 or more. Meanwhile, the number of the carbon atoms of the oxyalkylene group is preferably 6 or less, more preferably 4 or less, and still more preferably 3 or less.

The (SB1) compound preferably includes one or more selected from the group consisting of compounds having a structure represented by the general formula (21) and compounds represented by the general formula (22).

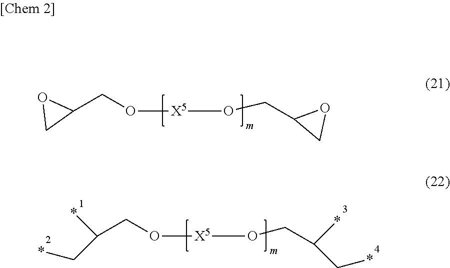

In the general formulas (21) and (22), X⁵ represents an alkylene group having 1 to 30 carbon atoms. m represents an integer 1 to 20. *¹ to *⁴ each independently represent a bonding point to another structure.

In the general formulas (21) and (22), the alkylene group having 1 to 30 carbon atoms is preferably a methylene group, an ethylene group, a propylene group, a butylene group, or a hexylene group. The alkylene group has a linear structure or a branched structure. The alkylene group may have a hetero atom and may be either unsubstituted or substituted.

The structure containing at least two aromatic structures of the (SB2) compound is preferably bonded to at least two oxyalkylene groups, and is preferably a divalent or more structure with the at least two oxyalkylene groups interposing therein. The divalent or more structure is more preferably trivalent or more. Meanwhile, the divalent or more structure is preferably hexavalent or less, and more preferably tetravalent or less.

The number of the carbon atoms of the aromatic structure of the (SB2) compound is preferably 6 or more, more preferably 7 or more, and still more preferably 8 or more. Meanwhile, the number of the carbon atoms of the aromatic structure is preferably 15 or less, more preferably 12 or less, and still more preferably 10 or less. The number of the aromatic structures of the (SB2) compound is preferably 2 or more, and more preferably 3 or more. Meanwhile, the number of the aromatic structures is preferably 6 or less, and more preferably 4 or less.

The structure containing at least two aromatic structures in the (SB2) compound preferably has a group linking at least two aromatic structures. The linking group is preferably a direct bond, an alkylene group having 1 to 6 carbon atoms, a halogenated alkylene group having 1 to 6 carbon atoms, a cycloalkylene group having 4 to 10 carbon atoms, an arylene group having 6 to 15 carbon atoms, an oxyaryleneoxy group having 6 to 15 carbon atoms, an ether linkage, a carbonyl group, a carboxylic acid ester linkage, an amide linkage, a urea linkage, a urethane linkage, a sulfonyl group, or a carbonic acid ester linkage.

The number of the oxyalkylene groups of the (SB2) compound is preferably 2 or more, more preferably 4 or more, still more preferably 6 or more, and particularly preferably 10 or more. Meanwhile, the number of the oxyalkylene groups is preferably 20 or less, more preferably 17 or less, and still more preferably 15 or less. The number of the carbon atoms of each oxyalkylene group of the (SB2) compound is preferably 1 or more, and more preferably 2 or more. Meanwhile, the number of the carbon atoms of the oxyalkylene group is preferably 6 or less, more preferably 4 or less, and still more preferably 3 or less.

The (SB2) compound preferably includes one or more selected from the group consisting of compounds represented by the general formula (23) and compounds having a structure represented by the general formula (24).

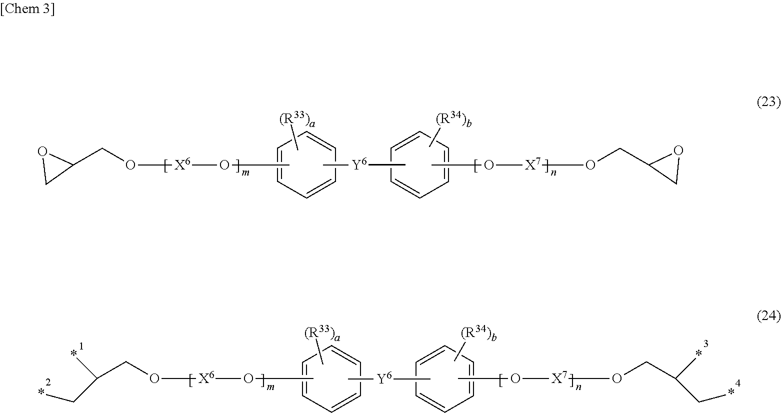

In the general formulas (23) and (24), X⁶ and X⁷ each independently represent an alkylene group having 1 to 30 carbon atoms. Y⁶ is preferably a direct bond, an alkylene group having 1 to 6 carbon atoms, a halogenated alkylene group having 1 to 6 carbon atoms, a cycloalkylene group having 4 to 10 carbon atoms, an arylene group having 6 to 15 carbon atoms, an oxyaryleneoxy group having 6 to 15 carbon atoms, an ether linkage, a carbonyl group, a carboxylic acid ester linkage, an amide linkage, a urea linkage, a urethane linkage, a sulfonyl group, or a carbonic acid ester linkage. R³³ and R³⁴ each independently represent an alkyl group having 1 to 6 carbon atoms, a cycloalkyl group having 4 to 7 carbon atoms, an aryl group having 6 to 15 carbon atoms, an alkoxy group having 1 to 6 carbon atoms, a hydroxy group, or a group forming a ring. The ring linked by the group forming a ring represents a monocyclic or condensed polycyclic hydrocarbon ring. a and b each independently represent an integer of 0 to 4. m and n each independently represent an integer of 1 to 20. *¹ to *⁴ each independently represent a bonding point to another structure.

In the general formulas (23) and (24), the alkyl group having 1 to 6 carbon atoms is preferably a methyl group, an ethyl group, or a propyl group. The cycloalkyl group having 4 to 7 carbon atoms is preferably a cyclobutyl group, a cyclopentyl group, or a cyclohexyl group. The aryl group having 6 to 15 carbon atoms is preferably a phenyl group, a tolyl group, or a xylyl group. The alkoxy group having 1 to 6 carbon atoms is preferably a methoxy group, an ethoxy group, or a propoxy group. The alkylene group having 1 to 30 carbon atoms is preferably a methylene group, an ethylene group, a propylene group, a butylene group, or a hexylene group. The alkylene group having 1 to 6 carbon atoms is preferably a methylene group, an ethylene group, or a propylene group. The cycloalkylene group having 4 to 7 carbon atoms is preferably a cyclobutylene group, a cyclopentylene group, or a cyclohexylene group. The alkyl group and the alkylene group each has a linear structure or a branched structure. The alkyl group, the cycloalkyl group, the aryl group, the alkoxy group, the alkylene group, and the cycloalkylene group may have a hetero atom, and may be either unsubstituted or substituted.

The tertiary amine structure of the (SB3) compound is bonded to an arylene group and two divalent organic groups, and is preferably a trivalent or more structure with the arylene group and the two divalent organic groups interposing. The trivalent or more structure is preferably hexavalent or less, and more preferably tetravalent or less.

The number of the carbon atoms of the arylene group of the (SB3) compound is preferably 6 or more, more preferably 7 or more, and still more preferably 8 or more. Meanwhile, the number of the carbon atoms in the arylene group is preferably 15 or less, more preferably 12 or less, and still more preferably 10 or less. The number of the aromatic rings in the arylene group of the (SB3) compound is preferably 1 or more, and more preferably 2 or more. Meanwhile, the number of the aromatic rings is preferably 6 or less, more preferably 4 or less, and still more preferably 3 or less.

The (SB3) compound also preferably has an oxyalkylene group. As an aspect in which the (SB3) compound has an oxyalkylene group, the arylene group in the (SB3) compound is preferably an arylene group bonded to an oxyalkylene group. The divalent organic groups in the (SB3) compound are each preferably a divalent aliphatic group, and more preferably an alkylene group. As an aspect in which the (SB3) compound has an oxyalkylene group, the divalent aliphatic groups in the (SB3) compound are each preferably a divalent aliphatic group bonded to an oxyalkylene group.

The number of the oxyalkylene groups of the (SB3) compound is preferably 2 or more, more preferably 4 or more, still more preferably 6 or more, and particularly preferably 10 or more. Meanwhile, the number of the oxyalkylene groups is preferably 20 or less, more preferably 17 or less, and still more preferably 15 or less. The number of the carbon atoms of each oxyalkylene group of the (SB3) compound is preferably 1 or more, and more preferably 2 or more. Meanwhile, the number of the carbon atoms of the oxyalkylene group is preferably 6 or less, more preferably 4 or less, and still more preferably 3 or less.

The (SB3) compound preferably includes one or more selected from the group consisting of compounds represented by the general formula (25) and compounds having a structure represented by the general formula (26).

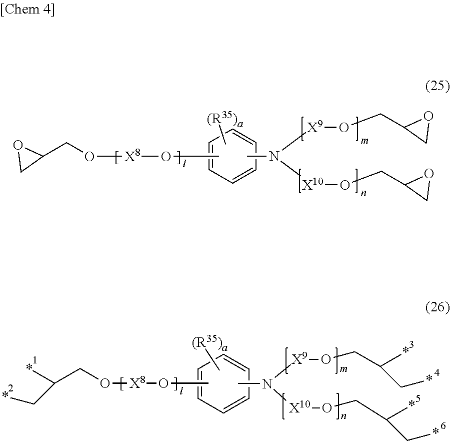

In the general formulas (25) and (26), X⁸, X⁹, and X¹⁰ each independently represent an alkylene group having 1 to 30 carbon atoms. R³⁵ represents an alkyl group having 1 to 6 carbon atoms, a cycloalkyl group having 4 to 7 carbon atoms, an aryl group having 6 to 15 carbon atoms, an alkoxy group having 1 to 6 carbon atoms, a hydroxy group, or a group forming a ring. The ring linked by the group forming a ring represents a monocyclic or condensed polycyclic hydrocarbon ring. a represents an integer of 0 to 4. 1, m, and n each independently represent an integer of 0 to 20. *¹ to *⁶ each independently represent a bonding point to another structure.

In the general formulas (25) and (26), the alkyl group having 1 to 6 carbon atoms is preferably a methyl group, an ethyl group, or a propyl group. The cycloalkyl group having 4 to 7 carbon atoms is preferably a cyclobutyl group, a cyclopentyl group, or a cyclohexyl group. The aryl group having 6 to 15 carbon atoms is preferably a phenyl group, a tolyl group, or a xylyl group. The alkoxy group having 1 to 6 carbon atoms is preferably a methoxy group, an ethoxy group, or a propoxy group. The alkylene group having 1 to 30 carbon atoms is preferably a methylene group, an ethylene group, a propylene group, a butylene group, or a hexylene group. The alkyl group and the alkylene group each has a linear structure or a branched structure. The alkyl group, the cycloalkyl group, the aryl group, the alkoxy group, and the alkylene group may have a hetero atom, and may be either unsubstituted or substituted.

The (SB1) compound, the (SB2), and the (SB3) compound as described above are suitable for adjusting the shear strain at −50 °C to be within a range of 0.70 to 20 and/or adjusting the elastic modulus at −50 °C to be within a range of 0.10 to 200 MPa by a flexible skeleton derived from an oxyalkylene group. In addition, the (SB) compound is considered to function as an anchor at an interface with a member at a cryogenic temperature due to coordination ability to each member derived from a tertiary amine structure. Therefore, it is presumed that followability to each member is improved, and the adhesion and the thermal cycle reliability are improved.

The total content of the (SB1) compound, the (SB2), and the (SB3) compound in the film is preferably 0.10 parts by mass or more, more preferably 0.50 parts by mass or more, still more preferably 1.0 parts by mass or more, further preferably 3.0 parts by mass or more, and particularly preferably 5.0 parts by mass or more where the content of the (SA) binder resin is 100 parts by mass. Meanwhile, the total content of the compound (SB1), the (SB2), and the compound (SB3) in the film is preferably 20 parts by mass or less, and more preferably 15 parts by mass or less.

<(SC) Amine Compound or Compound Having Structure Derived from Amine Compound>

The film of the present invention preferably contains (SC) an amine compound or a compound having a structure derived from an amine compound (hereinafter, “(SC) compound”). The (SC) compound may be an amine compound or a compound having a structure derived from an amine compound. The amine compound may be a compound in the composition for forming the film of the present invention. As described above, the (SC) compound is preferably a compound that is to form a cross-linked structure with the (SB) compound or a compound that has formed a cross-linked structure with the (SB) compound. The cross-linked structure is preferably one formed via a reaction and not particularly limited, for example, one formed by heating or by irradiation with an energy ray.

The number of the amino groups of the (SC) compound is preferably 2 or more, and more preferably 3 or more. Meanwhile, the number of the amino groups is preferably 6 or less, and more preferably 4.

It is preferable from the viewpoint of improving the adhesion at a cryogenic temperature of about −50 °C and improving the thermal cycle reliability that the film of the present invention contains the (SC) compound, and the (SC) compound contains an (SC1) compound having a silicone structure and/or a siloxane structure and having at least two alkylene groups bonding to a silicon atom in the silicone structure and/or the siloxane structure (hereinafter, “(SC1) compound”). The (SC1) compound may be a compound having a structure derived from the compound described above.

The silicone structure and the siloxane structure of the (SC1) compound are each preferably a divalent or more structure, which is bonded to at least two alkylene groups and in which these alkylene groups are interposed. The divalent or more structure is more preferably trivalent or more. Meanwhile, the divalent or more structure is preferably hexavalent or less, and more preferably tetravalent or less.

The number of the silicon atoms of the (SC1) compound is preferably 5 or more, more preferably 10 or more, still more preferably 15 or more, and particularly preferably 20 or more. Meanwhile, the number of the silicon atoms of the (SC1) compound is preferably 30 or less, more preferably 27 or less, and still more preferably 25 or less.

The silicone structure in the (SC1) compound is preferably a dialkylsilicone structure and/or a monoalkylsilicone structure. The number of the carbon atoms of an alkyl group of the dialkylsilicone structure and the monoalkylsilicone structure is preferably 1 or more, more preferably 2 or more, and still more preferably 3 or more. Meanwhile, the number of the carbon atoms in the alkyl group is preferably 10 or less, more preferably 8 or less, and still more preferably 6 or less.

The siloxane structure in the (SC1) compound is preferably a monoalkylsiloxane structure. The number of the carbon atoms of the alkyl group of the monoalkylsiloxane structure is preferably 1 or more, more preferably 2 or more, and still more preferably 3 or more. Meanwhile, the number of the carbon atoms in the alkyl group is preferably 10 or less, more preferably 8 or less, and still more preferably 6 or less.

In the (SC1) compound, a content ratio of aliphatic groups bonding to silicon atoms in the silicone structure and the siloxane structure accounting for in a total of the aliphatic groups and aromatic groups bonding to silicon atoms in the silicone structure and the siloxane structure is preferably 80 mol % or more, more preferably 85 mol % or more, and still more preferably 90 mol % or more. Meanwhile, the content ratio of the aliphatic groups to the total of the aliphatic groups and the aromatic groups is preferably 100 mol % or less, more preferably 99 mol % or less, and still more preferably 97 mol % or less from the viewpoint of improving the thermal cycle reliability.

The aliphatic group of the (SC1) compound is preferably an alkyl group. The preferred number of carbon atoms of the alkyl group is also the same as described above. The alkyl group is preferably a methyl group, an ethyl group, a propyl group, a butyl group, or a hexyl group. The number of the carbon atoms of the aromatic group of the (SC1) compound is preferably 6 or more, more preferably 7 or more, and still more preferably 8 or more. Meanwhile, the number of the carbon atoms of the aromatic group is preferably 15 or less, more preferably 12 or less, and still more preferably 10 or less. The aromatic group is preferably a phenyl group, a tolyl group, a xylyl group, a phenoxy group, a tolyloxy group, or a xylyloxy group.

The (SC1) compound preferably includes one or more selected from the group consisting of compounds represented by the general formula (31) and compounds having a structure represented by the general formula (32).

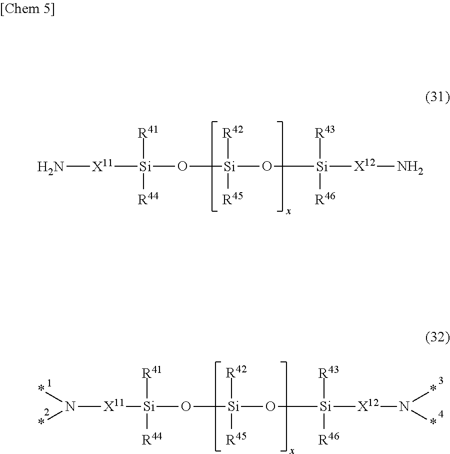

In the general formulas (31) and (32), X¹¹ and X¹² each independently represent a direct bond, an oxygen atom, an alkylene group having 1 to 30 carbon atoms, an alkyleneoxy group having 1 to 30 carbon atoms, or an arylene group having 6 to 30 carbon atoms. R⁴¹ to R⁴⁶ each independently represent an alkyl group having 1 to 30 carbon atoms, an aryl group having 6 to 30 carbon atoms, or an aryloxy group having 6 to 30 carbon atoms. x represents an integer of 1 to 100. *¹ to *⁴ each independently represent a bonding point to another structure.

In the general formulas (31) and (32), the alkyl group having 1 to 30 carbon atoms is preferably a methyl group, an ethyl group, a propyl group, a butyl group, or a hexyl group. The aryl group having 6 to 30 carbon atoms is preferably a phenyl group, a tolyl group, or a xylyl group. The aryloxy group having 6 to 30 carbon atoms is preferably a phenoxy group, a tolyloxy group, or a xylyloxy group. The alkylene group having 1 to 30 carbon atoms is preferably a methylene group, an ethylene group, a propylene group, a butylene group, or a hexylene group. The arylene group having 6 to 30 carbon atoms is preferably a phenylene group, a tolylene group, or a xylylene group. The alkyl group and the alkylene group each has a linear structure or a branched structure. The alkyl group, the aryl group, the aryloxy group, the alkylene group, and the arylene group each may have a hetero atom, and each may be either unsubstituted or substituted.

The (SC1) compound as described above is suitable for adjusting the shear strain at −50 °C to be within a range of 0.70 to 20 and/or adjusting the elastic modulus at −50 °C to be within a range of 0.10 to 200 MPa by a flexible skeleton derived from the silicone structure and/or the siloxane structure.

The content of the (SC1) compound in the film is preferably 1.0 parts by mass or more, more preferably 3.0 parts by mass or more, still more preferably 5.0 parts by mass or more, and particularly preferably 6.0 parts by mass or more where the total amount of the (SA) binder resin, the (SB) compound, and the (SC) compound is 100 parts by mass. Meanwhile, the content of the (SC1) compound in the film is preferably 20 parts by mass or less, and more preferably 15 parts by mass or less.

### <(SD) Thermally Conductive Filler>

The film of the present invention contains an (SD) thermally conductive filler. The (SD) thermally conductive filler refers to inorganic particles having a thermal conductivity at 25 °C. of 2.0 W/m. K or more. The thermal conductivity can be determined by obtaining a sintered body having a thickness of about 1.0 mm and a porosity of 10% by volume or less and performing measurement in accordance with JIS R1611 (2010). Incidentally, “7.2 Measurement Method” of JIS R1611 (2010) states “c) Bulk density: The thermal diffusivity is measured according to JIS R1634 or the like,” but in the measurement in the present invention, the measurement of “c) Bulk density” refers to a value measured in accordance with JIS R1634 (1998).

Examples of the shape of the (SD) thermally conductive filler include a perfect spherical shape, a spherical shape, a scaly shape, a flake shape, a foil piece shape, a fibrous shape, and a needle shape. From the viewpoint of improving the thermal conductivity of the film by high-density filling of the filler, a (SD) thermally conductive filler in a perfectly spherical form is preferable.

The thermal conductivity of the (SD) thermally conductive filler at 25 °C. is preferably 2.0 W/(m·K) or more, more preferably 5.0 W/(m·K) or more, still more preferably 10 W/(m·K) or more, further preferably 20 W/(m·K) or more, particularly preferably 30 W/(m·K) or more, and especially preferably 40 W/(m·K) or more from the viewpoint of improving the adhesion and improving the thermal cycle reliability. Meanwhile, the thermal conductivity of the (SD) thermally conductive filler at 25 °C. is preferably 300 W/(m·K) or less, more preferably 200 W/(m·K) or less, still more preferably 150 W/(m·K) or less, and particularly preferably 100 W/(m·K) or less from the viewpoint of improving the thermal cycle reliability.

From the viewpoint of improving the adhesion and improving the thermal cycle reliability, the (SD) thermally conductive filler preferably contains aluminum, boron, silicon, magnesium, zinc, titanium, zirconium, yttrium, or iron as a main component element, and more preferably contains aluminum, boron, silicon, magnesium, or zinc as a main component element. The main component element refers to an element that is contained most on a mass basis in the constituent components.

The (SD) thermally conductive filler preferably includes one or more selected from the group consisting of alumina particles, aluminum nitride particles, boron nitride particles, silica particles, silicon carbide particles, silicon nitride particles, magnesium oxide particles, magnesium carbonate particles, magnesium hydroxide particles, zinc oxide particles, titanium carbide particles, titanium nitride particles, titanium oxide particles, zirconium oxide particles, yttrium oxide particles, and iron oxide particles.

The (SD) thermally conductive filler as described above is suitable for adjusting the thermal conductivity of the film at 25 °C to be in a range of 0.10 to 5.0 W/(m·K) while maintaining the mechanical properties of the film by its robust structure and high thermal conductivity.

In the first aspect of the film of the present invention, the (SD) thermally conductive filler includes an (SD1) first thermally conductive filler and an (SD2) second thermally conductive filler, the (SD1) first thermally conductive filler has an average primary particle size of 1.0 to 200 μm, and the (SD2) second thermally conductive filler has an average primary particle size of 0.010 μm or more and less than 1.0 μm.

In a second aspect of the film of the present invention, the (SD) thermally conductive filler preferably includes the (SD1) first thermally conductive filler and the (SD2) second thermally conductive filler from the viewpoint of improving the adhesion and improving the thermal cycle reliability, and it is more preferable that the (SD1) first thermally conductive filler has an average primary particle size of 1.0 to 200 μm, and the (SD2) second thermally conductive filler has an average primary particle size of 0.010 μm or more and less than 1.0 μm.

The average primary particle size of the (SD1) first thermally conductive filler is preferably 2.0 μm or more, and more preferably 3.0 μm or more from the viewpoint of high-density filling of the filler and clarification of a filler interface.

With the configuration as described above, voids between the fillers having a large particle size are filled with the fillers having a small particle size, so that the effect of improving the thermal conductivity of the film due to high-density filling of the fillers is remarkable. In addition, it is presumed that the internal stress caused by the temperature rise of a member can be reduced by efficient heat radiation, and the followability to each member is improved, so that the adhesion and the thermal cycle reliability are improved.

The average primary particle size of the (SD1) first thermally conductive filler is preferably 5.0 μm or more, more preferably 10 μm or more, still more preferably 15 μm or more, further preferably 20 μm or more, particularly preferably 25 μm or more, and especially preferably 30 μm or more from the viewpoint of improving the thermal cycle reliability. Meanwhile, the average primary particle size is preferably 150 μm or less, more preferably 100 μm or less, and still more preferably 80 μm or less from the viewpoint of improving the adhesion. Furthermore, the average primary particle size is preferably 60 μm or less, more preferably 50 μm or less, still more preferably 45 μm or less, and particularly preferably 40 μm or less from the viewpoint of improving the adhesion at a cryogenic temperature of about −50 °C and improving the thermal cycle reliability.

The average primary particle size of the (SD2) second thermally conductive filler is preferably 0.050 μm or more, more preferably 0.10 μm or more, still more preferably 0.15 μm or more, and particularly preferably 0.20 μm or more from the viewpoint of improving the thermal cycle reliability. Meanwhile, the average primary particle size is preferably 0.80 μm or less, more preferably 0.60 μm or less, and still more preferably 0.40 μm or less from the viewpoint of improving the adhesion.

The primary particle size of the (SD) thermally conductive filler refers to the major axis diameter of primary particles of the filler. The average primary particle size of the (SD) thermally conductive filler in the film can be calculated as an average value obtained by imaging and analyzing a section of the film using a transmission electron microscope (hereinafter, “TEM”) and measuring 30 primary particles of the filler. The average primary particle size of the (SD1) first thermally conductive filler is an average value obtained by measuring 30 primary particles of the filler having a primary particle size of 1.0 μm or more in measurement using TEM. In addition, the average primary particle size of the (SD2) second thermally conductive filler is an average value obtained by measuring 30 primary particles of the filler having a primary particle size of less than 1.0 μm in measurement using TEM. Elements contained in the (SD) thermally conductive filler can be detected by imaging and analyzing a section of the film using transmission electron microscope-energy dispersive X-ray spectroscopy (hereinafter, “TEM-EDX”). Measurement using TEM-EDX makes it possible also to distinguish two or more types of fillers and clarify a filler interface. The average primary particle size of the thermally conductive filler in a filler dispersion is determined by measuring a particle size distribution by a laser diffraction/scattering method. Examples of the measuring instrument include SLD3100, manufactured by Shimadzu Corporation, LA-920, manufactured by HORIBA, Ltd. or its equivalent.

The specific surface area of the (SD1) first thermally conductive filler is preferably 0.023 m²/g or more, more preferably 0.031 m²/g or more, still more preferably 0.047 m²/g or more, and particularly preferably 0.059 m²/g or more from the viewpoint of improving the adhesion. Furthermore, from the viewpoint of improving the adhesion at a cryogenic temperature of about −50 °C and improving the thermal cycle reliability, the specific surface area is preferably 0.080 m²/g or more, more preferably 0.11 m²/g or more, still more preferably 0.15 m²/g or more, further preferably 0.18 m²/g or more, particularly preferably 0.20 m²/g or more, and especially preferably 0.23 m²/g or more. In particular, from the viewpoint of improving the adhesion at a cryogenic temperature of about −50 °C, the specific surface area is preferably 0.18 m²/g or more, more preferably 0.20 m²/g or more, and still more preferably 0.23 m²/g or more.

Meanwhile, the specific surface area of the (SD1) first thermally conductive filler is preferably 5.90 m²/g or less, more preferably 3.00 m²/g or less, and still more preferably 2.00 m²/g or less from the viewpoint of high-density filling of the filler and clarification of a filler interface. Furthermore, from the viewpoint of improving the thermal cycle reliability, the specific surface area is preferably 1.20 m²/g or less, more preferably 1.00 m²/g or less, still more preferably 0.80 m²/g or less, further preferably 0.60 m²/g or less, particularly preferably 0.50 m²/g or less, and especially preferably 0.40 m²/g or less. In particular, from the viewpoint of improving the adhesion at a cryogenic temperature of about −50 °C, the specific surface area is preferably 2.00 m²/g or less, more preferably 1.20 m²/g or less, still more preferably 1.00 m²/g or less, further preferably 0.80 m²/g or less, further preferably 0.60 m²/g or less, further preferably 0.50 m²/g or less, and particularly preferably 0.40 m²/g or less.

With the configuration as described above, the inclination in a stress-strain curve with the vertical axis representing the stress and the horizontal axis representing the strain decreases (the strain per unit stress increases) due to the anchor effect caused by the filler having a specific surface area, and therefore that configuration is suitable for adjusting the shear strain at −50 °C to be within a range of 0.70 to 20. Therefore, it is presumed that flexibility with which a difference in coefficient of thermal expansion between members can be alleviated even as a cryogenic temperature is attained and the followability to each member is improved, and as a result, the adhesion and the thermal cycle reliability are improved.

The specific surface area of the (SD2) second thermally conductive filler is preferably 5.91 m²/g or more, more preferably 8.00 m²/g or more, still more preferably 12.0 m²/g or more, further preferably 14.6 m²/g or more, particularly preferably 16.1 m²/g or more, and especially preferably 19.5 m²/g or more from the viewpoint of improving the adhesion. Meanwhile, the specific surface area of the (SD2) second thermally conductive filler is preferably 590 m²/g or less, more preferably 120 m²/g or less, still more preferably 60.0 m²/g or less, further preferably 50.0 m²/g or less, particularly preferably 40.0 m²/g or less, and especially preferably 30.0 m²/g or less from the viewpoint of improving the thermal cycle reliability.

With the configuration as described above, it is considered that voids between the fillers having a large particle size are filled with the fillers having a small particle size, so that heat generated in a member to be joined can be efficiently radiated, and an internal stress caused by temperature rise of the member can be reduced. In addition, it is also presumed that the heat stored in the film can be reduced, and the change in mechanical properties due to the temperature rise of the film can be suppressed.

The specific surface area of the (SD) thermally conductive filler can be calculated by measuring the BET specific surface area by a gas adsorption method. First, a film is heated at 600 to 900 °C to thermally decompose and/or volatilize organic components such as resins, and the mass of the (SD) thermally conductive filler remaining is measured. Subsequently, gas molecules are adsorbed, and the BET specific surface area is calculated from the monomolecular adsorption amount. The (SD) thermally conductive filler remaining is imaged and analyzed using TEM, and the primary particle size of the filler is measured, thereby determining whether it corresponds to the (SD1) first thermally conductive filler or the (SD2) second thermally conductive filler. When the (SD) thermally conductive filler remaining is a mixture of the (SD1) first thermally conductive filler and the (SD2) second thermally conductive filler, the specific surface area of each of the two types of fillers can be measured by separating the two types of fillers using a dry classifier or a wet classifier.

From the viewpoint of improving the adhesion and improving the thermal cycle reliability, the content ratio of the (SD1) first thermally conductive filler is preferably 40% by volume or more, more preferably 50% by volume or more, and still more preferably 60% by volume or more where the total of the (SD1) first thermally conductive filler and the (SD2) second thermally conductive filler is 100% by volume. Meanwhile, the content ratio of the (SD1) first thermally conductive filler is preferably 80% by volume or less, more preferably 75% by volume or less, and still more preferably 70% by volume or less from the viewpoint of improving the adhesion and improving the thermal cycle reliability.

From the viewpoint of improving the adhesion and improving the thermal cycle reliability, the content ratio of the (SD2) second thermally conductive filler is preferably 20% by volume or more, more preferably 25% by volume or more, and still more preferably 30% by volume or more where the total of the (SD1) first thermally conductive filler and the (SD2) second thermally conductive filler is 100% by volume. Meanwhile, the content ratio of the (SD1) first thermally conductive filler is preferably 60% by volume or less, more preferably 50% by volume or less, and still more preferably 40% by volume or less from the viewpoint of improving the adhesion and improving the thermal cycle reliability.

The film of the present invention may contain another (SD) thermally conductive filler. Examples of the other (SD) thermally conductive filler include carbon black or a metal filler such as aluminum particles, magnesium particles, silver particles, zinc particles, iron particles, or lead particles.

The content ratio of the (SD) thermally conductive filler in the film is preferably 50% by volume or more, more preferably 60% by volume or more, and still more preferably 70% by volume or more. Meanwhile, the content ratio of the (SD) thermally conductive filler in the film is preferably 90% by volume or less, more preferably 85% by volume or less, and still more preferably 80% by volume or less.

The content ratio of the (SD) thermally conductive filler can be calculated by a method of measuring by thermogravimetric analysis or a method equivalent thereto. In one method, first, a film is heated at 600 to 900 °C to thermally decompose and/or volatilize organic components such as resins, and the mass of the remaining (SD) thermally conductive filler is measured, and the mass of the organic components such as resins is calculated from the difference in mass. Subsequently, the volumes of the (SD) thermally conductive filler and the organic components such as resins are calculated by dividing the obtained masses by the respective specific gravities.

### <Content of Specific Element and Content of Specific Ion in Film>

The film of the present invention preferably satisfies at least one of the following conditions (S1a), (S2a), (S3a), (S1b), (S2b), and (S3b) from the viewpoint of improving the adhesion at a cryogenic temperature of about −50 °C and improving the thermal cycle reliability. From the same viewpoint, the film of the present invention more preferably satisfies at least one of the following conditions (S1a), (S2a), and (S3a), and still more preferably satisfies at least one of the following conditions (S1a), (S2a), and (S3a) and also satisfies at least one of the following conditions (S1b), (S2b), and (S3b). When the following (S1a) is satisfied, it is preferable that the following (S1b) is satisfied. When the following (S2a) is satisfied, it is preferable that the following (S2b) is satisfied. When the following (S3a) is satisfied, it is preferable that the following (S3b) is satisfied. When the film of the present invention satisfies the following condition (Sb), it is preferable that the following condition (S1a) is satisfied by the boron element-containing ions in the film. When the film of the present invention satisfies the following condition (S2b), the following condition (S2a) is preferably satisfied by the phosphorus element-containing ions in the film. When the film of the present invention satisfies the following condition (S3b), the following condition (S3a) is satisfied by the chloride ion and bromide ion in the film.
(S1a) the content of the boron element in the film is 5.0% by mass or less;
(S2a) the content of the phosphorus element in the film is 1,000 ppm by mass or less;
(S3a) the total content of the chlorine element and bromine element in the film is 1,000 ppm by mass or less;
(S1b) the total content of boron element-containing ions in the film is 5.0% by mass or less;
(S2b) the total content of phosphorus element-containing ions in the film is 5,000 ppm by mass or less; and
(S3b) the total content of chloride ion and bromide ion in the film is 1,000 ppm by mass or less.

In the case of taking the configuration as described above, the film of the present invention preferably contains the following (I) and/or (II):
(I) one or more selected from the group consisting of a boron element-containing component, a phosphorus element-containing component, a chlorine element-containing component, and a bromine element-containing component;
(II) one or more selected from the group consisting of a component containing a boron-based cation, a component containing a boron-based anion shown below, a component containing a phosphorus-based cation, a component containing a phosphorus-based anion shown below, and a component containing a halogen anion shown below, boron-based anion: one or more selected from the group consisting of a borate ion, a boronate ion, a borate ion, a tetraphenylborate ion, a tetrafluoroborate ion, and a trifluoroborate ion;
phosphorus-based anion: one or more selected from the group consisting of a phosphate ion, a phosphite ion, a hypophosphite ion, and a hexafluorophosphate ion; halogen anion: chloride ion and/or bromide ion.

The content of a boron element in the film is preferably 0.010% by mass or more, more preferably 0.030% by mass or more, still more preferably 0.050% by mass or more, further preferably 0.070% by mass or more, and particularly preferably 0.10% by mass or more. Meanwhile, the content of a boron element in the film is preferably 4.0% by mass or less, more preferably 3.0% by mass or less, still more preferably 2.0% by mass or less, and particularly preferably 1.0% by mass or less.

The content of a phosphorus element in the film is preferably 0.010 ppm by mass or more, more preferably 0.030 ppm by mass or more, still more preferably 0.050 ppm by mass or more, further preferably 0.070 ppm by mass or more, and particularly preferably 0.10 ppm by mass or more. Meanwhile, the content of a phosphorus element in the film is preferably 500 ppm by mass or less, more preferably 300 ppm by mass or less, still more preferably 100 ppm by mass or less, further preferably 50 ppm by mass or less, further preferably 30 ppm by mass or less, further preferably 10 ppm by mass or less, further preferably 5.0 ppm by mass or less, particularly preferably 3.0 ppm by mass or less, and especially preferably 1.0 ppm by mass or less.

A preferable range of the total content of chlorine element and bromine element in the film is also the same as the content of phosphorus element with respect to each of the upper limit value and the lower limit value.

The total content of the boron element-containing ions in the film is preferably 0.010% by mass or more, more preferably 0.030% by mass or more, still more preferably 0.050% by mass or more, further preferably 0.070% by mass or more, and particularly preferably 0.10% by mass or more. Meanwhile, the total content of the boron element-containing ions in the film is preferably 4.0% by mass or less, more preferably 3.0% by mass or less, still more preferably 2.0% by mass or less, and particularly preferably 1.0% by mass or less.

The total content of the phosphorus element-containing ions in the film is preferably 0.010 ppm by mass or more, more preferably 0.030 ppm by mass or more, still more preferably 0.050 ppm by mass or more, further preferably 0.070 ppm by mass or more, and particularly preferably 0.10 ppm by mass or more. Meanwhile, the total content of the phosphorus element-containing ions in the film is preferably 3,000 ppm by mass or less, more preferably 1,000 ppm by mass or less, still more preferably 500 ppm by mass or less, further preferably 300 ppm by mass or less, further preferably 100 ppm by mass or less, further preferably 50 ppm by mass or less, further preferably 30 ppm by mass or less, particularly preferably 10 ppm by mass or less, and especially preferably 5.0 ppm by mass or less.

The total content of chloride ion and bromide ion in the film is preferably 0.010 ppm by mass or more, more preferably 0.030 ppm by mass or more, still more preferably 0.050 ppm by mass or more, further preferably 0.070 ppm by mass or more, and particularly preferably 0.100 ppm by mass or more. Meanwhile, the total content of chloride ion and bromide ion in the film is preferably 500 ppm by mass or less, more preferably 300 ppm by mass or less, still more preferably 100 ppm by mass or less, further preferably 50 ppm by mass or less, further preferably 30 ppm by mass or less, further preferably 10 ppm by mass or less, further preferably 5.0 ppm by mass or less, particularly preferably 3.0 ppm by mass or less, and especially preferably 1.0 ppm by mass or less.

With the configuration as described above, it is considered that a boron element, phosphorus element, chlorine element, or bromine element interacts with the surface of a member to be joined. The boron element has an empty 3p orbital, and it is considered that a coordinate bond from the surface of a member is easily formed through electron acceptance utilizing the empty orbital. In addition, a phosphorus element has a lone pair, and therefore, it is considered that a coordination bond to the surface of a member is easily formed through efficient electron donation utilizing a 3d orbital, which is an empty atomic orbital. In addition, a chlorine element and bromine element have many lone pairs, and it is considered that a coordination bond to the surface of a member is easily formed through electron donation utilizing these electron pairs. It is presumed that owing to these actions, these elements function as anchors at an interface with a member at a cryogenic temperature, so that followability to each member is improved, and the adhesion and thermal cycle reliability are improved.

### <Content of Fluorine Element and Content of Fluoride Ion in Film>

The film of the present invention preferably satisfies at least one of the following conditions (S3α) and (S3β) from the viewpoint of improving the adhesion at a cryogenic temperature of about −50 °C and improving the thermal cycle reliability. From the same viewpoint, the film of the present invention more preferably satisfies the following condition (S3α), and also preferably satisfies the following condition (S3α) and also satisfies the following condition (S3β). When the film of the present invention satisfies the following condition (S3β), the following condition (S3α) by fluoride ions in the film is satisfied.
(S3α) The content of fluorine element in the film is 1,000 ppm by mass or less.
(S3β) The content of fluoride ion in the film is 1,000 ppm by mass or less.

In the case of taking the configuration as described above, the film of the present invention preferably contains the following (III) and/or (IV).
(III) Fluorine element-containing component.
(IV) Fluoride ion-containing component.

The content of fluorine element in the film is preferably more than 0.000 ppm by mass, more preferably 0.010 ppm by mass or more, still more preferably 0.030 ppm by mass or more, further preferably 0.050 ppm by mass or more, particularly preferably 0.070 ppm by mass or more, and especially preferably 0.10 ppm by mass or more. Meanwhile, the content of fluorine element in the film is preferably 500 ppm by mass or less, more preferably 300 ppm by mass or less, still more preferably 100 ppm by mass or less, further preferably 50 ppm by mass or less, further preferably 30 ppm by mass or less, further preferably 10 ppm by mass or less, further preferably 5.0 ppm by mass or less, particularly preferably 3.0 ppm by mass or less, and especially preferably 1.0 ppm by mass or less.

The content of fluoride ion in the film is preferably more than 0.000 ppm by mass, more preferably 0.010 ppm by mass or more, still more preferably 0.030 ppm by mass or more, further preferably 0.050 ppm by mass or more, particularly preferably 0.070 ppm by mass or more, and especially preferably 0.10 ppm by mass or more. Meanwhile, the content of fluoride ion in the film is preferably 500 ppm by mass or less, more preferably 300 ppm by mass or less, still more preferably 100 ppm by mass or less, further preferably 50 ppm by mass or less, further preferably 30 ppm by mass or less, further preferably 10 ppm by mass or less, further preferably 5.0 ppm by mass or less, particularly preferably 3.0 ppm by mass or less, and especially preferably 1.0 ppm by mass or less.

Fluorine element has many lone pairs, and it is considered that when fluorine element is contained in the film, a coordination bond to the surface of a member is easily formed through electron donation utilizing these electron pairs.

The content of fluorine element in the film may be 0.000 ppm by mass. The content of fluoride ion in the film may also be 0.000 ppm by mass. When the content of fluorine element and/or the content of fluoride ion in the film exceeds 0.000 ppm by mass, it is preferable that in the film of the present invention, the (SA) binder resin or the (SD) thermally conductive filler has a fluorine atom or a fluoride ion in the structure thereof, or the film further contains a fluorine element-containing component and/or a fluoride ion-containing component.

When the film of the present invention contains the (SB) compound or the (SC) compound, and the content of fluorine element and/or the content of fluoride ion in the film is more than 0.000 ppm by mass, it is preferable that in the film of the present invention, the (SA) binder resin, the (SD) thermally conductive filler, the (SB) compound, or the (SC) compound has a fluorine atom or a fluoride ion in the structure thereof, or the film further contains a fluorine element-containing component and/or a fluoride ion-containing component.

It is presumed that when the content of a compound containing a fluorine atom in the structure thereof, a fluorine element-containing component, or the like in the film is set to a specific value or less, the content of fluorine element or fluoride ion in these components or the content of an anion containing fluorine element derived from these components is controlled to a specific value or less, and therefore, a local interaction with the surface of a member to be joined is improved due to hydrogen bonding of each component in the film, the electronegativity of a fluorine atom, or the like. In addition, it is considered that by intentionally setting the content of the above components to a specific value or less, the polarization structure or the charge balance in the film is controlled, and the influence of an ionic component or the like that adversely affects the mechanical properties of the film in a cooling/heating cycle can be suppressed. It is presumed that owing to these actions, fluorine element functions as an anchor at an interface with a member at a cryogenic temperature, so that followability to each member is improved, and the adhesion and the thermal cycle reliability are improved.

### <Content of Platinum Element and Content of Platinum Element-Containing Ion in Film>

The film of the present invention preferably satisfies at least one of the following conditions (S4a) and (S4b) from the viewpoint of improving the adhesion at a cryogenic temperature of about −50 °C and improving the thermal cycle reliability. From the same viewpoint, the film of the present invention more preferably satisfies the following condition (S4a), and still more preferably satisfies the following condition (S4a) and also satisfies the following condition (S4b). When the film of the present invention satisfies the following condition (S4b), the following condition (S4a) is satisfied by the platinum element-containing ions in the film.
(S4a) The content of platinum element in the film is 1,000 ppm by mass or less.
(S4b) The total content of platinum element-containing ions in the film is 5,000 ppm by mass or less.

In the case of taking the configuration as described above, the film of the present invention preferably contains a platinum element-containing component and/or a platinum cation-containing component. The platinum element-containing component is preferably a simple substance of platinum or an organic platinum compound. The platinum cation-containing component is preferably a platinum halide, platinum hydroxide, a platinum alkoxide compound, a platinum chelate compound, or a platinum carboxylate.

The content of platinum element in the film is preferably 0.010 ppm by mass or more, more preferably 0.030 ppm by mass or more, still more preferably 0.050 ppm by mass or more, further preferably 0.070 ppm by mass or more, and particularly preferably 0.10 ppm by mass or more. Meanwhile, the content of platinum element in the film is preferably 500 ppm by mass or less, more preferably 300 ppm by mass or less, still more preferably 100 ppm by mass or less, further preferably 50 ppm by mass or less, particularly preferably 30 ppm by mass or less, and especially preferably 10 ppm by mass or less.

The total content of the platinum element-containing ions in the film is preferably 0.010 ppm by mass or more, more preferably 0.030 ppm by mass or more, still more preferably 0.050 ppm by mass or more, further preferably 0.070 ppm by mass or more, and particularly preferably 0.10 ppm by mass or more. Meanwhile, the total content of the platinum element-containing ions in the film is preferably 3,000 ppm by mass or less, more preferably 1,000 ppm by mass or less, still more preferably 500 ppm by mass or less, further preferably 300 ppm by mass or less, particularly preferably 100 ppm by mass or less, and especially preferably 50 ppm by mass or less.

With the configuration as described above, it is considered that the platinum element is coordinated to the surface of a member to be joined, and functions as an anchor at the interface with the member at a cryogenic temperature. Therefore, it is presumed that followability to each member is improved, and the adhesion and thermal cycle reliability are improved.

### <Contents of Specific Silicon Compound and Cyclic Silicone Compound in Film>

The film of the present invention preferably satisfies at least one of the following conditions (S5a) and (S5b) from the viewpoint of improving the adhesion at a cryogenic temperature of about −50 °C and improving the thermal cycle reliability. From the same viewpoint, the film of the present invention more preferably satisfies the following condition (S5a), and still more preferably satisfies the following condition (S5a) and also satisfies the following condition (S5b).
(S5a) The total content of an organosilane compound having 1 to 2 silicon atoms (hereinafter, “specific silicon compound”) in the film is 1,000 ppm by mass or less. (S5b) The total content of a cyclic silicone compound in the film is 1,000 ppm by mass or less.

The specific silicon compound preferably has a methyl group, a phenyl group, a hydroxy group, an epoxy group, an amino group, a styryl group, a (meth)acryloyl group, a vinyl group, or an allyl group.

The number of silicon atoms of the cyclic silicone compound is preferably 4 or more, more preferably 6 or more, still more preferably 8 or more, and particularly preferably 10 or more. Meanwhile, the number of silicon atoms is preferably 20 or less, more preferably 16 or less, and still more preferably 12 or less.

The specific silicon compound and the cyclic silicone compound each preferably have an alkoxy group and/or a silanol group. The total number of the alkoxy group and the silanol group is preferably 1 or more, more preferably 2 or more, and still more preferably 3 or more. Meanwhile, the total number of the alkoxy group and the silanol group is preferably 10 or less, more preferably 8 or less, and still more preferably 6 or less.

The total content of the specific silicon compound in the film is preferably 0.010 ppm by mass or more, more preferably 0.030 ppm by mass or more, still more preferably 0.050 ppm by mass or more, further preferably 0.070 ppm by mass or more, and particularly preferably 0.10 ppm by mass or more. Meanwhile, the total content of the specific silicon compound in the film is preferably 500 ppm by mass or less, more preferably 300 ppm by mass or less, still more preferably 100 ppm by mass or less, further preferably 50 ppm by mass or less, particularly preferably 30 ppm by mass or less, and especially preferably 10 ppm by mass or less.

The total content of the cyclic silicone compound in the film is preferably 0.010 ppm by mass or more, more preferably 0.030 ppm by mass or more, still more preferably 0.050 ppm by mass or more, further preferably 0.070 ppm by mass or more, and particularly preferably 0.10 ppm by mass or more. Meanwhile, the total content of the cyclic silicone compound in the film is preferably 500 ppm by mass or less, more preferably 300 ppm by mass or less, still more preferably 100 ppm by mass or less, further preferably 50 ppm by mass or less, particularly preferably 30 ppm by mass or less, and especially preferably 10 ppm by mass or less.

With the configuration as described above, it is considered that the specific silicon compound reacts with a hydroxy group and/or a silanol group on the surface of a member. Therefore, it is presumed that the specific silicon compound functions as an anchor at an interface with a member at a cryogenic temperature, so that followability to each member is improved, and the adhesion and thermal cycle reliability are improved.

<Cross-Linking Agent or Compound Having Structure Derived from Cross-Linking Agent>

The film of the present invention preferably contains a cross-linking agent or a compound having a structure derived from a cross-linking agent (hereinafter, “cross-linker compound”). The cross-linker compound may be a cross-linking agent or a compound having a structure derived from a cross-linking agent. The cross-linking agent may be a compound in the composition for forming the film of the present invention. The cross-linking agent refers to a compound having a cross-linkable group, a radically polymerizable group, a cationically polymerizable group, or an anionically polymerizable group capable of reacting with a resin or the like.

The cross-linker compound is preferably a compound that forms a cross-linked structure with the (SA) binder resin or a compound that has formed a cross-linked structure with the (SA) binder resin as described above. The cross-linking agent preferably has at least two alkoxymethyl groups, methylol groups, oxetanyl groups, blocked isocyanate groups, styryl groups, cinnamoyl groups, maleimide groups, nadimide groups, (meth)acryloyl groups, vinyl groups, or allyl groups. The cross-linking agent is a compound different from the (SB) compound described above, and may be a compound having an epoxy group different from the (SB) compound.

The cross-linker compound as described above is suitable for improving the mechanical properties of the film by a cross-linked structure, which is to be formed by this compound with the (SA) binder resin. In addition, it is presumed that the adhesion and the like are improved by the interaction to each member due to the structure derived from the cross-linking agent.

<Cure Accelerator or Compound Having Structure Derived from Cure Accelerator>

The film of the present invention preferably contains a cure accelerator or a compound having a structure derived from a cure accelerator (hereinafter, “cure accelerator compound”). The cure accelerator compound may be a cure accelerator or a compound having a structure derived from a cure accelerator. The cure accelerator may be a compound in the composition for forming the film of the present invention. The cure accelerator refers to a compound having a structure that accelerates the reaction of the (SB) compound or the cross-linking agent.

The cure accelerator compound is preferably a compound that forms a cross-linked structure with the (SB) compound or the cross-linking agent described above or a compound that has formed a cross-linked structure with the (SB) compound or the cross-linking agent. The cross-linked structure is preferably one formed via a reaction, and is not particularly limited, for example, one formed by heating or by irradiation with an energy ray. The cure accelerator preferably has an imidazole group, a polyhydric phenol structure, an acid anhydride group, a hydrazide group, a mercapto group, or a Lewis acid-amine complex structure. The cure accelerator is a compound different from the (SC) compound described above, and may be a compound having an amino group different from the (SC) compound. As the cure accelerator, a latent cure accelerator that liberates the substituent or structure by reaction, heating, or irradiation with an energy ray is also preferable.

The cure accelerator compound as described above is suitable for improving the mechanical properties of the film by a cross-linked structure, which is to be formed by this compound with the (SB) compound or a cross-linking agent. In addition, it is presumed that the adhesion and the like are improved by the interaction to each member due to the structure derived from the cure accelerator.

From the viewpoint of improving the adhesion at a cryogenic temperature of about −50 °C and improving the thermal cycle reliability, the cure accelerator is preferably a compound having a silicone structure and/or a siloxane structure, also having at least two alkylene groups bonded to a silicon atom in the silicone structure or the siloxane structure, and further having an acid anhydride group (hereinafter, “specific acid anhydride compound”).

The silicone structure and the siloxane structure of the specific acid anhydride compound are each preferably a divalent or more structure which is bonded to at least two alkylene groups and in which these alkylene groups are interposed. The number of the silicon atoms of the specific acid anhydride compound is preferably 5 or more, more preferably 10 or more, still more preferably 15 or more, and particularly preferably 20 or more. Meanwhile, the number of the silicon atoms of the specific acid anhydride compound is preferably 30 or less. The silicone structure in the specific acid anhydride compound is preferably a dialkylsilicone structure and/or a monoalkylsilicone structure. The siloxane structure in the specific acid anhydride compound is preferably a monoalkylsiloxane structure.

The specific acid anhydride compound as described above is suitable for adjusting the shear strain at −50 °C to be within a range of 0.70 to 20 and/or adjusting the elastic modulus at −50 °C to be within a range of 0.10 to 200 MPa by a flexible skeleton derived from the silicone structure or the siloxane structure.

<Other Compound or Compound Having Structure Derived from Other Compound>

The film of the present invention may contain another compound or a compound having a structure derived from the other compound. These compounds each may be the other compound or a compound having a structure derived from the other compound. The other compound may be a compound in the composition for forming the film of the present invention. The other compound is preferably a metal alkoxide compound, a metal chelate compound, or a surfactant.

The metal alkoxide compound and the metal chelate compound each preferably contain titanium, zirconium, aluminum, magnesium, zinc, indium, tin, or copper as a main component element. The metal alkoxide compound and the metal chelate compound as described above are suitable for improving the mechanical properties of the film by a cross-linked structure formed which is to be formed by these compounds with the (SA) binder resin, the (SB) compound, or a cross-linking agent. In addition, it is presumed that since these compounds function as anchors at the interface with a member, the adhesion and the like are improved.

As the surfactant, a fluororesin-based surfactant, a silicone-based surfactant, or an acrylic resin-based surfactant is preferable. The surfactant as described above is suitable for joining another member to the surface of the film through suppression of projections on the surface of the film. It is presumed that such suppression of projections on the surface improves the adhesion and the like by an increase in a joined area with another member, an interaction, or the like.

### <Solvent>

When the film of the present invention is in a semi-cured state (stage B) described later, a part of the solvent may remain. As the solvent, a part of the solvent in the composition for forming the film of the present invention may remain. As the solvent, a compound having an alcoholic hydroxy group, a carbonyl group, an ester linkage, an amide linkage, or at least three ether linkages is preferable.

### <Method for Manufacturing Film of the Present Invention>

A method for manufacturing a composition for forming the film of the present invention will be exemplified. One example is a method in which a resin, various additives, a filler component, and a solvent are added and mixed with a stirrer, a kneader, or the like, and then mixed with a bead mill, a triple roll mill, or the like.

A method for manufacturing the film of the present invention will be exemplified. A coating film of the composition is formed on a support described later by such a method as application or printing, the coating film is then dried under reduced pressure as necessary to distill off the solvent, and subsequently the coating film is heated at 40 °C to 150 °C. Thereafter, a protective film described later may optionally be laminated on the film formed.

### <Physical Properties of Film>

In the first aspect of the film of the present invention, the elastic modulus at −50 °C. is preferably 0.10 to 200 MPa. In the second aspect of the film of the present invention, the elastic modulus at −50 °C. is 0.10 to 200 MPa. In the film of the present invention, the elastic modulus at −50 °C. is preferably 0.10 MPa or more, more preferably 0.30 MPa or more, still more preferably 0.50 MPa or more, further preferably 0.70 MPa or more, and particularly preferably 1.0 MPa or more from the viewpoint of improving the adhesion at a cryogenic temperature of about −50 °C and improving the thermal cycle reliability. Meanwhile, the elastic modulus at −50 °C. is preferably 200 MPa or less, more preferably 130 MPa or less, still more preferably 100 MPa or less from the viewpoint of improving the adhesion at a cryogenic temperature of about −50 °C and improving thermal cycle reliability. Furthermore, the elastic modulus at −50 °C. is preferably 50 MPa or less, more preferably 30 MPa or less, still more preferably 10 MPa or less, and particularly preferably 5.0 MPa or less.

With the configuration as described above, it is presumed that the internal stress caused by the difference in coefficient of thermal expansion between the members to be joined by the film can be reduced by reducing the elastic modulus at a cryogenic temperature of about −50 °C, and the followability to each member is improved, so that the adhesion and the thermal cycle reliability are improved.

The film of the present invention has a thermal conductivity at 25 °C. of 0.10 to 5.0 W/(m·K). In the film of the present invention, the thermal conductivity at 25 °C. is preferably 0.30 W/(m·K) or more, more preferably 0.50 W/(m·K) or more, still more preferably 0.70 W/(m·K) or more, and particularly preferably 1.0 W/(m·K) or more from the viewpoint of improving the adhesion and improving the thermal cycle reliability. Meanwhile, the thermal conductivity at 25 °C. is preferably 4.0 W/(m·K) or less, more preferably 3.0 W/(m·K) or less, still more preferably 2.5 W/(m·K) or less, and particularly preferably 2.0 W/(m·K) or less from the viewpoint of improving the thermal cycle reliability.

In the first aspect of the film of the present invention, the shear strain at −50 °C. is 0.70 to 20. In the second aspect of the film of the present invention, the shear strain at −50 °C. is preferably 0.70 to 20. In the film of the present invention, the shear strain at −50 °C. is preferably 1.0 or more, more preferably 1.5 or more, still more preferably 2.0 or more, and particularly preferably 2.5 or more from the viewpoint of improving the adhesion at a cryogenic temperature of about −50 °C and improving the thermal cycle reliability. Meanwhile, the shear strain at −50 °C. is preferably 17 or less, more preferably 15 or less, still more preferably 12 or less, and particularly preferably 10 or less from the viewpoint of improving the adhesion at a cryogenic temperature of about −50 °C and improving the thermal cycle reliability.

With the configuration as described above, it is presumed that flexibility with which a difference in coefficient of thermal expansion between members can be alleviated even as a cryogenic temperature is attained and the followability to each member is improved, and as a result, the adhesion and the thermal cycle reliability are improved.

The thickness of the film of the present invention is preferably 5.0 μm or more, more preferably 20 μm or more, still more preferably 50 μm or more, further preferably 100 μm or more, and particularly preferably 150 μm or more from the viewpoint of improving the adhesion. Meanwhile, the thickness of the film of the present invention is preferably 500 μm or less, more preferably 400 μm or less, still more preferably 350 μm or less, and particularly preferably 300 μm or less from the viewpoint of improving the thermal cycle reliability.

### <Laminate>

The laminate of the present invention will be described below. In the case of making a description referring to “the laminate of the present invention,” this description is a common description of the first aspect and the third aspect of the laminate of the present invention having the film of the present invention. Meanwhile, when a laminate of a specific aspect is described, the description is made with an expression “the first aspect of the laminate of the present invention” or the like. It is noted that the present invention is not limited to the following embodiments, and various modifications can naturally be made as long as the modifications can achieve the object of the invention and do not depart from the gist of the invention.

### <Film in Semi-Cured State, and Laminate>

In the film of the present invention, the elastic modulus at 25 °C. is preferably 0.010 MPa or more, more preferably 0.050 MPa or more, still more preferably 0.10 MPa or more, and particularly preferably 0.30 MPa or more from the viewpoint of improving the adhesion. Meanwhile, the elastic modulus at 25 °C. is preferably 1.0 MPa or less, more preferably 0.70 MPa or less, and still more preferably 0.50 MPa or less from the viewpoint of improving the adhesion.

The film of the present invention is preferably in a semi-cured state (B stage) from the viewpoint of improving the adhesion. The semi-cured state refers to a state in which a cross-linked structure is not formed, or a cross-linked structure is formed by a partial reaction, but the film has fluidity, or a state thereof. Examples thereof include a state in which a coating film is applied to a substrate or the like and then dried under reduced pressure to distill off a solvent, and a state in which a coating film is heated at 40 °C to 150 °C and dried, and this state refers to a state in which the coating film is soluble in an organic solvent or an alkaline solution.

The first aspect of the laminate of the present invention is a laminate including a support and the film of the present invention, wherein the film of the present invention is disposed on the support. In the first aspect of the laminate of the present invention, the elastic modulus of the film at 25 °C. is preferably 0.010 to 1.0 MPa, and the film is preferably in a semi-cured state.

The configuration as described above is suitable from the viewpoint of improvement in adhesion and handleability, and is suitable for disposing the film on a base plate or a ceramic dielectric plate described later.

### <Support>

The first aspect of the laminate of the present invention includes a support. The support is preferably a flexible substrate from the viewpoint of improvement in adhesion to the film, flexibility, and handleability. The flexible substrate is preferably a polyimide substrate, a polyphenylene sulfide substrate, a silicone substrate, an acrylic resin substrate, an epoxy resin substrate, a polyethylene terephthalate substrate, a polybutylene terephthalate substrate, a polyethylene naphthalate substrate, or a polycarbonate substrate. The support may be a rigid substrate. Examples of the rigid substrate include a glass substrate, a quartz substrate, a crystal substrate, and a sapphire substrate. The surface of the support on the film side may have been subjected to a surface treatment with a silane coupling agent or the like from the viewpoint of improving adhesion to the film and improving peelability. The thickness of the support is preferably 10 to 200 μm from the viewpoint of handleability.

The first aspect of the laminate of the present invention is preferably a laminate including a first support, the film of the present invention, and a second support arranged in this order from the viewpoint of improving handleability and protecting the surface of the film. Preferably, the first support and the second support are different in thickness.

Examples and preferred descriptions of the first support and the second support are the same as those of the support described above. The second support is preferably a protective film, and is preferably a polyethylene film, a polypropylene film, a polyester film, a polyethylene terephthalate film, a polybutylene terephthalate film, or a polyethylene naphthalate film. The second support preferably has a small adhesive force with the film from the viewpoint of handleability.

### Embodiment 1 of Laminate

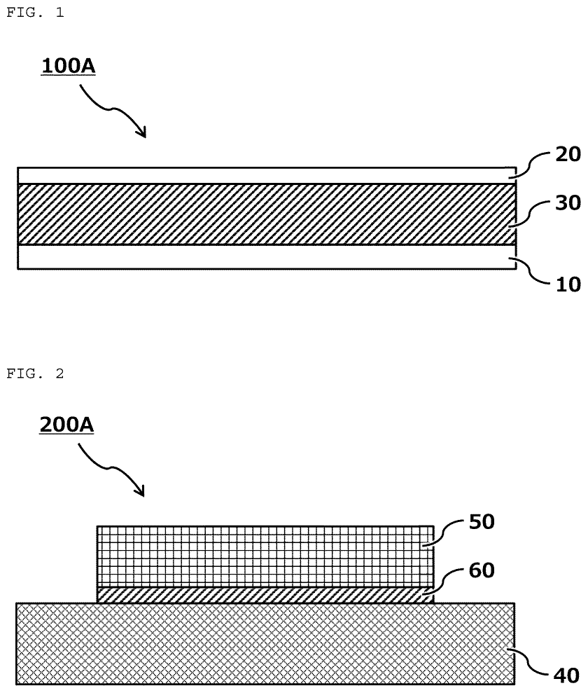

FIG. 1 shows a schematic sectional view of one configuration example of Embodiment 1 of the laminate. A laminate 100A shown in FIG. 1 is a laminate including a first support 10, a film 30 of the present invention, and a second support 20 arranged in this order. The first support 10 and the second support 20 are as described above. The film 30 is the film of the present invention, and is preferably in a semi-cured state (B stage). The film 30 is preferably a layer formed from a composition for forming the film of the present invention.

### <Film as Cured Product of Composition, and Laminate>

The film of the present invention is preferably a cured product of a composition. The composition is preferably a composition for forming the film of the present invention. Curing means that a cross-linked structure is formed by a reaction, and the fluidity of the film is lost, or a state thereof. The reaction is not particularly limited and may be one performed by heating, one performed by irradiation with an energy ray, or the like, and is preferably one performed by heating. A state in which a cross-linked structure has been formed by heating and the fluidity of the film has been lost is referred to as thermal curing.

The heating condition is, for example, a condition of heating at 150 to 500 °C for 5 to 300 minutes. Examples of the heating method include a method of heating using an oven, a hot plate, infrared rays, a flash annealing device, or a laser annealing device. Examples of the treatment atmosphere include an air, oxygen, nitrogen, helium, neon, argon, krypton, or xenon atmosphere, a gas atmosphere containing 1.0 ppm by mass or more and less than 10,000 ppm by mass (0.00010% by mass or more and less than 1.0% by mass) of oxygen, a gas atmosphere containing 10,000 ppm by mass (1.0% by mass) or more of oxygen, and a vacuum atmosphere.

The film of the present invention can have both high adhesion for joining members to each other even at a cryogenic temperature of about −50 °C and high thermal cycle reliability. Therefore, the film of the present invention is preferably used in a substrate treatment step at a temperature of 0 °C or less, and more preferably used for formation of a laminate during which a substrate treatment step is performed at a temperature of 0 °C or less. The temperature of the substrate treatment step in which the laminate is used is more preferably-20 °C, still more preferably-40 °C or less, further preferably-50 °C or less, and particularly preferably-60 °C or less. Meanwhile, the temperature of the substrate treatment step is preferably-150 °C or more, more preferably-100 °C or more, and still more preferably −80 °C or more. The substrate treatment step is preferably one or more selected from the group consisting of sputtering, vapor deposition, chemical vapor deposition, ion implantation, etching, ashing, exposure, and inspection.

The film of the present invention may be used in a substrate treatment step at a temperature higher than 0 °C, or may be used for formation of a laminate in which a substrate treatment step is performed at a temperature higher than 0 °C. In that case, the temperature of the substrate treatment step in which the laminate is used is preferably 20 °C or more, more preferably 40 °C or more, and still more preferably 60 °C or more. Meanwhile, the temperature of the substrate treatment step is preferably 150 °C or less, more preferably 100 °C or less, and still more preferably 80 °C or less.

The film preferably has a plurality of through holes. The method of processing a through hole is preferably a punch hole method, a press processing method, a laser processing method, a laser direct imaging method, a laser direct structuring method, a printing method, an inkjet method, an etching method, or a photolithography method.

The second aspect of the laminate of the present invention is a laminate, including: a base plate; a film of the present invention; and a ceramic dielectric plate arranged in this order, wherein the base plate and the ceramic dielectric plate are different in coefficient of thermal expansion. In the second aspect of the laminate of the present invention, the film is preferably a cured product of a composition. In the second aspect of the laminate of the present invention, the elastic modulus of the film at 25 °C. is preferably 0.010 to 1.0 MPa, and the film is also preferably in a semi-cured state.

It is suitable to take the configuration as described above from the viewpoint of improving the adhesion in the case of joining the base plate to a ceramic member, and the effect of suppressing peeling of the base plate and the ceramic dielectric plate is made thereby remarkable even when these members are different in coefficient of thermal expansion.

The difference in coefficient of thermal expansion between the base plate and the ceramic dielectric plate is preferably 1.0 ppm/K or more, more preferably 5.0 ppm/K or more, and still more preferably 10 ppm/K or more from the viewpoint of improving the adhesion and heat radiation efficiency in the substrate treatment step. Meanwhile, the difference in coefficient of thermal expansion is preferably 30 ppm/K or less, more preferably 25 ppm/K or less, and still more preferably 20 ppm/K or less.

### <Content of Specific Element and Content of Specific Ion in Film of Laminate>

The film of the laminate of the present invention preferably satisfies at least one of the conditions (S1a), (S2a), (S3a), (S1b), (S2b), and (S3b) similar to the film of the present invention from the viewpoint of improving the adhesion at a cryogenic temperature of about −50 °C and improving the thermal cycle reliability. In the case of taking the configuration as described above, the film of the laminate of the present invention preferably contains the above-described (I) and/or (II) in the same manner as the film of the present invention.

A preferred range of the content of boron element, a preferred range of the content of phosphorus element, and a preferred range of the total content of chlorine element and bromine element in the film of the laminate are also the same as those in the film of the present invention. A preferred range of the total content of boron element-containing ions, a preferred range of the total content of phosphorus element-containing ions, and a preferred range of the total content of chloride ion and bromide ion in the film of the laminate are also the same as those described above.

The film of the laminate of the present invention preferably satisfies at least one of the conditions (S4a) and (S4b) similar to the film of the present invention from the viewpoint of improving the adhesion at a cryogenic temperature of about −50 °C and improving the thermal cycle reliability. In the case of taking the configuration as described above, the film of the laminate of the present invention preferably contains a platinum element-containing component and/or a platinum cation-containing component in the same manner as the film of the present invention.

A preferred range of the content of platinum element in the film of the laminate is also the same as that of the film of the present invention. A preferable range of the total content of the platinum element-containing ions in the film of the laminate is also the same as that of the film of the present invention.

### <Content of Specific Silicon Compound and Content of Cyclic Silicone Compound in Film of Laminate>

The film of the laminate of the present invention preferably satisfies at least one of the conditions (S5a) and (S5b) similar to the film of the present invention from the viewpoint of improving the adhesion at a cryogenic temperature of about −50 °C and improving the thermal cycle reliability. In the case of taking the configuration as described above, examples and preferred descriptions regarding the specific silicon compound and the cyclic silicone compound are also as described above.

A preferred range of the total content of the specific silicon compound and a preferred range of the total content of the cyclic silicone compound in the film of the laminate are also the same as described above.

### <Base Plate>

The second aspect of the laminate of the present invention includes a base plate. The base plate is preferably made of metal and various composite materials. The metal is preferably aluminum, titanium, or an alloy thereof. The composite material is preferably one obtained by melting an aluminum alloy containing aluminum as a main component and pressure-impregnating a porous ceramic containing silicon carbide as a main component with the melt. The aluminum alloy in the composite material may contain silicon or magnesium, and may contain other elements.

### <Ceramic Dielectric Plate>

The second aspect of the laminate of the present invention includes a ceramic dielectric plate. The ceramic dielectric plate is preferably a flat plate-shaped base material made of sintered ceramic. From the viewpoint of mechanical strength, abrasion resistance, plasma resistance, thermal conductivity, and insulation property, the ceramic dielectric plate preferably includes one or more selected from the group consisting of aluminum oxide (alumina: Al₂O₃), aluminum nitride, silicon carbide, silicon nitride, and yttrium oxide (yttria: Y₂O₃), and more preferably includes aluminum oxide or aluminum nitride as a main component. The main component refers to a component that is contained most on a mass basis in the constituent components.

### Embodiment 2 of Laminate

FIG. 2 shows a schematic sectional view of one configuration example of Embodiment 2 of the laminate. A laminate 200A shown in FIG. 2 is a laminate including a base plate 40, a film 60 of the present invention, and a ceramic dielectric plate 50 arranged in this order. The base plate 40 and the ceramic dielectric plate 50 are as described above. The film 60 is the film of the present invention, and is preferably a cured product of a composition. The film 60 is preferably a layer formed from a composition for forming the film of the present invention.

### <Electrostatic Chuck Including Laminate>

The electrostatic chuck of the present invention includes a laminate including the film of the present invention. In addition, the film of the present invention can have both high adhesion for joining members to each other even at a cryogenic temperature of about −50 °C and high thermal cycle reliability. Therefore, the film of the present invention is preferably used in a substrate treatment step at a temperature of 0 °C or less, and more preferably used for formation of an electrostatic chuck in a substrate treatment step at a temperature of 0 °C or less. That is, the film of the present invention is suitable for applications of an electrostatic chuck. The film of the present invention is particularly suitable for the applications of an electrostatic chuck to be used at 0 °C or less, and is particularly suitable for the applications of an electrostatic chuck to be used at −50 °C or less. A preferred range of the temperature in the substrate treatment step in which the electrostatic chuck is used is also the same as the temperature in the substrate treatment step in which the laminate is used. The substrate treatment step is preferably one or more selected from the group consisting of sputtering, vapor deposition, chemical vapor deposition, ion implantation, etching, ashing, exposure, and inspection.

The film of the present invention may be used in a substrate treatment step at a temperature higher than 0 °C, or may be used for formation of an electrostatic chuck in a substrate treatment step at a temperature higher than 0 °C. In that case, a preferred range of the temperature of the substrate processing step in which the electrostatic chuck is used is also the same as the temperature of the substrate treatment step in which the laminate is used.

### <Article Including Laminate>

The laminate of the present invention is applicable to various articles. As the article, an article including an electrostatic chuck including the laminate of the present invention is preferable. Examples of the article including the laminate or the article including the electrostatic chuck include an electronic device, a moving body, a construction, and a window. Examples of the electronic device include a display device, a semiconductor device, a metal-clad laminate, an industrial device, a medical device, and a building device. Examples of the moving body include a vehicle, a railway, an airplane, and a heavy machine. Examples of the construction include a house, a store, an office, a building, and a factory. Examples of the window include an electronic device window, a moving body window, and a construction window.

### <Plasma Processing Apparatus Including Laminate>

The plasma processing apparatus of the present invention includes a plasma source and the laminate of the present invention. The plasma processing apparatus of the present invention preferably includes a plasma source and an electrostatic chuck including the laminate of the present invention. Such a configuration is suitable from the viewpoint of increasing the aspect ratio in the etching step and reducing the process time in that step, and is suitably used for densification and increase in the degree of integration of a 3D-NAND memory or the like.

The plasma processing apparatus of the present invention is an apparatus in which a substrate to be processed such as a semiconductor wafer is placed on a laminate (preferably an electrostatic chuck) provided in a vacuum chamber, and plasma is generated by applying a high-frequency voltage under a vacuum environment to perform etching or the like. The electrostatic chuck in the plasma processing apparatus is a laminate in which a ceramic dielectric plate including a heater electrode and an electrostatic electrode both built therein and a base plate, which is a cooling plate having a refrigerant flow path formed therein, are joined with a film.

The plasma processing apparatus is provided inside a vacuum chamber, with a stage on which a semiconductor wafer is to be placed, and the stage is composed mainly of an electrostatic chuck and a cooler for controlling the temperature of the electrostatic chuck. In recent years, high processing accuracy has been required in the manufacturing of semiconductor devices, and etching processing at a cryogenic temperature of −30 °C or less is required in formation of vias with a high aspect ratio. Therefore, it is necessary to cool the ceramic dielectric plate by cooling the base plate, which is a cooling plate, to −30 °C or less. The film of the present invention for joining these members can reduce thermal resistance at the interface between both members, and therefore can improve cooling efficiency.

### <Article Including Film and Article Including Laminate>

The article including the film of the present invention and the laminate including the film of the present invention are also suitable for use in applications other than electrostatic chucks. Examples of such other applications include a vacuum chuck in addition to the articles enumerated above as examples.

### <Method for Manufacturing Laminate>

The method for manufacturing a laminate of the present invention is a method for manufacturing a laminate including a step of disposing a base plate, a step of disposing the film of the present invention, and a step of disposing a ceramic dielectric plate.

The step of disposing the film of the present invention is preferably performed after the step of disposing the base plate, and the film is preferably disposed on the base plate. That is, the method for manufacturing a laminate of the present invention preferably includes the step of disposing the film of the present invention after the step of disposing the base plate, and the step of disposing the ceramic dielectric plate is preferably performed after the step of disposing the film of the present invention.

The step of disposing the film of the present invention is also preferable to be performed after the step of disposing the ceramic dielectric plate, and it is also preferable to dispose the film on the ceramic dielectric plate. That is, the method for manufacturing a laminate of the present invention includes the step of disposing the film of the present invention after the step of disposing the ceramic dielectric plate, and it is also preferable to perform the step of disposing the base plate after the step of disposing the film of the present invention.

### <Step of Disposing Base Plate>

The step of disposing the base plate is preferably a step of disposing the base plate on an article, and a step of disposing the base plate fixed to an article is also preferable. When the step of disposing the base plate is performed after the step of disposing the film of the present invention, the base plate is preferably disposed on the film of the present invention. The step of disposing the base plate is also preferably a step of forming a base plate on a support, disposing the base plate having the support, and then peeling the support from the base plate. The base plate having the support preferably has been disposed with these members bonded by an adhesive or the like.

Examples of the article include an electronic device, a moving body, a construction, and a window. Examples of the electronic device include a display device, a semiconductor device, a metal-clad laminate, an industrial device, a medical device, and a building device. Examples of the moving body include a vehicle, a railway, an airplane, and a heavy machine. Examples of the construction include a house, a store, an office, a building, and a factory. Examples of the window include an electronic device window, a moving body window, and a construction window.

The base plate may be a commercially available metal member. The step of disposing the base plate may be a step of disposing a commercially available metal member as the base plate on an article.

### <Step of Disposing Ceramic Dielectric Plate>

The step of disposing the ceramic dielectric plate is preferably a step of disposing the ceramic dielectric plate on an article. When the step of disposing the ceramic dielectric plate is performed after the step of disposing the film of the present invention, the ceramic dielectric plate is preferably disposed on the film of the present invention. The step of disposing the ceramic dielectric plate is also preferably a step of forming the ceramic dielectric plate on the support, disposing the ceramic dielectric plate having the support, and then peeling the support from the ceramic dielectric plate. The ceramic dielectric plate having the support preferably has been disposed with these members bonded by an adhesive or the like. Examples of the article include the articles enumerated above as examples for the base plate.

The ceramic dielectric plate may be a commercially available ceramic member. The step of disposing the ceramic dielectric plate may be a step of disposing a commercially available ceramic member as the ceramic dielectric plate on an article.

### <Step of Disposing Film>

The step of disposing the film of the present invention is preferably a step of joining the film of the present invention by thermocompression bonding, and it is preferable to join the film of the present invention onto the base plate by thermocompression bonding. Similarly, it is also preferable to join the film of the present invention onto the ceramic dielectric plate by thermocompression bonding. In the step of disposing the base plate, it is also preferable to join the base plate onto the film of the present invention by thermocompression bonding. Similarly, in the step of disposing the ceramic dielectric plate, it is also preferable to join the ceramic dielectric plate onto the film of the present invention by thermocompression bonding. The method of joining by thermocompression bonding is preferably a hot press treatment, a hot lamination treatment, or a hot vacuum lamination treatment.

When the film of the present invention having the first support and the second support is used, it is preferable to dispose the film of the present invention after the second support is peeled off. The first support may be peeled off after the film of the present invention is disposed, or may be peeled off during or after the film of the present invention is joined by such a method as thermocompression bonding.

### EXAMPLES

The present invention will be described more concretely hereinafter with reference to Examples, Reference Examples, and Comparative Examples. However, the present invention is not limited to scopes thereof. Among the compounds used in the following description or tables, for those where abbreviations are used, the names corresponding to the abbreviations are listed below. The structures of KF-8010, X-22-161A, X-22-161B, X-22-168A, and X-22-168AS are shown below. The main component refers to a component that is contained most on a mass basis in the constituent components.
ABPS: bis(3-amino-4-hydroxyphenyl) sulfone
BAHF: 2, 2-bis(3-amino-4-hydroxyphenyl) hexafluoropropane
BAP: 2,2-bis(3-amino-4-hydroxyphenyl) propane
BAPF: 9,9-bis(3-amino-4-hydroxyphenyl) fluorene
cyEpoTMS: 2-(3,4-epoxycyclohexyl)ethyltrimethoxysilane
DMeDMS: dimethyldimethoxysilane
DPhDMS: diphenyldimethoxysilane
KF-8010: dual-end amino group-modified dimethyl silicone represented by the general formula (IIa) (x=7 to 11 is a main component), number average molecular weight: 860, amino group equivalent: 430 g/mol
MePhDMS: methyldimethoxysilane
MeTMS: methyltrimethoxysilane
ODPA: 4,4′-oxydiphthalic dianhydride
PET: polyethylene terephthalate
PhTMS: phenyltrimethoxysilane
TEGDM: triethylene glycol dimethyl ether
X-22-161A: dual-end amino group-modified dimethyl silicone represented by the general formula (IIa) (x=15 to 23 is a main component), number average molecular weight: 1,600, amino group equivalent: 800 g/mol
X-22-161B: dual-end amino group-modified dimethyl silicone represented by the general formula (IIa) (x=32 to 44 is a main component), number average molecular weight: 3,000, amino group equivalent: 1,500 g/mol
X-22-168A: dual-end carboxylic acid anhydride group-modified dimethyl silicone represented by the general formula (12a) (y=18 to 26 is a main component), number average molecular weight: 2,000, acid anhydride equivalent: 1,000 g/mol
X-22-168AS: dual-end carboxylic acid anhydride group-modified dimethyl silicone represented by the general formula (12a) (y=6 to 10 is a main component), number average molecular weight: 1,000, acid anhydride equivalent: 500 g/mol.

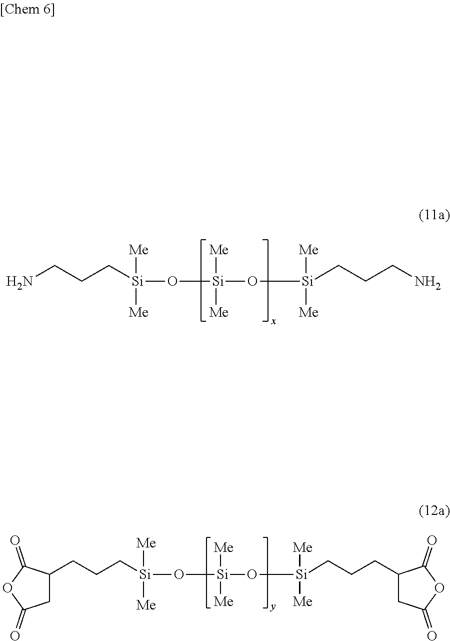

### Synthesis Example of Each Resin

As the (SA) binder resin, the compositions of the resins obtained in Synthesis Examples 1 to 19 are collectively shown in Tables 1 and 2.

### Synthesis Example 1 Synthesis of Polyimide (PI-1)

A stirrer, a thermometer, a nitrogen introducing tube, and a dropping funnel were set to a 300-mL four-necked flask, and 40.00 g (0.040 mol; 100 mol % with respect to all carboxylic acid residues; molar ratio based on acid anhydride groups=100) of X-22-168AS, and 79.33 g of TEGDM were weighed therein, and stirred and dissolved at 60 °C. under a dry nitrogen stream. Then, while stirring at 60 °C, 7.33 g (0.020 mol; 50 mol % based on all amine residues; molar ratio based on amino groups=50) of BAHF and 32.00 g (0.020 mol; 50 mol % based on all amine residues; molar ratio based on amino groups=50) of X-22-161A were added, and the mixture was stirred for 1 hour. Thereafter, the mixture was heated to 180 °C and stirred for 3 hours, then cooled to room temperature, affording a polyimide (PI-1) solution having a solid concentration of 50% by mass. The polyimide obtained had a weight-average molecular weight of 29,000 and an imidization rate of 99%.

In Synthesis Examples 2 to 11, polyimides (PI-2) to (PI-11) were synthesized by the method described in Synthesis Example 1 with appropriate change of the monomer compounds to serve as monomers and the copolymerization ratios. The copolymerization ratios of the monomers are as shown in Table 1.

### Synthesis Example 12 Synthesis of Silicone Resin (SR-1)

A three-necked flask was charged with 52.30 g (87 mol %) of DMeDMS, 2.73 g (3 mol %) of DPhDMS, 3.41 g (5 mol %) of MeTMS, 6.16 g (5 mol %) of cyEpoTMS, and 61.63 g of PGMEA. Air was allowed to flow through the flask at 0.05 L/min, and the mixed solution was heated to 40 °C. while stirring in an oil bath. While the mixture solution was further stirred, an aqueous phosphoric acid solution in which 0.194 g of phosphoric acid was dissolved in 19.37 g of water was added over 10 minutes. After the addition ended, stirring was performed at 40 °C for 30 minutes to hydrolyze the silane compounds. After the hydrolysis ended, the bath temperature was raised to 70 °C and stirring was performed for 1 hour. Subsequently, the bath temperature was raised up to 115 °C. About 1 hour after the initiation of the temperature raising, the internal temperature of the solution reached 100 °C, and subsequently, the solution was heated and stirred for 2 hours (the internal temperature was 100 to 110 °C). The resin solution obtained by heating and stirring for 2 hours was cooled in an ice bath, affording a silicone resin (SR-1) solution having a solid concentration of 40% by mass. The silicone resin obtained had a weight-average molecular weight of 4,000.

In Synthesis Example 13 to 15, silicone resins (SR-2) to (SR-4) were synthesized by the method described in Synthesis Example 12 with appropriate change of the monomer compounds to serve as monomers and the copolymerization ratios. The copolymerization ratios of the monomers are as shown in Table 2.

### Synthesis Example 16 Synthesis of Polysiloxane (PS-1)

A three-necked flask was charged with 38.82 g (57 mol %) of MeTMS, 2.97 g (3 mol %) of PhTMS, 21.04 g (35 mol %) of DMeDMS, 6.16 g (5 mol %) of cyEpoTMS, and 57.15 g of PGMEA. Air was allowed to flow through the flask at 0.05 L/min, and the mixed solution was heated to 40 °C. while stirring in an oil bath. While the mixture solution was further stirred, an aqueous phosphoric acid solution in which 0.207 g of phosphoric acid was dissolved in 24. 33 q of water was added over 10 minutes. After the addition ended, stirring was performed at 40 °C for 30 minutes to hydrolyze the silane compounds. After the hydrolysis ended, the bath temperature was raised to 70 °C and stirring was performed for 1 hour. Subsequently, the bath temperature was raised up to 115 °C. About 1 hour after the initiation of the temperature raising, the internal temperature of the solution reached 100 °C, and subsequently, the solution was heated and stirred for 2 hours (the internal temperature was 100 to 110 °C). The resin solution obtained by heating and stirring for 2 hours was cooled in an ice bath, affording a polysiloxane (PS-1) solution having a solid concentration of 40% by mass. The polysiloxane obtained had a weight-average molecular weight of 5,500.

In Synthesis Examples 17 to 19, polysiloxanes (PS-2) to (PS-4) were synthesized by the method described in Synthesis Example 16 with appropriate change of the monomer compounds to serve as monomers and the copolymerization ratios. The copolymerization ratios of the monomers are as shown in Table 2.

TABLE 1

| | | | | | | | | Weight- | |
|---|---|---|---|---|---|---|---|---|---|
| | | Monomer [mol %] | | | | | | average | Imidization |
| | | Acid monomer (molar ratio | | | Amine monomer (molar ratio | | | molecular | rate |
| | Polymer | based on acid anhydride group) | | | based on amino group) | | | weight | [%] |
| Synthesis | Polyimide | X-22-168AS | — | — | X-22-161A | — | BAHF | 29,000 | 99 |
| Example 1 | (PI-1) | (100) | | | (50) | | (50) | | |
| Synthesis | Polyimide | X-22-168AS | — | — | X-22-161A | — | BAHF | 20,000 | 99 |
| Example 2 | (PI-2) | (100) | | | (70) | | (30) | | |
| Synthesis | Polyimide | X-22-168AS | — | — | X-22-161A | — | BAHF | 19,000 | 99 |
| Example 3 | (PI-3) | (100) | | | (90) | | (10) | | |
| Synthesis | Polyimide | X-22-168AS | — | — | — | X-22-161B | BAHF | 19,000 | 99 |
| Example 4 | (PI-4) | (100) | | | | (90) | (10) | | |
| Synthesis | Polyimide | — | X-22-168A | — | X-22-161A | — | BAHF | 17,000 | 99 |
| Example 5 | (PI-5) | | (100) | | (90) | | (10) | | |
| Synthesis | Polyimide | X-22-168AS | — | ODPA | X-22-161A | — | BAHF | 24,000 | 99 |
| Example 6 | (PI-6) | (50) | | (50) | (90) | | (10) | | |
| Synthesis | Polyimide | X-22-168AS | — | ODPA | X-22-161A | — | BAHF | 30,000 | 99 |
| Example 7 | (PI-7) | (10) | | (90) | (90) | | (10) | | |
| Synthesis | Polyimide | X-22-168AS | — | — | X-22-161A | — | BAP | 19,000 | 99 |
| Example 8 | (PI-8) | (100) | | | (90) | | (10) | | |
| Synthesis | Polyimide | X-22-168AS | — | — | X-22-161A | — | ABPS | 19,000 | 99 |
| Example 9 | (PI-9) | (100) | | | (90) | | (10) | | |
| Synthesis | Polyimide | X-22-168AS | — | — | X-22-161A | — | BAPF | 19,000 | 99 |
| Example 10 | (PI-10) | (100) | | | (90) | | (10) | | |
| Synthesis | Polyimide | — | — | ODPA | — | — | BAHF | 39,000 | 99 |
| Example 11 | (PI-11) | | | (100) | | | (100) | | |

TABLE 2

| | | | | | | | Weight- |
|---|---|---|---|---|---|---|---|
| | | Monomer [mol %] | | | | | average |
| | | Bifunctional | | Trifunctional | | | molecular |
| | Polymer | organosilane | | organosilane | | | weight |
| Synthesis | Silicone resin | DMeDMS | DPhDMS | MeTMS | — | cyEpoTMS | 4,000 |
| Example 12 | (SR-1) | (87) | (3) | (5) | | (5) | |
| Synthesis | Silicone resin | DMeDMS | DPhDMS | MeTMS | — | cyEpoTMS | 3,700 |
| Example 13 | (SR-2) | (85) | (5) | (5) | | (5) | |
| Synthesis | Silicone resin | DMeDMS | DPhDMS | MeTMS | — | cyEpoTMS | 3,500 |
| Example 14 | (SR-3) | (80) | (10) | (5) | | (5) | |
| Synthesis | Silicone resin | DMeDMS | DPhDMS | MeTMS | — | cyEpoTMS | 3,200 |
| Example 15 | (SR-4) | (75) | (15) | (5) | | (5) | |
| Synthesis | Polysiloxane | DMeDMS | — | MeTMS | PhTMS | cyEpoTMS | 5,500 |
| Example 16 | (PS-1) | (35) | | (57) | (3) | (5) | |
| Synthesis | Polysiloxane | DMeDMS | — | MeTMS | PhTMS | cyEpoTMS | 5,200 |
| Example 17 | (PS-2) | (35) | | (55) | (5) | (5) | |
| Synthesis | Polysiloxane | DMeDMS | — | MeTMS | PhTMS | cyEpoTMS | 5,000 |
| Example 18 | (PS-3) | (35) | | (50) | (10) | (5) | |
| Synthesis | Polysiloxane | DMeDMS | — | MeTMS | PhTMS | cyEpoTMS | 4,700 |
| Example 19 | (PS-4) | (35) | | (45) | (15) | (5) | |

The structural units and structures of the resins obtained in the Synthesis Examples and the resins used in Examples, Reference Examples, and Comparative Examples are collectively shown below.

### Polyimides (PI-1) to (PI-7)

These polyimides have a main chain containing a polyimide structure, a diamine residue having a structure represented by the general formula (11), and a tetracarboxylic acid anhydride residue having a structure represented by the general formula (12). The content of a fluorine element in the structure of a resin of these polyimides is 29, 300 ppm by mass for (PI-1), 15, 600 ppm by mass for (PI-2), 4,700 ppm by mass for (PI-3), 3,100 ppm by mass for (PI-4), 3,300 ppm by mass for (PI-5), 5,400 ppm by mass for (PI-6), and 6,200 ppm by mass for (PI-7).

### Polyimides (PI-8) to (PI-10)

These polyimides have a main chain containing a polyimide structure, a diamine residue having a structure represented by the general formula (11), and a tetracarboxylic acid anhydride residue having a structure represented by the general formula (12).

The content of a fluorine element in the structure of a resin of these polyimides is 0.000 ppm by mass.

### Polyimide (PI-11)

This polyimide has a main chain containing a polyimide structure. The content of a fluorine element in the structure of a resin of this polyimide is 168, 500 ppm by mass.

### Silicone Resins (SR-1) to (SR-4)

These silicone resins have a main chain containing a silicone resin structure, a bifunctional organosilane unit and a trifunctional organosilane unit each having an aliphatic group, a trifunctional organosilane unit having an aromatic group, and a trifunctional organosilane unit having an epoxy group.

### Polysiloxanes (PS-1) to (PS-4)

These polysiloxanes have a main chain containing a polysiloxane structure, a bifunctional organosilane unit and a trifunctional organosilane unit each having an aliphatic group, a trifunctional organosilane unit having an aromatic group, and a trifunctional organosilane unit having an epoxy group.

### Evaluation methods in Examples, Reference Examples, and Comparative Examples

Evaluation methods in Examples, Reference Examples, and Comparative Examples are described below.

### (1) Weight-Average Molecular Weight of Resin

For the polyimides (PI-1) to (PI-11) described above, each resin was dissolved in N-methyl-2-pyrrolidone to prepare a 0.10% by mass N-methyl-2 pyrrolidone solution. A polystyrene-equivalent weight-average molecular weight was measured and determined using a GPC analyzer (Waters 2690, manufactured by Waters Corporation) under the following measurement conditions.
<GPC measurement conditions>
Detector: Waters 996
System controller: Waters 2690
Column oven: Waters HTR-B
Thermo controller: Waters TCM
Column: TOSOH Guard Column
Column: TOSOH TSK-GEL x-4000
Column: TOSOH TSK-GEL x-2500
Fluid layer: N-methyl-2-pyrrolidone in which lithium chloride and phosphoric acid are each dissolved at 0.050 mol/L
Development rate: 0.40 mL/min.

The silicone resins (SR-1) to (SR-4) and the polysiloxanes (PS-1) to (PS-4) were subjected to measurement and determination of a polystyrene-equivalent weight-average molecular weight by a method near normal temperature in accordance with “JIS K7252-3 (2008)” using a GPC analyzer (HLC-8220; manufactured by Tosoh Corporation) and using tetrahydrofuran or N-methyl-2-pyrrolidone as a fluid layer.

### (2) Imidization Rate of Polyimide

Using a Fourier transform infrared spectrophotometer (FT-720; manufactured by Horiba, Ltd.), the infrared absorption spectrum of each polyimide was measured, and the presence or absence of absorption peaks (a peak around 1, 780 cm⁻¹ and a peak around 1, 377 cm⁻¹) of the imide structure of the polyimide was confirmed. Each of the polyimides measured was heated at 350 °C for 1 hour, whereby a polyimide precursor structure (such as a polyamic acid structure and a polyamic ester structure) in each of the polyimides was imide-cyclized. The infrared absorption spectrum of each polyimide after the heating was measured, and the peak intensities around 1, 377 cm⁻¹ before and after the heating were compared. The imidization rate of the polyimide before the heating was calculated with the peak intensity of the polyimide after the heating taken as the imidization rate of 100%.

### (3) Average Primary Particle Size of Filler in Filler Dispersion

Each filler was dispersed in methanol to prepare a methanol dispersion. Using a laser diffraction/scattering particle size distribution analyzer (LA-920; manufactured by Horiba, Ltd.), the particle size distribution of each filler was measured by a laser diffraction/scattering method. From the particle size distribution, D50, at which the cumulative particle size distribution on a volume basis from the smaller particle size side was 50%, was calculated. The measurement was performed twice, and the average value was taken as the average primary particle size of the filler in the filler dispersion.

### (4) Average Primary Particle Size of Filler in Film

A film having a thickness of 250 μm, which was a cured film of a composition, was formed on a PET film having a thickness of 38 μm by the method described in Example 1 below. The PET film was peeled off, a section of the remaining film was imaged and analyzed using a transmission electron microscope, and the primary particle size of the filler was measured. The average value obtained by measuring 30 primary particles of the filler was determined as the average primary particle size of the filler in the film.

### (5) Volume Fraction of Filler in Film

The film was heated at 800 °C to thermally decompose and/or volatilize organic components such as a resin. The mass of the remaining filler was measured, and the mass of the organic components such as the resin was calculated from the difference in mass. The masses obtained were divided by the respective specific gravities to determine the volumes of the respective components. The volume fraction of the filler was calculated with the total of the volumes of the respective components taken as 100% by volume.

### (6) Contents of a Boron Element, Phosphorus Element, Chlorine Element, Bromine Element, and Fluorine Element in Film

The contents of a boron element, phosphorus element, chlorine element, bromine element, and fluorine element were measured by combustion ion chromatography under the following measurement conditions. The film was burned and decomposed in a combustion tube of an analyzer, the generated gas was absorbed into an absorbent, and a part of the absorbent was analyzed by ion chromatography. When the element content is not described, it indicates that the element is not detected.

### <Combustion/Absorption Conditions>

System: AQF-2100H and GA-210 (manufactured by Mitsubishi Chemical Corporation)
Temperature of electric furnace: 900 °C. at the inlet and 1,000 °C. at the outlet
Gas: Ar/O₂ 200 mL/min, O₂ 400 mL/min
Absorbent: H₂O₂ 0.1% by mass
Volume of absorbent: 5 mL

### <Ion Chromatography/Anion Analysis Conditions>

System: ICS1600 (manufactured by DIONEX)
Mobile phase: 2.7 mmol/L Na₂CO₃, 0.3 mmol/L NaHCO₃
Flow rate: 1.50 mL/min
Detector: electrical conductivity detector
Injection amount: 100 μL.

### (7) Platinum Element Content in Film

The content of platinum element was measured by inductively coupled plasma mass spectrometry using a calibration curve by a standard substance and inductively coupled plasma-atomic emission spectroscopy.

### (8) Content of Specific Ion Content in Film

The contents of boron element-containing ions, phosphorus element-containing ions, chloride ion, bromide ion, platinum element-containing ions, and fluoride ion were measured by ion chromatography under the following measurement conditions. A film was added to a 10 mmol/L aqueous potassium hydroxide solution, and the mixture was shaken for 2 hours to extract ionic components. The extract was filtered under the following conditions, and then cation components and anion components were analyzed by ion chromatography. When the ion content is not described, it indicates that the ion is not detected.

### <Filtration Treatment Conditions>

Membrane filter: 0.22 μmφ, PVDF (manufactured by Merck Millipore)
Solid phase extraction cartridge: InertSep Slim-J PLS-3 (manufactured by GL Sciences Inc.)
Cation exchange cartridge: OnGuard II H (manufactured by Thermo Fisher Scientific Inc.)

### <Ion Chromatography Analysis Conditions>

Instrument: ICS-5000⁺ (manufactured by Thermo Fisher Scientific Inc.)
Separation column: 2 mmφ 250 mm, IonPac AS11-HC-4 μm
Eluent: potassium hydroxide/gradient
Detector: electrical conductivity detector
Sample injection volume: 100 μL.

### (9) Thermal Conductivity of Film

A film having a thickness of 250 μm, which was a cured film of a composition, was formed on a PET film having a thickness of 38 μm by the method described in Example 1 below. The PET film was peeled off, and the thermal diffusivity of the remaining film was measured using a Laser Flash method thermal diffusivity measuring apparatus (LFA 447; manufactured by NETZSCH). In addition, the specific gravity of the film was measured by the Archimedes method, and the specific heat of the film was measured by the differential scanning calorimetry. The thermal conductivity at 25 °C. was calculated from the measured value obtained and the following formula. Thermal conductivity [W/(m·K)]=Thermal diffusivity [m²/s]×Specific gravity [kg/m³]×Specific heat [J/(kg·K)].

### (10) Elastic Modulus of Film

A film having a thickness of 250 μm, which was a cured film of a composition, was formed on a PET film having a thickness of 38 μm by the method described in Example 1 below. The PET film was peeled off, the remaining film was cut into a shape of 5.0 mm wide×30 mm long, and the elastic modulus of the film was measured using a dynamic viscoelasticity measuring device (DVA-200; manufactured by IT Measurement Control Co., Ltd.). The storage elastic modulus at each temperature in the range of from −100 to 300 °C. was measured under the measurement conditions of a temperature raising rate of 5.0 °C/min and a measurement frequency of 1 Hz, and the elastic modulus at −50 °C. was determined.

### (11) Shear Strain and Shear Adhesion Strength (Bonding Adhesion) of Film

A film in a semi-cured state of a composition was formed on a PET film having a thickness of 38 μm by the method described in Example 1 below such that a cured film would come to have a thickness of 250 μm. The laminate in which the film in the semi-cured state was formed was cut into a shape of 12.5 mm wide×25 mm long, and was subjected to a thermal lamination treatment on an aluminum plate of 25 mm wide×100 mm long×1.6 mm thick under the conditions of 60 °C and 0.10 MPa. Then, the PET film was peeled off, and an aluminum plate of 25 mm wide×100 mm long×1.6 mm thick was laminated and hot-pressed at 180 °C and 0.50 MPa for 1 hour to prepare a laminate. The laminate obtained was subjected to a shear test in accordance with “JIS K6850” using a universal testing machine (AGX-V; manufactured by Shimadzu Corporation). Under the test conditions of a temperature of −50 °C and a tensile speed of 2.0 mm/min, the stress at break and the shear deformation were measured. The shear strain at −50 °C was calculated from the shear deformation, and the stress at break was taken as the shear adhesion strength at −50 °C as an index of bonding adhesion. It has been determined as follows that A+, A, B+, B, C+, and C where the shear adhesion strength is 0.5 MPa or more are regarded as pass, A+, A, B+, and B where the shear adhesion strength is 1.5 MPa or more are regarded as good, and A+ and A where the shear adhesion strength is 1,000 or more are regarded as excellent.
A+: The shear adhesion strength is 3.0 or more
A: The shear adhesion strength is 2.5 or more and less than 3.0
B+: The shear adhesion strength is 2.0 or more and less than 2.5
B: The shear adhesion strength is 1.5 or more and less than 2.0
C+: The shear adhesion strength is 1.0 or more and less than 1.5
C: The shear adhesion strength is 0.5 or more and less than 1.0
D: The shear adhesion strength is 0.1 or more and less than 0.5
E: The shear adhesion strength is less than 0.1 or unmeasurable.

### (12) Thermal Cycle Reliability of Film

A film in a semi-cured state of a composition was formed on a PET film having a thickness of 38 μm by the method described in Example 1 below such that a cured film would come to have a thickness of 250 μm. The laminate in which the film in the semi-cured state was formed was cut into a shape of 150 mmφ, and was subjected to a thermal lamination treatment on an aluminum plate of 100 mmφ and 3.0 mm thick under the conditions of 60 °C and 0.10 MPa. Then, the PET film was peeled off, and an alumina substrate of 100 mmφ and 3.0 mm thick was laminated and hot-pressed at 120 °C and 0.50 MPa for 24 hours to prepare a laminate. Using an ultrasonic flaw detector (FS300; manufactured by Hitachi Power Solutions Co., Ltd.), the presence or absence of a peeled portion in the laminate obtained was observed. In addition, the presence or absence of cracks or the like in the alumina substrate was observed by visual inspection for the appearance. Next, a thermal cycle test was performed using a thermal shock testing machine (TSE-11; manufactured by ESPEC CORP.). As test conditions, a combination of a treatment at −65 °C for 30 minutes and a treatment at 100 °C for 30 minutes was defined as one cycle, and the presence or absence of a peeled portion in the laminate was observed after lapse of 250 cycles, 500 cycles, and 1,000 cycles. In addition, the presence or absence of cracks or the like in the alumina substrate was observed by visual inspection for the appearance. As an index of the thermal cycle reliability, the number of cycles at which peeling, cracks, and the like occurred in the laminate and the alumina substrate was measured. In addition, the thermal cycle test was not performed for a laminate in which peeling, cracking or the like occurred after the production of the laminate, and the number of cycles was determined to be 0. In addition, for a laminate in which peeling, cracking, or the like did not occur after 1,000 cycles, the number of cycles was determined to be >1,000. It has been determined as follows that A+, A, B, and C where the number of cycles is 250 or more are regarded as pass, A+, A, and B where the number of cycles is 500 or more are regarded as good, and A+ and A where the number of cycles is 1,000 or more are regarded as excellent.
A+: There was no occurrence of peeling, cracking or the like after lapse of 1,000 cycles
A: The number of cycles at which peeling, cracking, or the like occurred is 1,000
B: The number of cycles at which peeling, cracking, or the like occurred was 500
C: The number of cycles at which peeling, cracking, or the like occurred is 250
D: Peeling, cracks, or the like occurred after the production of the laminate, and the number of cycles is 0.

### <Compounds Used in Examples, Reference Examples, and Comparative Examples>

As the (SD) thermally conductive fillers used in Examples, Reference Examples, and Comparative Examples, a list and description of (sd-1) to (sd-10) are collectively shown below.

### [(SD) Thermally Conductive Filler]

(sd-1): alumina particles (average primary particle size in filler dispersion: 3.0 μm, thermal conductivity: 20 W/(m·K), specific surface area: 1.62 m²/g)
(sd-2): alumina particles (average primary particle size in filler dispersion: 45 μm, thermal conductivity: 26 W/(m·K), specific surface area: 0.108 m²/g)
(sd-3): aluminum nitride particles (average primary particle size in filler dispersion: 30 μm, thermal conductivity: 170 W/(m·K), specific surface area: 0.196 m²/g)
(sd-4): alumina particles (average primary particle size in filler dispersion: 0.40 μm, thermal conductivity: 20 W/(m·K), specific surface area: 12.2 m²/g)
(sd-5): alumina particles (average primary particle size in filler dispersion: 10 μm, thermal conductivity: 26 W/(m·K), specific surface area: 0.486 m²/g)
(sd-6): alumina particles (average primary particle size in filler dispersion: 60 μm, thermal conductivity: 26 W/(m·K), specific surface area: 0.081 m²/g)
(sd-7): aluminum nitride particles (average primary particle size in filler dispersion: 10 μm, thermal conductivity: 170 W/(m·K), specific surface area: 0.589 m²/g)
(sd-8): aluminum nitride particles (average primary particle size in filler dispersion: 50 μm, thermal conductivity: 170 W/(m·K), specific surface area: 0.118 m²/g)
(sd-9): alumina particles (average primary particle size in filler dispersion: 0.20 μm, thermal conductivity: 20 W/(m·K), specific surface area: 24.3 m²/g)
(sd-10): alumina particles (average primary particle size in filler dispersion: 0.80 μm, thermal conductivity: 20 W/(m·K), specific surface area: 6.08 m²/g).

In addition, the compounds collectively shown below are the compounds corresponding to the (SB) compound, namely, (sb-1), the (SC) compounds, namely, (sc-1), (sc-2), (sc-3), and (sc-4), the cure accelerator (ad-1), which were used in Examples, Reference Examples, and Comparative Examples, and the amine compound (r-1), which was used in Comparative Examples.

[(SB) compound]

(sb-1) is a bifunctional epoxy compound having a structure containing an oxyalkylene group represented by the general formula (21a), wherein m=10.3 is a main component. The (sb-1) has a weight-average molecular weight of 870 and an epoxy group equivalent of 435 g/mol.

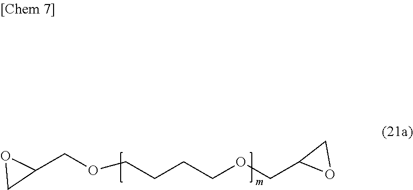

### [(SC) Compound]

(sc-1): KF-8010
(sc-2): X-22-161A
(sc-3): X-22-161B
(sc-4): 1, 3-bis(3-aminopropyl)tetramethyldisiloxane

### [Cure Accelerator]

(ad-1): 2-phenyl-4-methylimidazole

### [Amine Compound]

(r-1): 3, 3′-diaminodiphenyl sulfone.

The compound containing a boron element, phosphorus element, chlorine element, bromine element, platinum element, or fluorine element, and a compound containing a boron element-containing ion, a phosphorus element-containing ion, a chloride ion, a bromide ion, a platinum element-containing ion, or a fluoride ion (hereinafter, “specific element compound”) used in each of Examples, Reference Examples, and Comparative Examples; the specific silicon compound described above; the cyclic silicone compounds described above, and compounds corresponding thereto are also shown below.
(B-1): triphenyl borate
(B-2): tetraethylammonium tetrafluoroborate
(P-1): triphenylphosphine
(P-2): tetraethylammonium phosphate
(C1-1): benzyl chloride
(C1-2): tetraethylammonium chloride
(Br-1): benzyl bromide
(Br-2): tetraethylammonium bromide
(Pt-1): platinum simple substance
(Pt-2): platinum (II) acetylacetonate
(Si-1): dimethyldimethoxysilane
(Si-2): diphenyldimethoxysilane
(Si-3): octamethylcyclotetrasiloxane
(Si-4): octaphenylcyclotetrasiloxane
(F-1): dodecyl fluoride
(F-2): butyltriethylammonium fluoride.

### Preparation of Film-Forming Composition

Compositions 1 to 67 to be used for forming a film were prepared with the compositions shown in Tables 3 to 10. In Tables 3 to 10, the numerical values in parentheses represent parts by mass of the solid content of each component. After mixing the components, the mixture was repeatedly kneaded five times with a triple roll mill, affording a viscous liquid composition. Compositions 1 to 67 contain TEGDM contained as a solvent in each of the above polyimide solutions, and compositions 22 to 29 contain PGMEA contained as a solvent in each of the above silicone resin solutions or the above polysiloxane solutions.

The composition 1 had a solid concentration of 87% by mass.

The additional amount of the specific element compound was adjusted such that the contents of a boron element, phosphorus element, chlorine element, bromine element, platinum element, and fluorine element accounting for in the composition, and the contents of boron element-containing ions, phosphorus element-containing ions, chloride ion, bromide ion, platinum element-containing ions, and fluoride ion were the compositions shown in Tables 3 to 10. The amounts of the specific silicon compound and the cyclic silicone compound added were adjusted such that the compositions shown in Tables 3 to 10 were obtained.

TABLE 3

| | | | | | | | | Specific | | | |
|---|---|---|---|---|---|---|---|---|---|---|---|
| | | Composition [parts by mass] | | | | | | element | | | |
| | | | | | (SD) Thermally | | | compound | Content of | | |
| | | | | | conductive filler | | | Specific | specific | | |
| | | | | | (SD1) | (SD2) | | silicon | element or | Content of | |
| | | | | | First | Second | | compound | specific | specific | |
| | | (SA) | | | thermally | thermally | | Cyclic | ion in | element in | |
| | Compo- | Binder | (SB) | (SC) | conductive | conductive | Cure | silicone | compo- | compo- | |
| | sition | resin | Compound | Compound | filler | filler | accelerator | compound | sition | sition | Solvent |
| Example 1 | 1 | PI-1 | sb-1 | sc-1 | sd-1 | sd-4 | ad-1 | B-1 | B element | F element | TEGDM = |
| | | (100) | (5.6) | (5.6) | (333) | (222) | (0.37) | | (1.5% by | (4,396 ppm by | 100 |
| | | | | | | | | | mass) | mass) | |
| Example 2 | 2 | PI-2 | | | | | | | | F element | |
| | | (100) | | | | | | | | (2,340 ppm by | |
| | | | | | | | | | | mass) | |
| Example 3 | 3 | PI-3 | | | | | | | | F element | |
| | | (100) | | | | | | | | (705 ppm by | |
| | | | | | | | | | | mass) | |
| Example 4 | 4 | PI-4 | | | | | | | | F element | |
| | | (100) | | | | | | | | (465 ppm by | |
| | | | | | | | | | | mass) | |
| Example 5 | 5 | PI-5 | | | | | | | | F element | |
| | | (100) | | | | | | | | (495 ppm by | |
| | | | | | | | | | | mass) | |
| Example 6 | 6 | PI-6 | | | | | | | | F element | |
| | | (100) | | | | | | | | (810 ppm by | |
| | | | | | | | | | | mass) | |
| Example 7 | 7 | PI-7 | | | | | | | | F element | |
| | | (100) | | | | | | | | (930 ppm by | |
| | | | | | | | | | | mass) | |
| Example 8 | 8 | PI-8 | | | | | | | | — | |
| | | (100) | | | | | | | | | |
| Example 9 | 9 | PI-9 | | | | | | | | — | |
| | | (100) | | | | | | | | | |
| Example 10 | 10 | PI-10 | | | | | | | | — | |
| | | (100) | | | | | | | | | |
| Example 11 | 11 | PI-3 | sb-1 | sc-4 | | | | | | F element | |
| | | (100) | (9.3) | (1.9) | | | | | | (705 ppm by | |
| | | | | | | | | | | mass) | |
| Example 12 | 12 | | sb-1 | sc-2 | | | | | | F element | |
| | | | (4.6) | (6.5) | | | | | | (705 ppm by | |
| | | | | | | | | | | mass) | |
| Example 13 | 13 | | sb-1 | sc-3 | | | | | | F element | |
| | | | (3.7) | (7.4) | | | | | | (705 ppm by | |
| | | | | | | | | | | mass) | |
| Example 14 | 14 | | sb-1 | sc-1 | sd-1 | sd-4 | ad-1 | | | F element | |
| | | | (21.4) | (21.4) | (429) | (286) | (0.48) | | | (548 ppm by | |
| | | | | | | | | | | mass) | |
| Example 15 | 15 | | sb-1 | sc-1 | sd-1 | sd-4 | ad-1 | | | F element | |
| | | | (50) | (50) | (600) | (400) | (0.67) | | | (391 ppm by | |
| | | | | | | | | | | mass) | |

Average primary particle size in filler dispersion of sd-1: 3.0 μm
Average primary particle size in filler dispersion of sd-4: 0.40 μm

TABLE 4

| | | | | | | | | Specific | | | |
|---|---|---|---|---|---|---|---|---|---|---|---|
| | | Composition [parts by mass] | | | | | | element | | | |
| | | | | | (SD) Thermally | | | compound | Content of | | |
| | | | | | conductive filler | | | Specific | specific | | |
| | | | | | (SD1) | (SD2) | | silicon | element or | Content of | |
| | | | | | First | Second | | compound | specific | specific | |
| | | (SA) | (SB) | (SC) | thermally | thermally | Cure | Cyclic | ion in | element in | |
| | Compo- | Binder | Com- | Com- | conductive | conductive | accel- | silicone | compo- | compo- | |
| | sition | resin | pound | pound | filler | filler | erator | compound | sition | sition | Solvent |
| Example 3 | 3 | PI-3 | sb-1 | sc-1 | sd-1 | sd-4 | ad-1 | B-1 | B element | F element | TEGDM = |
| | | (100) | (5.6) | (5.6) | (333) | (222) | (0.37) | | (1.5% by | (705 ppm by | 100 |
| | | | | | | | | | mass) | mass) | |
| Example 16 | 16 | | | | sd-2 | sd-4 | | | | F element | |
| | | | | | (333) | (222) | | | | (705 ppm by | |
| | | | | | | | | | | mass) | |
| Example 17 | 17 | | | | sd-1 | sd-4 | | | | F element | |
| | | | | | (407) | (278) | | | | (590 ppm by | |
| | | | | | | | | | | mass) | |
| Example 18 | 18 | | | | sd-3 | sd-4 | | | | F element | |
| | | | | | (306) | (185) | | | | (780 ppm by | |
| | | | | | | | | | | mass) | |
| Example 19 | 19 | | | | — | sd-4 | | | | F element | |
| | | | | | | (556) | | | | (704 ppm by | |
| | | | | | | | | | | mass) | |
| Example 20 | 20 | | | | sd-1 | — | | | | F element | |
| | | | | | (556) | | | | | (704 ppm by | |
| | | | | | | | | | | mass) | |
| Example 21 | 21 | | | | sd-2 | — | | | | F element | |
| | | | | | (556) | | | | | (704 ppm by | |
| | | | | | | | | | | mass) | |

Average primary particle size in filler dispersion of sd-1: 3.0 μm
Average primary particle size in filler dispersion of sd-2: 45 μm
Average primary particle size in filler dispersion of sd-3: 30 μm
Average primary particle size in filler dispersion of sd-4: 0.40 μm

TABLE 5

| | | | | | | | | Specific | | | |
|---|---|---|---|---|---|---|---|---|---|---|---|
| | | Composition [parts by mass] | | | | | | element | | | |
| | | | | | (SD) Thermally | | | compound | | | |
| | | | | | conductive filler | | | Specific | Content of | | |
| | | | | | (SD1) | (SD2) | | silicon | specific | | |
| | | | | | First | Second | | compound | element or | Content of | |
| | | (SA) | | | thermally | thermally | Cure | Cyclic | specific | specific | |
| | Compo- | Binder | (SB) | (SC) | conductive | conductive | accel- | silicone | ion in | element in | |
| | sition | resin | Compound | Compound | filler | filler | erator | compound | composition | composition | Solvent |
| Exam- | 3 | PI-3 | sb-1 | sc-1 | sd-1 | sd-4 | ad-1 | B-1 | B element | F element | TEGDM = |
| ple 3 | | (100) | (5.6) | (5.6) | (333) | (222) | (0.37) | | (1.5% by | (705 ppm | 100 |
| | | | | | | | | | mass) | by mass) | |
| Exam- | 22 | SR-1 | | | | | | | | — | |
| ple 22 | | (100) | | | | | | | | | |
| Exam- | 23 | SR-2 | | | | | | | | — | |
| ple 23 | | (100) | | | | | | | | | |
| Exam- | 24 | SR-3 | | | | | | | | — | PGMEA = |
| ple 24 | | (100) | | | | | | | | | 100 |
| Exam- | 25 | SR-4 | | | | | | | | — | |
| ple 25 | | (100) | | | | | | | | | |
| Exam- | 26 | PS-1 | | | | | | | | — | |
| ple 26 | | (100) | | | | | | | | | |
| Exam- | 27 | PS-2 | | | | | | | | — | |
| ple 27 | | (100) | | | | | | | | | |
| Exam- | 28 | PS-3 | | | | | | | | — | |
| ple 28 | | (100) | | | | | | | | | |
| Exam- | 29 | PS-4 | | | | | | | | — | |
| ple 29 | | (100) | | | | | | | | | |

Average primary particle size in filler dispersion of sd-1: 3.0 μm
Average primary particle size in filler dispersion of sd-4: 0.40 μm

TABLE 6

| | | Composition [parts by mass] | | | Specific | | | | |
|---|---|---|---|---|---|---|---|---|---|
| | | (SA) Binder | | | element | | | | |
| | | resin | (SD) Thermally | | compound | | | | |
| | | (SB) | conductive filler | | Specific | | | | |
| | | Compound | (SD1) | (SD2) | silicon | | | | |
| | | (SC) | First | Second | compound | | | Content of | |
| | | Compound | thermally | thermally | Cyclic | | | specific | |
| | Compo- | Cure | conductive | conductive | silicone | Content of specific | | ion in | |
| | sition | accelerator | filler | filler | compound | element in composition | | composition | Solvent |
| Exam- | 3 | PI-3 | sd-1 | sd-4 | B-1 | B element | F element | — | TEGDM = |
| ple 3 | | (100) | (333) | (222) | | (1.5% | (705 ppm | | 100 |
| | | sb-1 | | | | by mass) | by mass) | | |
| Exam- | 30 | (5.6) | | | B-1 | B element | F element | — | |
| ple 30 | | sc-1 | | | | (0.5% | (705 ppm | | |
| | | (5.6) | | | | by mass) | by mass) | | |
| Exam- | 31 | ad-1 | | | B-1 | B element | F element | — | |
| ple 31 | | (0.37) | | | | (3.0% | (705 ppm | | |
| | | | | | | by mass) | by mass) | | |
| Exam- | 32 | | | | B-2 | B element | F element | Tetrafluoro- | |
| ple 32 | | | | | | (0.19% | (13,805 ppm | borate | |
| | | | | | | by mass) | by mass) | ion (1.5% | |
| | | | | | | | | by mass) | |
| Exam- | 33 | | | | P-1 | P element | F element | — | |
| ple 33 | | | | | | (3 ppm | (705 ppm | | |
| | | | | | | by mass) | by mass) | | |
| Exam- | 34 | | | | P-2 | P element | F element | Phosphate ion | |
| ple 34 | | | | | | (0.96 ppm | (705 ppm | (3 ppm | |
| | | | | | | by mass) | by mass) | by mass) | |
| Exam- | 35 | | | | Cl-1 | Cl element | F element | — | |
| ple 35 | | | | | | (3 ppm | (705 ppm | | |
| | | | | | | by mass) | by mass) | | |
| Exam- | 36 | | | | Cl-2 | Cl element | F element | Chloride ion | |
| ple 36 | | | | | | (3 ppm | (705 ppm | (3 ppm | |
| | | | | | | by mass) | by mass) | by mass) | |
| Exam- | 37 | | | | Br-1 | Br element | F element | — | |
| ple 37 | | | | | | (3 ppm | (705 ppm | | |
| | | | | | | by mass) | by mass) | | |
| Exam- | 38 | | | | Br-2 | Br element | F element | Bromide ion | |
| ple 38 | | | | | | (3 ppm | (705 ppm | (3 ppm | |
| | | | | | | by mass) | by mass) | by mass) | |
| Exam- | 39 | | | | Pt-1 | Pt element | F element | — | |
| ple 39 | | | | | | (3 ppm | (705 ppm | | |
| | | | | | | by mass) | by mass) | | |
| Exam- | 40 | | | | Pt-2 | Pt element | F element | Pt ion | |
| ple 40 | | | | | | (0.5 ppm | (705 ppm | (0.5 ppm | |
| | | | | | | by mass) | by mass) | by mass) | |
| Exam- | 41 | | | | Pt-2 | Pt element | F element | Pt ion | |
| ple 41 | | | | | | (3 ppm | (705 ppm | (3 ppm | |
| | | | | | | by mass) | by mass) | by mass) | |
| Exam- | 42 | | | | Pt-2 | Pt element | F element | Pt ion | |
| ple 42 | | | | | | (40 ppm | (705 ppm | (40 ppm | |
| | | | | | | by mass) | by mass) | by mass) | |

Average primary particle size in filler dispersion of sd-1: 3.0 μm
Average primary particle size in filler dispersion of sd-4: 0.40 μm

TABLE 7

| | | Composition [parts by mass] | | | Specific | | | | | |
|---|---|---|---|---|---|---|---|---|---|---|
| | | (SA) Binder | | | element | | | | Content of | |
| | | resin | (SD) Thermally | | compound | | | | specific | |
| | | (SB) | conductive filler | | Specific | | | | silicon | |
| | | Compound | (SD1) | (SD2) | silicon | | | | compound or | |
| | | (SC) | First | Second | compound | | | Content of | cyclic | |
| | | Compound | thermally | thermally | Cyclic | | | specific | silicone | |
| | Compo- | Cure | conductive | conductive | silicone | Content of specific | | ion in | compound in | |
| | sition | accelerator | filler | filler | compound | element in composition | | composition | composition | Solvent |
| Exam- | 3 | PI-3 | sd-1 | sd-4 | B-1 | B element | F element | — | — | TEGDM = |
| ple 3 | | (100) | (333) | (222) | | (1.5% by | (705 ppm | | | 100 |
| | | sb-1 | | | | mass) | by mass) | | | |
| Exam- | 43 | (5.6) | | | Si-1 | — | F element | — | Si-1 | |
| ple 43 | | sc-1 | | | | | (705 ppm | | (3 ppm | |
| | | (5.6) | | | | | by mass) | | by mass) | |
| Exam- | 44 | ad-1 | | | Si-2 | — | F element | — | Si-2 | |
| ple 44 | | (0.37) | | | | | (705 ppm | | (3 ppm | |
| | | | | | | | by mass) | | by mass) | |
| Exam- | 45 | | | | Si-3 | — | F element | — | Si-3 | |
| ple 45 | | | | | | | (705 ppm | | (0.5 ppm | |
| | | | | | | | by mass) | | by mass) | |
| Exam- | 46 | | | | Si-3 | — | F element | — | Si-3 | |
| ple 46 | | | | | | | (705 ppm | | (3 ppm | |
| | | | | | | | by mass) | | by mass) | |
| Exam- | 47 | | | | Si-3 | — | F element | — | Si-3 | |
| ple 47 | | | | | | | (705 ppm | | (40 ppm | |
| | | | | | | | by mass) | | by mass) | |
| Exam- | 48 | | | | Si-4 | — | F element | — | Si-4 | |
| ple 48 | | | | | | | (705 ppm | | (3 ppm | |
| | | | | | | | by mass) | | by mass) | |
| Exam- | 49 | | | | B-1 | B element | F element | Chloride | — | |
| ple 49 | | | | | Cl-2 | (1.5% by | (705 ppm | ion | | |
| | | | | | | mass) | by mass) | (3 ppm | | |
| | | | | | | Cl element | | by mass) | | |
| | | | | | | (3 ppm by | | | | |
| | | | | | | mass) | | | | |
| Exam- | 50 | | | | B-1 | B element | F element | Pt ion | — | |
| ple 50 | | | | | Pt-2 | (1.5% by | (705 ppm | (3 ppm | | |
| | | | | | | mass) | by mass) | by mass) | | |
| | | | | | | Pt element | | | | |
| | | | | | | (3 ppm by | | | | |
| | | | | | | mass) | | | | |
| Exam- | 51 | | | | B-1 | B element | F element | — | Si-3 | |
| ple 51 | | | | | Si-3 | (1.5% by | (705 ppm | | (3 ppm | |
| | | | | | | mass) | by mass) | | by mass) | |
| Exam- | 52 | | | | Pt-2 | Pt element | F element | Pt ion | Si-3 | |
| ple 52 | | | | | Si-3 | (3 ppm by | (705 ppm | (3 ppm | (3 ppm | |
| | | | | | | mass) | by mass) | by mass) | by mass) | |
| Exam- | 53 | | | | B-1 | B element | F element | Chloride | Si-3 | |
| ple 53 | | | | | Cl-2 | (1.5% by | (705 ppm | ion | (3 ppm | |
| | | | | | Si-3 | mass) | by mass) | (3 ppm | by mass) | |
| | | | | | | Cl element | | by mass) | | |
| | | | | | | (3 ppm by | | | | |
| | | | | | | mass) | | | | |
| Exam- | 54 | | | | B-1 | B element | F element | Pt ion | Si-3 | |
| ple 54 | | | | | Pt-2 | (1.5% by | (705 ppm | (3 ppm | (3 ppm | |
| | | | | | Si-3 | mass) | by mass) | by mass) | by mass) | |
| | | | | | | Pt element | | | | |
| | | | | | | (3 ppm by | | | | |
| | | | | | | mass) | | | | |

Average primary particle size in filler dispersion of sd-1: 3.0 μm
Average primary particle size in filler dispersion of sd-4: 0.40 μm

TABLE 8

| | | Composition [parts by mass] | | | Specific | | | |
|---|---|---|---|---|---|---|---|---|
| | | (SA) Binder | | | element | | | |
| | | resin | (SD) Thermally | | compound | | | |
| | | (SB) | conductive filler | | Specific | | | |
| | | Compound | (SD1) | (SD2) | silicon | | | |
| | | (SC) | First | Second | compound | Content of | Content of | |
| | | Compound | thermally | thermally | Cyclic | specific | specific | |
| | Compo- | Cure | conductive | conductive | silicone | element in | ion in | |
| | sition | accelerator | filler | filler | compound | composition | composition | Solvent |
| Exam- | 8 | PI-8 | sd-1 | sd-4 | B-1 | B element | — | TEGDM = |
| ple 8 | | (100) | (333) | (222) | | (1.5% | | 100 |
| | | sb-1 | | | | by mass) | | |
| Exam- | 55 | (5.6) | | | B-1 | B element | — | |
| ple 55 | | sc-1 | | | F-1 | (1.5% | | |
| | | (5.6) | | | | by mass) | | |
| | | ad-1 | | | | F element | | |
| | | (0.37) | | | | (3 ppm | | |
| | | | | | | by mass) | | |
| Exam- | 56 | | | | B-1 | B element | Fluoride | |
| ple 56 | | | | | F-2 | (1.5% | ion | |
| | | | | | | by mass) | (0.5 ppm | |
| | | | | | | F element | by mass) | |
| | | | | | | (0.5 ppm | | |
| | | | | | | by mass) | | |
| Exam- | 57 | | | | | B element | Fluoride | |
| ple 57 | | | | | | (1.5% | ion | |
| | | | | | | by mass) | (3 ppm | |
| | | | | | | F element | by mass) | |
| | | | | | | (3 ppm | | |
| | | | | | | by mass) | | |
| Exam- | 58 | | | | | B element | Fluoride | |
| ple 58 | | | | | | (1.5% | ion | |
| | | | | | | by mass) | (40 ppm | |
| | | | | | | F element | by mass) | |
| | | | | | | (40 ppm | | |
| | | | | | | by mass) | | |

Average primary particle size in filler dispersion of sd-1: 3.0 μm
Average primary particle size in filler dispersion of sd-4: 0.40 μm

TABLE 9

| | | | | | | | | Specific | | |
|---|---|---|---|---|---|---|---|---|---|---|
| | | Composition [parts by mass] | | | | | | element | | |
| | | | | | (SD) Thermally | | | compound | | |
| | | | | | conductive filler | | | Specific | Content of | |
| | | | | | (SD1) | (SD2) | | silicon | specific | |
| | | | | | First | Second | | compound | element or | |
| | | (SA) | | | thermally | thermally | Cure | Cyclic | specific | |
| | Compo- | Binder | (SB) | (SC) | conductive | conductive | accel- | silicone | ion in | |
| | sition | resin | Compound | Compound | filler | filler | erator | compound | composition | Solvent |
| Exam- | 3 | PI-3 | sb-1 | sc-1 | sd-1 | sd-4 | ad-1 | B-1 | B element | TEGDM = |
| ple 3 | | (100) | (5.6) | (5.6) | (333) | (222) | (0.37) | | (1.5% | 100 |
| Exam- | 59 | | | | sd-5 | | | | by mass) | |
| ple 59 | | | | | (333) | | | | F element | |
| Exam- | 60 | | | | sd-6 | | | | (705 ppm | |
| ple 60 | | | | | (333) | | | | by mass) | |
| Exam- | 61 | | | | sd-7 | | | | | |
| ple 61 | | | | | (333) | | | | | |
| Exam- | 62 | | | | sd-8 | | | | | |
| ple 62 | | | | | (333) | | | | | |
| Exam- | 63 | | | | sd-1 | sd-9 | | | | |
| ple 63 | | | | | (333) | (222) | | | | |
| Exam- | 64 | | | | | sd-10 | | | | |
| ple 64 | | | | | | (222) | | | | |

Average primary particle size in filler dispersion of sd-1: 3.0 μm
Average primary particle size in filler dispersion of sd-2: 45 μm
Average primary particle size in filler dispersion of sd-3: 30 μm
Average primary particle size in filler dispersion of sd-4: 0.40 μm
Average primary particle size in filler dispersion of sd-5: 10 μm
Average primary particle size in filler dispersion of sd-6: 60 μm
Average primary particle size in filler dispersion of sd-7: 10 μm
Average primary particle size in filler dispersion of sd-8: 50 μm
Average primary particle size in filler dispersion of sd-9: 0.20 μm
Average primary particle size in filler dispersion of sd-10: 0.80 μm

TABLE 10

| | | | | | | | | Specific | | |
|---|---|---|---|---|---|---|---|---|---|---|
| | | Composition [parts by mass] | | | | | | element | | |
| | | | | | (SD) Thermally | | | compound | | |
| | | | | | conductive filler | | | Specific | Content of | |
| | | | | | (SD1) | (SD2) | | silicon | specific | |
| | | | | | First | Second | | compound | element or | |
| | | (SA) | | | thermally | thermally | Cure | Cyclic | specific | |
| | Compo- | Binder | (SB) | (SC) | conductive | conductive | accel- | silicone | ion in | |
| | sition | resin | Compound | Compound | filler | filler | erator | compound | composition | Solvent |
| Compar- | 65 | PI-3 | sb-1 | r-1 | sd-1 | sd-4 | ad-1 | — | F element | TEGDM = |
| ative | | (100) | (6.5) | (4.6) | (333) | (222) | (0.37) | | (705 ppm | 100 |
| Exam- | | | | | | | | | by mass) | |
| ple 1 | | | | | | | | | | |
| Compar- | 66 | | sb-1 | — | | | | — | F element | |
| ative | | | (11.1) | | | | | | (705 ppm | |
| Exam- | | | | | | | | | by mass) | |
| ple 2 | | | | | | | | | | |
| Compar- | 67 | PI-11 | sb-1 | sc-1 | | | | — | F element | |
| ative | | (100) | (5.6) | (5.6) | | | | | (25,279 ppm | |
| Exam- | | | | | | | | | by mass) | |
| ple 3 | | | | | | | | | | |

Average primary particle size in filler dispersion of sd-1: 3.0 μm
Average primary particle size in filler dispersion of sd-4: 0.40 μm

### Example 1

### Preparation of Samples for Evaluation of Film

Composition 1 was applied onto a PET film having a thickness of 38 μm using a comma roll coater such that a cured film would come to have a thickness of 250 μm, and then dried at 100 °C for 30 minutes to form a film, whereby a film in a semi-cured state of Composition 1 was prepared. The prepared film in the semi-cured state was heated at 180 °C for 4 hours, whereby a film having a thickness of 250 μm, which was a cured film of Composition 1, was prepared.

Using this evaluation sample, the volume fraction of the filler in the film and the thermal conductivity, elastic modulus, shear adhesion strength, shear strain, and thermal cycle reliability of the film were evaluated. The results are shown in Table 11.

### Examples 2 to 64 and Comparative Examples 1 to 3

The same operation and evaluation as in Example 1 were performed using each composition shown in Tables 3 to 10. The evaluation results are collectively shown in Tables 11 to 18. To facilitate comparison, the evaluation results of Example 3 are described in Tables 12 to 15 and Table 17, and the evaluation results of Example 8 are described in Table 16. In Examples 1 to 7, Examples 11 to 21, Examples 30 to 64, and Comparative Examples 1 to 3, the content of fluorine element accounting for in the composition is as shown in Tables 3, 4, and 6 to 10, and the content of fluorine element in the film is as shown in Tables 11, 12, and 14 to 18.

TABLE 11-1

| | | Thermally conductive filler in film | | | | |
|---|---|---|---|---|---|---|
| | | Specific | Specific | Fraction | Fraction | |
| | | surface area | surface area | of first | of second | |
| | | of first | of second | thermally | thermally | Content of |
| | | thermally | thermally | conductive | conductive | specific |
| | | conductive | conductive | filler | filler | element or |
| | Compo- | filler | filler | [% by | [% by | specific |
| | sition | [m²/g] | [m²/g] | volume] | volume] | ion in film |
| Exam- | 1 | 1.62 | 12.2 | 38 | 25 | B element |
| ple 1 | | | | | | (1.5% |
| Exam- | 2 | 1.62 | 12.2 | 38 | 25 | by mass) |
| ple 2 | | | | | | |
| Exam- | 3 | 1.62 | 12.2 | 38 | 25 | |
| ple 3 | | | | | | |
| Exam- | 4 | 1.62 | 12.2 | 38 | 25 | |
| ple 4 | | | | | | |
| Exam- | 5 | 1.62 | 12.2 | 38 | 25 | |
| ple 5 | | | | | | |
| Exam- | 6 | 1.62 | 12.2 | 38 | 25 | |
| ple 6 | | | | | | |
| Exam- | 7 | 1.62 | 12.2 | 38 | 25 | |
| ple 7 | | | | | | |
| Exam- | 8 | 1.62 | 12.2 | 38 | 25 | |
| ple 8 | | | | | | |
| Exam- | 9 | 1.62 | 12.2 | 38 | 25 | |
| ple 9 | | | | | | |
| Exam- | 10 | 1.62 | 12.2 | 38 | 25 | |
| ple 10 | | | | | | |
| Exam- | 11 | 1.62 | 12.2 | 38 | 25 | |
| ple 11 | | | | | | |
| Exam- | 12 | 1.62 | 12.2 | 38 | 25 | |
| ple 12 | | | | | | |
| Exam- | 13 | 1.62 | 12.2 | 38 | 25 | |
| ple 13 | | | | | | |
| Exam- | 14 | 1.62 | 12.2 | 37 | 25 | |
| ple 14 | | | | | | |
| Exam- | 15 | 1.62 | 12.2 | 36 | 24 | |
| ple 15 | | | | | | |

TABLE 11-2

| | | | | | Evaluation of film | |
|---|---|---|---|---|---|---|
| | | Characteristics of film | | | Shear | Thermal |
| | Content of | Thermal | Elastic | | adhesion | cycle |
| | specific | conductivity | modulus | Shear | strength | reliability |
| | element | (25 °C) | (−50 °C) | strain | (−50 °C) | (number of |
| | in film | [W/(m · K)] | [MPa] | (−50 °C) | [MPa] | cycles) |
| Exam- | F element | 1.4 | 150 | 1.5 | 2.1 | 500 |
| ple 1 | (4,396 ppm | | | | B+ | B |
| | by mass) | | | | | |
| Exam- | F element | 1.3 | 100 | 2.1 | 2.5 | 1,000 |
| ple 2 | (2,340 ppm | | | | A | A |
| | by mass) | | | | | |
| Exam- | F element | 1.2 | 7.0 | 3.1 | 2.9 | >1,000 |
| ple 3 | (705 ppm | | | | A | A+ |
| | by mass) | | | | | |
| Exam- | F element | 1.2 | 1.0 | 3.5 | 3.1 | >1,000 |
| ple 4 | (465 ppm | | | | A+ | A+ |
| | by mass) | | | | | |
| Exam- | F element | 1.2 | 0.80 | 3.6 | 3.1 | >1,000 |
| ple 5 | (495 ppm | | | | A+ | A+ |
| | by mass) | | | | | |
| Exam- | F element | 1.2 | 75 | 2.3 | 2.6 | 1,000 |
| ple 6 | (810 ppm | | | | A | A |
| | by mass) | | | | | |
| Exam- | F element | 1.2 | 135 | 1.6 | 2.2 | 500 |
| ple 7 | (930 ppm | | | | B+ | B |
| | by mass) | | | | | |
| Exam- | — | 1.2 | 5.0 | 3.2 | 2.9 | >1,000 |
| ple 8 | | | | | A | A+ |
| Exam- | — | 1.2 | 5.0 | 3.2 | 2.9 | >1,000 |
| ple 9 | | | | | A | A+ |
| Exam- | — | 1.2 | 5.0 | 3.2 | 2.9 | >1,000 |
| ple 10 | | | | | A | A+ |
| Exam- | F element | 1.2 | 80 | 2.2 | 2.6 | 500 |
| ple 11 | (705 ppm | | | | A | B |
| | by mass) | | | | | |
| Exam- | F element | 1.2 | 4.0 | 3.4 | 3.0 | >1,000 |
| ple 12 | (705 ppm | | | | A+ | A+ |
| | by mass) | | | | | |
| Exam- | F element | 1.2 | 1.0 | 3.5 | 3.1 | >1,000 |
| ple 13 | (705 ppm | | | | A+ | A+ |
| | by mass) | | | | | |
| Exam- | F element | 1.2 | 68 | 2.3 | 2.6 | 1,000 |
| ple 14 | (548 ppm | | | | A | A |
| | by mass) | | | | | |
| Exam- | F element | 1.2 | 110 | 1.8 | 2.4 | 500 |
| ple 15 | (391 ppm | | | | B+ | B |
| | by mass) | | | | | |

TABLE 12

| | | Thermally conductive filler in film | | | | |
|---|---|---|---|---|---|---|
| | | Specific | Specific | | | |
| | | surface | surface | Fraction | Fraction | |
| | | area of | area of | of first | of second | |
| | | first | second | thermally | thermally | Content of |
| | | thermally | thermally | conductive | conductive | specific |
| | | conductive | conductive | filler | filler | element or |
| | Compo- | filler | filler | [% by | [% by | specific |
| | sition | [m²/g] | [m²/g] | volume] | volume] | ion in film |
| Exam- | 3 | 1.62 | 12.2 | 38 | 25 | B element |
| ple 3 | | | | | | (1.5% by |
| Exam- | 16 | 0.108 | 12.2 | 38 | 25 | mass) |
| ple 16 | | | | | | |
| Exam- | 17 | 1.62 | 12.2 | 40 | 28 | |
| ple 17 | | | | | | |
| Exam- | 18 | 0.196 | 12.2 | 42 | 21 | |
| ple 18 | | | | | | |
| Exam- | 19 | — | 12.2 | 0 | 63 | |
| ple 19 | | | | | | |
| Exam- | 20 | 1.62 | — | 63 | 0 | |
| ple 20 | | | | | | |
| Exam- | 21 | 0.108 | — | 63 | 0 | |
| ple 21 | | | | | | |

| | | | | | Evaluation of film | |
|---|---|---|---|---|---|---|
| | | Characteristics of film | | | Shear | Thermal |
| | Content of | Thermal | Elastic | | adhesion | cycle |
| | specific | conductivity | modulus | Shear | strength | reliability |
| | element | (25 °C) | (−50 °C) | strain | (−50 °C) | (number |
| | in film | [W/(m · K)] | [MPa] | (−50 °C) | [MPa] | of cycles) |
| Exam- | F element | 1.2 | 7.0 | 3.1 | 2.9 | >1,000 |
| ple 3 | (705 ppm | | | | A | A+ |
| | by mass) | | | | | |
| Exam- | F element | 1.2 | 20 | 2.9 | 2.2 | 1,000 |
| ple 16 | (705 ppm | | | | B+ | A |
| | by mass) | | | | | |
| Exam- | F element | 1.5 | 35 | 2.6 | 2.8 | 1,000 |
| ple 17 | (590 ppm | | | | A | A |
| | by mass) | | | | | |
| Exam- | F element | 1.6 | 30 | 2.7 | 2.8 | 1,000 |
| ple 18 | (780 ppm | | | | A | A |
| | by mass) | | | | | |
| Exam- | F element | 0.8 | 10 | 3.0 | 2.9 | 500 |
| ple 19 | (704 ppm | | | | A | B |
| | by mass) | | | | | |
| Exam- | F element | 1.0 | 20 | 2.9 | 2.8 | 500 |
| ple 20 | (704 ppm | | | | A | B |
| | by mass) | | | | | |
| Exam- | F element | 1.1 | 75 | 2.3 | 2.6 | 500 |
| ple 21 | (704 ppm | | | | A | B |
| | by mass) | | | | | |

TABLE 13

| | | Thermally conductive filler in film | | | | |
|---|---|---|---|---|---|---|
| | | Specific | Specific | | | |
| | | surface | surface | Fraction | Fraction | |
| | | area of | area of | of first | of second | |
| | | first | second | thermally | thermally | Content of |
| | | thermally | thermally | conductive | conductive | specific |
| | | conductive | conductive | filler | filler | element or |
| | Compo- | filler | filler | [% by | [% by | specific |
| | sition | [m²/g] | [m²/g] | volume] | volume] | ion in film |
| Exam- | 3 | 1.62 | 12.2 | 38 | 25 | B element |
| ple 3 | | | | | | (1.5% by |
| Exam- | 22 | 1.62 | 12.2 | 38 | 25 | mass) |
| ple 22 | | | | | | |
| Exam- | 23 | 1.62 | 12.2 | 38 | 25 | |
| ple 23 | | | | | | |
| Exam- | 24 | 1.62 | 12.2 | 38 | 25 | |
| ple 24 | | | | | | |
| Exam- | 25 | 1.62 | 12.2 | 38 | 25 | |
| ple 25 | | | | | | |
| Exam- | 26 | 1.62 | 12.2 | 38 | 25 | |
| ple 26 | | | | | | |
| Exam- | 27 | 1.62 | 12.2 | 38 | 25 | |
| ple 27 | | | | | | |
| Exam- | 28 | 1.62 | 12.2 | 38 | 25 | |
| ple 28 | | | | | | |
| Exam- | 29 | 1.62 | 12.2 | 38 | 25 | |
| ple 29 | | | | | | |

| | | | | | Evaluation of film | |
|---|---|---|---|---|---|---|
| | | Characteristics of film | | | Shear | Thermal |
| | Content of | Thermal | Elastic | | adhesion | cycle |
| | specific | conductivity | modulus | Shear | strength | reliability |
| | element | (25 °C) | (−50 °C) | strain | (−50 °C) | (number |
| | in film | [W/(m · K)] | [MPa] | (−50 °C) | [MPa] | of cycles) |
| Exam- | F element | 1.2 | 7.0 | 3.1 | 2.9 | >1,000 |
| ple 3 | (705 ppm | | | | A | A+ |
| | by mass) | | | | | |
| Exam- | — | 1.2 | 25 | 2.8 | 2.8 | 1,000 |
| ple 22 | | | | | A | A |
| Exam- | — | 1.2 | 8.0 | 3.0 | 2.9 | >1,000 |
| ple 23 | | | | | A | A+ |
| Exam- | — | 1.2 | 2.0 | 3.4 | 3.1 | >1,000 |
| ple 24 | | | | | A+ | A+ |
| Exam- | — | 1.2 | 1.0 | 3.5 | 3.1 | >1,000 |
| ple 25 | | | | | A+ | A+ |
| Exam- | — | 1.2 | 160 | 1.4 | 2.1 | 500 |
| ple 26 | | | | | B+ | B |
| Exam- | — | 1.2 | 110 | 1.8 | 2.4 | 500 |
| ple 27 | | | | | B+ | B |
| Exam- | — | 1.2 | 80 | 2.2 | 2.6 | 1,000 |
| ple 28 | | | | | A | A |
| Exam- | — | 1.2 | 50 | 2.5 | 2.7 | 1,000 |
| ple 29 | | | | | A | A |

TABLE 14-1

| | | Thermally conductive filler in film | | | |
|---|---|---|---|---|---|
| | | Specific surface | Specific surface | Fraction of first | Fraction of second |
| | | area of first | area of second | thermally | thermally |
| | | thermally | thermally | conductive | conductive |
| | | conductive filler | conductive filler | filler | filler |
| | Composition | [m²/g] | [m²/g] | [% by volume] | [% by volume] |
| Example 3 | 3 | 1.62 | 12.2 | 38 | 25 |
| Example 30 | 30 | 1.62 | 12.2 | 38 | 25 |
| Example 31 | 31 | 1.62 | 12.2 | 38 | 25 |
| Example 32 | 32 | 1.62 | 12.2 | 38 | 25 |
| Example 33 | 33 | 1.62 | 12.2 | 38 | 25 |
| Example 34 | 34 | 1.62 | 12.2 | 38 | 25 |
| Example 35 | 35 | 1.62 | 12.2 | 38 | 25 |
| Example 36 | 36 | 1.62 | 12.2 | 38 | 25 |
| Example 37 | 37 | 1.62 | 12.2 | 38 | 25 |
| Example 38 | 38 | 1.62 | 12.2 | 38 | 25 |
| Example 39 | 39 | 1.62 | 12.2 | 38 | 25 |
| Example 40 | 40 | 1.62 | 12.2 | 38 | 25 |
| Example 41 | 41 | 1.62 | 12.2 | 38 | 25 |
| Example 42 | 42 | 1.62 | 12.2 | 38 | 25 |

TABLE 14-2

| | | | | | | | Evaluation of film | |
|---|---|---|---|---|---|---|---|---|
| | | | | Characteristics of film | | | Shear | Thermal |
| | | | | Thermal | Elastic | | adhesion | cycle |
| | | | Content of | conductivity | modulus | Shear | strength | reliability |
| | Content of specific | | specific | (25 °C) | (−50 °C) | strain | (−50 °C) | (number |
| | element in film | | ion in film | [W/(m · K)] | [MPa] | (−50 °C) | [MPa] | of cycles) |
| Exam- | B element | F element | — | 1.2 | 7.0 | 3.1 | 2.9 | >1,000 |
| ple 3 | (1.5% | (705 ppm | | | | | A | A+ |
| | by mass) | by mass) | | | | | | |
| Exam- | B element | F element | — | 1.2 | 6.5 | 3.2 | 3.1 | >1,000 |
| ple 30 | (0.5% | (705 ppm | | | | | A+ | A+ |
| | by mass) | by mass) | | | | | | |
| Exam- | B element | F element | — | 1.2 | 8.0 | 2.8 | 2.7 | 1,000 |
| ple 31 | (3.0% | (705 ppm | | | | | A | A |
| | by mass) | by mass) | | | | | | |
| Exam- | B element | F element | Tetrafluoro- | 1.2 | 7.1 | 3.0 | 2.9 | >1,000 |
| ple 32 | (0.19% | (13,805 ppm | borate ion | | | | A | A+ |
| | by mass) | by mass) | (1.5% | | | | | |
| | | | by mass) | | | | | |
| Exam- | P element | F element | — | 1.2 | 7.0 | 3.1 | 2.9 | >1,000 |
| ple 33 | (3 ppm | (705 ppm | | | | | A | A+ |
| | by mass) | by mass) | | | | | | |
| Exam- | P element | F element | Phosphate ion | 1.2 | 7.1 | 3.0 | 2.9 | >1,000 |
| ple 34 | (0.96 ppm | (705 ppm | (3 ppm | | | | A | A+ |
| | by mass) | by mass) | by mass) | | | | | |
| Exam- | Cl element | F element | — | 1.2 | 7.2 | 3.1 | 2.9 | >1,000 |
| ple 35 | (3 ppm | (705 ppm | | | | | A | A+ |
| | by mass) | by mass) | | | | | | |
| Exam- | Cl element | F element | Chloride ion | 1.2 | 7.3 | 3.0 | 2.9 | >1,000 |
| ple 36 | (3 ppm | (705 ppm | (3 ppm | | | | A | A+ |
| | by mass) | by mass) | by mass) | | | | | |
| Exam- | Br element | F element | — | 1.2 | 7.4 | 2.9 | 2.8 | >1,000 |
| ple 37 | (3 ppm | (705 ppm | | | | | A | A+ |
| | by mass) | by mass) | | | | | | |
| Exam- | Br element | F element | Bromide ion | 1.2 | 7.5 | 2.8 | 2.8 | >1,000 |
| ple 38 | (3 ppm | (705 ppm | (3 ppm | | | | A | A+ |
| | by mass) | by mass) | by mass) | | | | | |
| Exam- | Pt element | F element | — | 1.2 | 7.1 | 3.0 | 2.9 | >1,000 |
| ple 39 | (3 ppm | (705 ppm | | | | | A | A+ |
| | by mass) | by mass) | | | | | | |
| Exam- | Pt element | F element | Pt ion | 1.2 | 6.6 | 3.2 | 3.1 | >1,000 |
| ple 40 | (0.5 ppm | (705 ppm | (0.5 ppm | | | | A+ | A+ |
| | by mass) | by mass) | by mass) | | | | | |
| Exam- | Pt element | F element | Pt ion | 1.2 | 7.1 | 3.1 | 2.9 | >1,000 |
| ple 41 | (3 ppm | (705 ppm | (3 ppm | | | | A | A+ |
| | by mass) | by mass) | by mass) | | | | | |
| Exam- | Pt element | F element | Pt ion | 1.2 | 8.1 | 2.8 | 2.7 | 1,000 |
| ple 42 | (40 ppm | (705 ppm | (40 ppm | | | | A | A |
| | by mass) | by mass) | by mass) | | | | | |

TABLE 15-1

| | | Thermally conductive filler in film | | | |
|---|---|---|---|---|---|
| | | Specific surface | Specific surface | Fraction of first | Fraction of second |
| | | area of first | area of second | thermally | thermally |
| | | thermally | thermally | conductive | conductive |
| | | conductive filler | conductive filler | filler | filler |
| | Composition | [m²/g] | [m²/g] | [% by volume] | [% by volume] |
| Example 3 | 3 | 1.62 | 12.2 | 38 | 25 |
| Example 43 | 43 | 1.62 | 12.2 | 38 | 25 |
| Example 44 | 44 | 1.62 | 12.2 | 38 | 25 |
| Example 45 | 45 | 1.62 | 12.2 | 38 | 25 |
| Example 46 | 46 | 1.62 | 12.2 | 38 | 25 |
| Example 47 | 47 | 1.62 | 12.2 | 38 | 25 |
| Example 48 | 48 | 1.62 | 12.2 | 38 | 25 |
| Example 49 | 49 | 1.62 | 12.2 | 38 | 25 |
| Example 50 | 50 | 1.62 | 12.2 | 38 | 25 |
| Example 51 | 51 | 1.62 | 12.2 | 38 | 25 |
| Example 52 | 52 | 1.62 | 12.2 | 38 | 25 |
| Example 53 | 53 | 1.62 | 12.2 | 38 | 25 |
| Example 54 | 54 | 1.62 | 12.2 | 38 | 25 |

TABLE 15-2

| | | | | | | | Evaluation of film | |
|---|---|---|---|---|---|---|---|---|
| | | | | Characteristics of film | | | Shear | Thermal |
| | | | | Thermal | Elastic | | adhesion | cycle |
| | | | Content of | conductivity | modulus | Shear | strength | reliability |
| | Content of specific | | specific | (25 °C) | (−50 °C) | strain | (−50 °C) | (number |
| | element in film | | ion in film | [W/(m · K)] | [MPa] | (−50 °C) | [MPa] | of cycles) |
| Exam- | B element | F element | — | 1.2 | 7.0 | 3.1 | 2.9 | >1,000 |
| ple 3 | (1.5% | (705 ppm | | | | | A | A+ |
| | by mass) | by mass) | | | | | | |
| Exam- | — | F element | — | 1.2 | 7.4 | 2.9 | 2.9 | >1,000 |
| ple 43 | | (705 ppm | | | | | A | A+ |
| | | by mass) | | | | | | |
| Exam- | — | F element | — | 1.2 | 7.5 | 2.8 | 2.8 | >1,000 |
| ple 44 | | (705 ppm | | | | | A | A+ |
| | | by mass) | | | | | | |
| Exam- | — | F element | — | 1.2 | 6.6 | 3.2 | 3.1 | >1,000 |
| ple 45 | | (705 ppm | | | | | A+ | A+ |
| | | by mass) | | | | | | |
| Exam- | — | F element | — | 1.2 | 7.1 | 3.1 | 2.9 | >1,000 |
| ple 46 | | (705 ppm | | | | | A | A+ |
| | | by mass) | | | | | | |
| Exam- | — | F element | — | 1.2 | 8.1 | 2.8 | 2.7 | 1,000 |
| ple 47 | | (705 ppm | | | | | A | A |
| | | by mass) | | | | | | |
| Exam- | — | F element | — | 1.2 | 7.2 | 3.0 | 2.9 | >1,000 |
| ple 48 | | (705 ppm | | | | | A | A+ |
| | | by mass) | | | | | | |
| Exam- | B element | F element | Chloride ion | 1.2 | 6.5 | 3.2 | 3.1 | >1,000 |
| ple 49 | (1.5% | (705 ppm | (3 ppm | | | | A+ | A+ |
| | by mass) | by mass) | by mass) | | | | | |
| | Cl element | | | | | | | |
| | (3 ppm | | | | | | | |
| | by mass) | | | | | | | |
| Exam- | B element | F element | Pt ion | 1.2 | 6.6 | 3.2 | 3.1 | >1,000 |
| ple 50 | (1.5% | (705 ppm | (3 ppm | | | | A+ | A+ |
| | by mass) | by mass) | by mass) | | | | | |
| | Pt element | | | | | | | |
| | (3 ppm | | | | | | | |
| | by mass) | | | | | | | |
| Exam- | B element | F element | — | 1.2 | 6.6 | 3.2 | 3.1 | >1,000 |
| ple 51 | (1.5% | (705 ppm | | | | | A+ | A+ |
| | by mass) | by mass) | | | | | | |
| Exam- | Pt element | F element | Pt ion | 1.2 | 6.6 | 3.2 | 3.1 | >1,000 |
| ple 52 | (3 ppm | (705 ppm | (3 ppm | | | | A+ | A+ |
| | by mass) | by mass) | by mass) | | | | | |
| Exam- | B element | F element | Chloride ion | 1.2 | 6.0 | 3.4 | 3.2 | >1,000 |
| ple 53 | (1.5% | (705 ppm | (3 ppm | | | | A+ | A+ |
| | by mass) | by mass) | by mass) | | | | | |
| | Cl element | | | | | | | |
| | (3 ppm | | | | | | | |
| | by mass) | | | | | | | |
| Exam- | B element | F element | Pt ion | 1.2 | 6.1 | 3.4 | 3.2 | >1,000 |
| ple 54 | (1.5% | (705 ppm | (3 ppm | | | | A+ | A+ |
| | by mass) | by mass) | by mass) | | | | | |
| | Pt element | | | | | | | |
| | (3 ppm | | | | | | | |
| | by mass) | | | | | | | |

TABLE 16

| | | Thermally conductive filler in film | | | | |
|---|---|---|---|---|---|---|
| | | Specific | Specific | | | |
| | | surface | surface | Fraction | Fraction | |
| | | area of | area of | of first | of second | |
| | | first | second | thermally | thermally | |
| | | thermally | thermally | conductive | conductive | Content of |
| | | conductive | conductive | filler | filler | specific |
| | Compo- | filler | filler | [% by | [% by | element |
| | sition | [m²/g] | [m²/g] | volume] | volume] | in film |
| Exam- | 8 | 1.62 | 12.2 | 38 | 25 | B element |
| ple 8 | | | | | | (1.5% by |
| | | | | | | mass) |
| Exam- | 55 | 1.62 | 12.2 | 38 | 25 | B element |
| ple 55 | | | | | | (1.5% by |
| | | | | | | mass) |
| | | | | | | F element |
| | | | | | | (3 ppm |
| | | | | | | by mass) |
| Exam- | 56 | 1.62 | 12.2 | 38 | 25 | B element |
| ple 56 | | | | | | (1.5% by |
| | | | | | | mass) |
| | | | | | | F element |
| | | | | | | (0.5 ppm |
| | | | | | | by mass) |
| Exam- | 57 | 1.62 | 12.2 | 38 | 25 | B element |
| ple 57 | | | | | | (1.5% by |
| | | | | | | mass) |
| | | | | | | F element |
| | | | | | | (3 ppm |
| | | | | | | by mass) |
| Exam- | 58 | 1.62 | 12.2 | 38 | 25 | B element |
| ple 58 | | | | | | (1.5% by |
| | | | | | | mass) |
| | | | | | | F element |
| | | | | | | (40 ppm |
| | | | | | | by mass) |

| | | | | | Evaluation of film | |
|---|---|---|---|---|---|---|
| | | Characteristics of film | | | Shear | Thermal |
| | | Thermal | Elastic | | adhesion | cycle |
| | Content of | conductivity | modulus | Shear | strength | reliability |
| | specific | (25 °C) | (−50 °C) | strain | (−50 °C) | (number |
| | ion in film | [W/(m · K)] | [MPa] | (−50 °C) | [MPa] | of cycles) |
| Exam- | — | 1.2 | 5.0 | 3.1 | 2.9 | >1,000 |
| ple 8 | | | | | A | A+ |
| Exam- | — | 1.2 | 4.6 | 3.2 | 3.1 | >1,000 |
| ple 55 | | | | | A+ | A+ |
| Exam- | Fluoride | 1.2 | 4.0 | 3.4 | 3.2 | >1,000 |
| ple 56 | ion | | | | A+ | A+ |
| | (0.5 ppm | | | | | |
| | by mass) | | | | | |
| Exam- | Fluoride | 1.2 | 4.5 | 3.2 | 3.1 | >1,000 |
| ple 57 | ion | | | | A+ | A+ |
| | (3 ppm | | | | | |
| | by mass) | | | | | |
| Exam- | Fluoride | 1.2 | 4.8 | 3.2 | 3.0 | >1,000 |
| ple 58 | ion | | | | A+ | A+ |
| | (40 ppm | | | | | |
| | by mass) | | | | | |

TABLE 17

| | | Thermally conductive filler in film | | | | | | | | | |
|---|---|---|---|---|---|---|---|---|---|---|---|
| | | Specific | Specific | | | | | | | | |
| | | surface | surface | Fraction | Fraction | | | | | | |
| | | area of | area of | of first | of second | | | | | Evaluation of film | |
| | | first | second | thermally | thermally | Content of | Characteristics of film | | | Shear | Thermal |
| | | thermally | thermally | conductive | conductive | specific | Thermal | Elastic | | adhesion | cycle |
| | | conductive | conductive | filler | filler | element or | conductivity | modulus | Shear | strength | reliability |
| | Compo- | filler | filler | [% by | [% by | specific | (25 °C) | (−50 °C) | strain | (−50 °C) | (number |
| | sition | [m²/g] | [m²/g] | volume] | volume] | ion in film | [W/(m · K)] | [MPa] | (−50 °C) | [MPa] | of cycles) |
| Exam- | 3 | 1.62 | 12.2 | 38 | 25 | B element | 1.2 | 7.0 | 3.1 | 2.9 | >1,000 |
| ple 3 | | | | | | (1.5% by | | | | A | A+ |
| Exam- | 59 | 0.486 | 12.2 | 38 | 25 | mass) | 1.2 | 12 | 3.0 | 2.9 | >1,000 |
| ple 59 | | | | | | F element | | | | A | A+ |
| Exam- | 60 | 0.08 | 12.2 | 38 | 25 | (705 ppm | 1.2 | 30 | 2.7 | 2.1 | 1,000 |
| ple 60 | | | | | | by mass) | | | | B+ | A |
| Exam- | 61 | 0.589 | 12.2 | 43 | 23 | | 1.6 | 15 | 3.0 | 2.8 | >1,000 |
| ple 61 | | | | | | | | | | A | A+ |
| Exam- | 62 | 0.118 | 12.2 | 43 | 23 | | 1.6 | 35 | 2.5 | 2.1 | 1,000 |
| ple 62 | | | | | | | | | | B+ | A |
| Exam- | 63 | 1.62 | 24.3 | 38 | 25 | | 1.2 | 8.0 | 3.0 | 2.8 | >1,000 |
| ple 63 | | | | | | | | | | A | A+ |
| Exam- | 64 | 1.620 | 6.1 | 38 | 25 | | 1.2 | 8.0 | 3.0 | 2.7 | >1,000 |
| ple 64 | | | | | | | | | | A | A+ |

TABLE 18

| | | Thermally conductive filler in film | | | | | | | | | |
|---|---|---|---|---|---|---|---|---|---|---|---|
| | | Specific | Specific | | | | | | | | |
| | | surface | surface | Fraction | Fraction | | | | | | |
| | | area of | area of | of first | of second | | | | | Evaluation of film | |
| | | first | second | thermally | thermally | Content of | Characteristics of film | | | Shear | Thermal |
| | | thermally | thermally | conductive | conductive | specific | Thermal | Elastic | | adhesion | cycle |
| | | conductive | conductive | filler | filler | element or | conductivity | modulus | Shear | strength | reliability |
| | Compo- | filler | filler | [% by | [% by | specific | (25 °C) | (−50 °C) | strain | (−50 °C) | (number |
| | sition | [m²/g] | [m²/g] | volume] | volume] | ion in film | [W/(m · K)] | [MPa] | (−50 °C) | [MPa] | of cycles) |
| Compar-ative | 65 | 1.62 | 12.2 | 38 | 25 | F element | 1.2 | 310 | 0.4 | 1.0 | 0 |
| Exam- | | | | | | (705 ppm | | | | C+ | (Peeled) |
| ple 1 | | | | | | by mass) | | | | | D |
| Compar- | 66 | 1.62 | 12.2 | 38 | 25 | F element | 1.2 | 210 | 0.6 | 1.5 | 0 |
| ative | | | | | | (705 ppm | | | | B | (Peeled) |
| Exam- | | | | | | by mass) | | | | | D |
| ple 2 | | | | | | | | | | | |
| Compar- | 67 | 1.62 | 12.2 | 38 | 25 | F element | 1.0 | 18,000 | 0.2 | 0.5 | 0 |
| ative | | | | | | (25,279 ppm | | | | C | (Crack) |
| Exam- | | | | | | by mass) | | | | | D |
| ple 3 | | | | | | | | | | | |

In Comparative Example 1, (r-1) is contained as an amine compound instead of the (SC) compound, and the flexibility of (r-1) is poor. As a result, the elastic modulus of the film at −50 °C. is significantly greater than 200 MPa, and the shear strain at −50 °C. is less than 0.70. Therefore, the thermal cycle reliability of the film is poor.

In Comparative Example 2, the (SC) compound is not contained. As a result, the elastic modulus at −50 °C. is out of the range of 0.10 to 200 MPa, and the shear strain at −50 °C. is also out of the range of 0.70 to 20. Therefore, the thermal cycle reliability of the film is poor.

Comparative Example 3, polyimide (PI-11) is contained as the (SA) binder resin. Since the flexibility of polyimide (PI-11) is poor, the elastic modulus of the film at −50 °C. is significantly large, and the shear strain at −50 °C. is significantly small. Therefore, the thermal cycle reliability of the film is poor.

### DESCRIPTION OF REFERENCE SIGNS

10: First support
20: Second support
30: Film
40: Base plate
50: Ceramic dielectric plate
60: Film
100A, 200A: Laminate

1. A film comprising:
an (SA) binder resin; and
an (SD) thermally conductive filler,
wherein
the (SD) thermally conductive filler includes an (SD1) first thermally conductive filler and an (SD2) second thermally conductive filler,
the (SD1) first thermally conductive filler has an average primary particle size of 1.0 to 200 μm,
the (SD2) second thermally conductive filler has an average primary particle size of 0.010 μm or more and less than 1.0 μm,
the film has a shear strain of 0.70 to 20 at −50 °C, and
the film has a thermal conductivity 0.10 to 5.0 W/(m·K) at 25 °C.

2. The film according to claim 1, wherein the film has an elastic modulus of 0.10 to 200 MPa at −50 °C.

3.-5. (canceled)

6. A film comprising:
an (SA) binder resin; and
an (SD) thermally conductive filler,
wherein
the film has an elastic modulus of 0.10 to 200 MPa at −50 °C, and
the film has a thermal conductivity of 0.10 to 5.0 W/(m·K) at 25 °C.

7. The film according to claim 6, wherein the film has a shear strain of 0.70 to 20 at −50 °C.

8. The film according to claim 6, wherein the film satisfies at least one of the following conditions (S1a), (S2a), (S3a), (S1b), (S2b), and (S3b):
(S1a) a content of boron element in the film is 5.0% by mass or less;
(S2a) a content of phosphorus element in the film is 1,000 ppm by mass or less;
(S3a) a total content of chlorine element and bromine element in the film is 1,000 ppm by mass or less;
(S1b) a total content of boron element-containing ions in the film is 5.0% by mass or less;
(S2b) a total content of phosphorus element-containing ions in the film is 5,000 ppm by mass or less; and
(S3b) a total content of chloride ion and bromide ion in the film is 1,000 ppm by mass or less.

9. The film according to claim 6, wherein the film satisfies at least one of the following conditions (S4a) and (S4b):
(S4a) a content of platinum element in the film is 1,000 ppm by mass or less; and
(S4b) a total content of platinum element-containing ions in the film is 5,000 ppm by mass or less.

10. The film according to claim 6, wherein the film satisfies at least one of the following conditions (S5a) and (S5b):
(S5a) a total content of an organosilane compound having 1 to 2 silicon atoms in the film is 1,000 ppm by mass or less; and
(S5b) a total content of a cyclic silicone compound in the film is 1,000 ppm by mass or less.

11. The film according to claim 1, wherein the (SA) binder resin includes an (SA1) resin having a silicone structure and/or a siloxane structure in a structural unit of the resin.

12.-15. (canceled)

16. The film according to claim 1, wherein
the film contains (SC) an amine compound or a compound having a structure derived from an amine compound (hereinafter “(SC) compound”), and
the (SC) compound contains an (SC1) compound having a silicone structure and/or a siloxane structure and having at least two alkylene groups bonding to a silicon atom in the silicone structure and/or the siloxane structure.

17. The film according to claim 1, wherein the film has an elastic modulus of 0.010 to 1.0 MPa at 25 °C.

18. The film according to claim 1, wherein the film is a cured product of a composition.

19. (canceled)

20. A laminate comprising:
a base plate;
the film according to claim 1; and
a ceramic dielectric plate
arranged in this order,
wherein the base plate and the ceramic dielectric plate are different in coefficient of thermal expansion.

21. The laminate according to claim 20, wherein a difference in coefficient of thermal expansion between the base plate and the ceramic dielectric plate is 1.0 to 30 ppm/K.

22. A plasma processing apparatus comprising:
a plasma source; and
the laminate according to claim 20.

23. A method for manufacturing a laminate, comprising:
a step of disposing a base plate;
a step of disposing the film according to claim 1; and
a step of disposing a ceramic dielectric plate.

24. The film according to claim 1, wherein a specific surface area of the (SD1) first thermally conductive filler is 0.023 m²/g or more and 5.90 m²/g or less, and a specific surface area of the (SD2) second thermally conductive filler is 5.91 m²/g or more and 590 m²/g or less.

25. The film according to claim 1, wherein the (SD1) first thermally conductive filler and the (SD2) second thermally conductive filler include one or more selected from the group consisting of alumina particles, aluminum nitride particles, boron nitride particles, silica particles, silicon carbide particles, silicon nitride particles, magnesium oxide particles, magnesium carbonate particles, magnesium hydroxide particles, zinc oxide particles, titanium carbide particles, titanium nitride particles, titanium oxide particles, zirconium oxide particles, yttrium oxide particles, and iron oxide particles.

26. The film according to claim 1, wherein the content ratio of the (SD2) second thermally conductive filler is preferably 20% by volume or more 60% by volume or less where the total of the (SD1) first thermally conductive filler and the (SD2) second thermally conductive filler is 100% by volume.

27. The film according to claim 6, wherein the (SA1) resin contains an (SA1-2) silicone resin and/or a polysiloxane.

28. The film according to claim 27, wherein
the silicone resin is a resin having, a bifunctional organosilane unit having two organic groups on a silicon atom and having a silicon atom bonded to two oxygen atoms is contained as a main skeleton,
the content ratio of the bifunctional organosilane unit accounting for in all the organosilane units in the silicone resin is 50 mol % or more and 100 mol % or less,
the polysiloxane is a resin having, a trifunctional organosilane unit that has one organic group having two organic groups on a silicon atom and has a silicon atom bonded to three oxygen atoms is contained as a main skeleton, and
the content ratio of the trifunctional organosilane unit accounting for in all the organosilane units in the silicone resin is 50 mol % or more and 100 mol % or less.
